(19) United States
(12) Patent Application Publication
(10) Pub. No.: US 2022/0285623 A1
(43) Pub. Date: Sep. 8, 2022

(54) INKJET RECORDING MEDIUM FOR ORGANIC SEMICONDUCTOR DEVICE, MEMBER FOR ORGANIC SEMICONDUCTOR DEVICE, AND MANUFACTURING METHOD FOR ORGANIC SEMICONDUCTOR DEVICE

(71) Applicant: Konica Minolta, Inc., Tokyo (JP)

(72) Inventors: Hideo TAKA, Tokyo (JP); Tomoo IZUMI, Osaka (JP); Kazuhiro OIKAWA, Tokyo (JP)

(21) Appl. No.: 17/650,445

(22) Filed: Feb. 9, 2022

(30) Foreign Application Priority Data
Feb. 26, 2021 (JP) 2021-029515

(51) Int. Cl. H01L 51/00; B41M 5/50; B41M 3/00; H01L 51/10; H01L 51/44; H01L 51/52

(52) U.S. Cl. CPC H01L 51/0012; B41M 5/502; B41M 3/006; H01L 51/0005; H01L 51/10; H01L 51/44; H01L 51/52; H01L 51/0034

(57) ABSTRACT

Provided is an inkjet recording medium for an organic semiconductor device including a base material, an electrode, and ink receiving layer in this order, wherein the ink receiving layer has an ink penetration prevention area on an electrode side that prevents ink which permeates from a surface far from the electrode toward the electrode from reaching the electrode.

### CROSS-REFERENCE TO RELATED APPLICATIONS

The entire disclosure of Japanese Patent Application No. 2021-029515 filed on Feb. 26, 2021 is incorporated herein by reference in its entirety.

### BACKGROUND

### Technological Field

The present invention relates to an inkjet recording medium for an organic semiconductor device, a member for an organic semiconductor device, and a method for manufacturing the organic semiconductor device.

### Description of the Related Art

In recent years, organic semiconductor devices utilizing the semiconductor property of organic thin films, for example, electroluminescence (hereinafter abbreviated as “EL”) elements and organic thin film solar cells have been actively developed.

As an example of a method for manufacturing such an organic semiconductor device, a technique for forming pixels containing an organic semiconductor material by an inkjet method is known. When forming pixels by the inkjet method, a method is applied in which a bank serving as a partition wall is formed in advance between each pixel, and an ink containing an organic semiconductor material is applied to a pixel area partitioned by the bank by an inkjet method. However, in this method, the apparatus and the process are complicated, and there is a problem of cost increase due to low yield.

In order to solve the above problems, a so-called “self-alignment process” has come to be known as a method for manufacturing an organic semiconductor device by a simple process. In the self-alignment process, for example, an insulating resin layer to be an ink receiving layer is formed on an electrode of a base material with an electrode, and an organic semiconductor material-containing ink is pattern-printed on the ink receiving layer by an inkjet method. At this time, the solvent used for the organic semiconductor material-containing ink dissolves the ink receiving layer and replaces the organic semiconductor material which is a solute, so that the bank and the organic semiconductor layer may be formed at the same time.

As an organic semiconductor device manufactured by using a self-alignment process, for example, Non-Patent Document 1 describes the following organic EL element. This organic EL element is provided with a light-emitting layer formed by inkjet ejection of a light-emitting ink (an ink containing a charge transporting host compound and a luminescent compound) on an ink receiving layer made of an insulating polymer, and a discharge pattern image is light-emitted by passing an electric current between a pair of an anode and a cathode.

Further, Non-Patent Document 2 discloses “an organic EL element including a light-emitting layer formed by inkjet ejection of an ink containing a luminescent compound onto an ink receiving layer containing a hole transport material in advance”.

However, in the self-alignment process, the organic semiconductor layer is formed so as to penetrate the ink receiving layer, whereby a contact portion where the organic semiconductor layer contacts the electrode is formed. It is difficult to control the electrode interface of the organic semiconductor layer formed by the inkjet method, and the interface cannot be formed accurately. Therefore, due to the disturbance (defect) of the contact portion between the organic semiconductor layer and the electrode, a leakage current is generated through the contact portion. As a result, in an organic EL element, there are problems such as a decrease in yield due to poor light emission of the device and poor light emission at the time of reapplication.

### PRIOR ART DOCUMENTS

### Non-Patent Documents

Non-Patent Document 1: K. Matsui, J. Yanagi, M. Shibata, S. Naka, H. Okada, T. Miyabayashi, T. Inoue: “Multi-Color Organic Light Emitting Panels Using Self-Aligned Ink-Jet Printing Technology”, Mol. Cryst. Liq. Cryst., 471 (1), pp. 261-268 (2007)

Non-Patent Document 2: R. Satoh, S. Naka, M. Shibata, H. Okada, T. Inoue, T. Miyabayashi: “Self-Aligned Organic Light-Emitting Diodes with Color Changing by Ink-Jet Printing Dots”, Japanese Journal of Applied Physics, 50, pp. 01BC09-1-4 (2011)

### SUMMARY

The present invention has been made in view of the above problems and situations, and the problem to be solved is to provide an inkjet recording medium for an organic semiconductor device and a member for an organic semiconductor device for accurately manufacturing an organic semiconductor device by a simple process. Another object of the present invention is to provide a method for manufacturing an organic semiconductor device, which may accurately manufacture an organic semiconductor device by a simple process using the inkjet recording medium for the organic semiconductor device.

As a result of investigating the causes of the above problems in order to solve the above problems, the present inventor found the following. In the self-alignment process, for an ink receiving layer formed on the electrodes of the base material with electrodes, the ink receiving layer was designed so that the organic semiconductor material-containing ink ejected by the inkjet apparatus does not penetrate the ink receiving layer and does not reach the electrodes. By this the above problems have been solved. That is, the above problems according to the present invention are solved by the following means.

To achieve at least one of the above-mentioned objects of the present invention, an inkjet recording medium for an organic semiconductor device that reflects an aspect of the present invention is as follows.

An inkjet recording medium for an organic semiconductor device comprising a base material, an electrode, and an ink receiving layer laminated in this order, wherein the ink receiving layer has an ink penetration prevention area on an electrode side that prevents an ink which permeates from a surface far from the electrode toward the electrode from reaching the electrode.

Another aspect of the present invention is an organic semiconductor device member comprising a base material, an electrode, and an organic semiconductor layer laminated in this order,

wherein the organic semiconductor layer has:

(i) an ink receiving layer continuously present in an entire area of the organic semiconductor layer formation area on the electrode;

(ii) a pattern-shaped exposed portion on a surface of the organic semiconductor layer far from the electrode as a discontinuous area surrounded by the ink receiving layer; and

(iii) an organic semiconductor material-containing area which has no interface with the electrode.

By the above means of the present invention, it is possible to provide an inkjet recording medium for an organic semiconductor device and a member for an organic semiconductor device for accurately manufacturing an organic semiconductor device by a simple process. Further, it is possible to provide a method for manufacturing an organic semiconductor device, which may accurately manufacture an organic semiconductor device by a simple process using the inkjet recording medium for an organic semiconductor device. The mechanism of expression or mechanism of action of the effect of the present invention is inferred as follows.

By using the inkjet recording medium for an organic semiconductor device and the member for an organic semiconductor device of the present invention, and by applying a self-alignment process to the production of an organic semiconductor device, the pixels as the organic semiconductor layer and the bank that partitions the pixels may be manufactured at the same time, and the manufacturing process can be simplified.

Further, in the obtained organic semiconductor device, the organic semiconductor layer hardly reaches the electrodes of the base material with electrodes. As a result, it is possible to accurately manufacture a high-quality organic semiconductor device in which the occurrence of disturbance (defect) at the contact point between the organic semiconductor layer and the electrode is suppressed.

According to the method for manufacturing an organic semiconductor device using the inkjet recording medium for an organic semiconductor device of the present invention, in addition to obtaining the above effects, the process may be divided. As a result, it is advantageous in terms of labor saving in production control, efficiency improvement by parallelization, and shortening of product completion time by using intermediate materials.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are not intended as a definition of the limits of the present invention.

FIG. 1 is a cross-sectional view of an example of an inkjet recording medium for an organic semiconductor device of the present invention.

FIG. 2 is a plan view of an example of a member for an organic semiconductor device of the present invention.

FIG. 3 is a cross-sectional view taken along the line of a member for an organic semiconductor device shown in FIG. 2.

FIG. 4 is a cross-sectional view of another example of a member for an organic semiconductor device of the present invention.

FIG. 5 is a cross-sectional view illustrating an ink dropping process in an example of a method for manufacturing an organic semiconductor device of the present invention.

FIG. 6 is a cross-sectional view of an example of an organic semiconductor device obtained by the manufacturing method of the present invention.

### DETAILED DESCRIPTION OF THE EMBODIMENTS

Hereinafter, one or more embodiments of the present invention will be described. However, the scope of the invention is not limited to the disclosed embodiments.

The inkjet recording medium for an organic semiconductor device of the present invention is an inkjet recording medium for an organic semiconductor device in which a substrate, an electrode, and an ink receiving layer are laminated in this order. The ink receiving layer is characterized by having an ink penetration prevention area on an electrode side that prevents an ink which permeates from a surface far from the electrode toward the electrode from reaching the electrode.

In an embodiment of the inkjet recording medium for an organic semiconductor device of the present invention, from the viewpoint of exhibiting the effect of the present invention, it is preferable that the ink receiving layer has an ink penetrating layer including a surface far from the electrode, and further has an ink insoluble layer on an electrode side as an ink penetration prevention area.

In an embodiment of the inkjet recording medium for an organic semiconductor device of the present invention, it is preferable that the ink insoluble layer contains a crosslinked resin as a main component from the viewpoint of enhancing the ink penetration prevention performance on the electrode side. Alternatively, it is preferable that the ink insoluble layer contains an interpenetrating polymer network structure.

In an embodiment of the inkjet recording medium for an organic semiconductor device of the present invention, the absolute value of the difference between the SP value of the constituent component of the ink penetrating layer and the SP value of the ink is preferably 3.0 (J/cm³)^{1/2} or less from the viewpoint of enhancing the ink permeability in the surface layer far from the electrode. From the viewpoint of enhancing the ink penetration prevention performance on the electrode side, the absolute value of the difference between the SP value of the constituent component of the ink insoluble layer and the SP value of the ink is preferably 3.1 (J/cm³)^{1/2} or more. The SP value in the present invention may be measured as described later.

In an embodiment of the inkjet recording medium for an organic semiconductor device of the present invention, it is preferable that the ink penetrating layer contains a polystyrene resin from the viewpoint of enhancing the ink penetrability in the surface layer far from the electrode. From the viewpoint of enhancing the ink penetration prevention performance on the electrode side, it is preferable that the ink insoluble layer contains a resin containing tetraphenylbenzidine or a derivative thereof as a main polymerization unit.

In an embodiment of the inkjet recording medium for an organic semiconductor device of the present invention, it is preferable that the inkjet recording medium for an organic semiconductor device further has a release film on the ink receiving layer from the viewpoint of stably maintaining the effect of the present invention.

The member for an organic semiconductor device of the present invention is a member for an organic semiconductor device in which a base material, an electrode, and an organic semiconductor layer are laminated in this order, and the organic semiconductor layer has: an ink receiving layer that is continuously present in the entire area of the organic semiconductor layer forming area on the electrode; and as a discontinuous area surrounded by the ink receiving layer, a patterned exposed portion provided on the surface of the organic semiconductor layer far from the electrode. Further, the organic semiconductor layer has an area having no interface with the electrode.

In an embodiment of the member for an organic semiconductor device of the present invention, the maximum thickness of the ink receiving layer is preferably in the range of 3 nm to 5 μm from the viewpoint of exhibiting the effect of the present invention. Further, it is preferable that the constituent material of the ink receiving layer mainly contains a resin having a weight average molecular weight in the range of 1,000 to 1,000,000.

In an embodiment of the member for an organic semiconductor device of the present invention, the area containing the organic semiconductor material is an area formed by using the ink containing the organic semiconductor material from the viewpoint of exhibiting the effect of the present invention. The absolute value of the difference between the SP value of the constituent material of the ink receiving layer and the SP value of the ink is preferably 3.0 (J/cm³)^{1/2} or less.

In an embodiment of the member for an organic semiconductor device of the present invention, the area containing the organic semiconductor material is an area formed by using the ink containing the organic semiconductor material from the viewpoint of exhibiting the effect of the present invention. The ink receiving layer preferably has an ink penetrating layer including a surface far from the electrode and an ink insoluble layer on the electrode side.

The method for manufacturing an organic semiconductor device of the present invention is a method for manufacturing an organic semiconductor device using the inkjet recording medium for an organic semiconductor device of the present invention. It is characterized by having a step of dropping an ink onto the ink receiving layer and a step of forming a film of an electrode on the ink receiving layer which is paired with the electrode after the dropping.

In the method for manufacturing an organic semiconductor device of the present invention, the organic semiconductor device is, for example, an organic electroluminescent device, an organic thin film transistor, or an organic photoelectric conversion element.

Hereinafter, the present invention, its constituent elements, and shapes and embodiments for carrying out the present invention will be described in detail with reference to the drawings. However, the scope of the present invention is not limited to the illustrated examples. The inkjet recording medium for an organic semiconductor device, the member for an organic semiconductor device, and the organic semiconductor device of the illustrated example may be appropriately changed without departing from the spirit of the present invention.

In the present application, “to” is used to mean that the numerical values described before and after the value are included as the lower limit value and the upper limit value. In the present specification, “main component”, “mainly contained”, and “composed as a main component” mean that that the main component accounts for 50 mass % or more, preferably 70 mass % or more, and still more preferably 90% mass % or more of based on the whole.

[Inkjet recording medium for organic semiconductor device]

The inkjet recording medium for an organic semiconductor device (hereinafter simply referred to as an “inkjet recording medium”) of the present invention is an inkjet recording medium in which a base material, an electrode, and an ink receiving layer are laminated in this order. The inkjet recording medium of the present invention is characterized in that the ink receiving layer has, on the electrode side, an ink penetration prevention area that prevents the ink which penetrates from a surface far from the electrode toward the electrode from reaching the electrode.

The inkjet recording medium of the present invention is used for manufacturing an organic semiconductor device. Specifically, the organic semiconductor device includes an organic EL element, an organic thin film transistor (hereinafter also referred to as an “organic TFT”) and organic photoelectric conversion devices. The ink of the present invention is an ink for use in an inkjet method, and contains an organic semiconductor material used for manufacturing an organic semiconductor device.

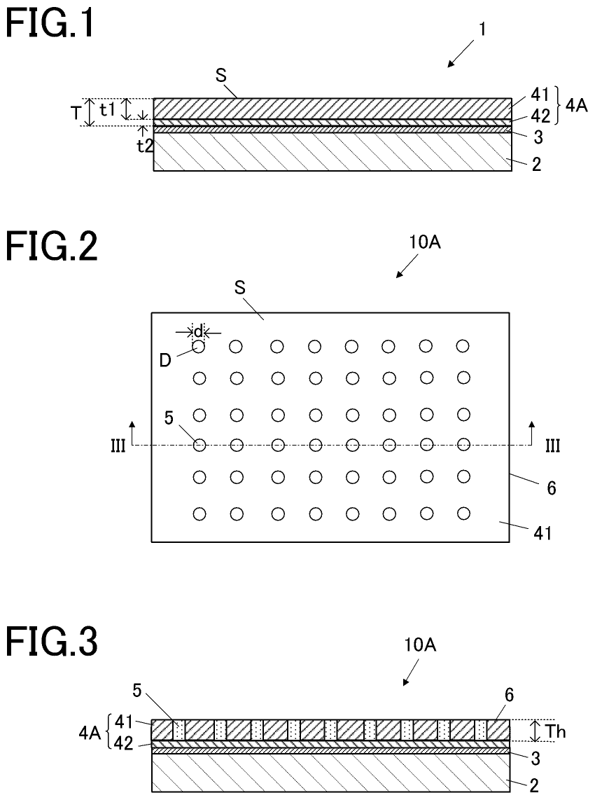

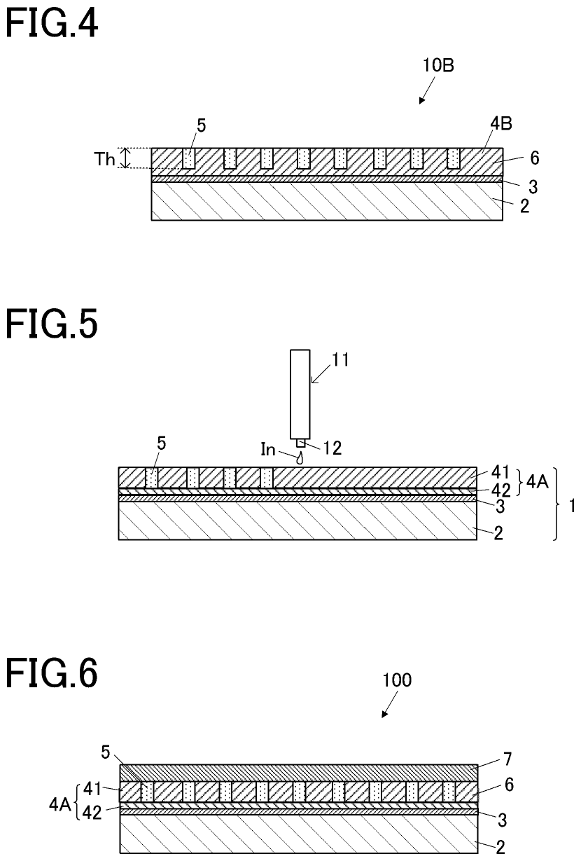

FIG. 1 shows a cross-sectional view of an example of an inkjet recording medium of the present invention. FIG. 2 and FIG. 3 show, respectively, a plan view of an example of an organic semiconductor device member of the present invention and a cross-sectional view cut therethrough at The organic semiconductor device member shown in FIG. 2 is an example of an organic semiconductor device member obtained by using the inkjet recording medium shown in FIG. 1. FIG. 4 shows a cross-sectional view of another example of an organic semiconductor device member of the present invention. FIG. 5 is a cross-sectional view illustrating an ink dropping process in one example of a method for manufacturing an organic semiconductor device, and FIG. 6 is a cross-sectional view of an example of an organic semiconductor device obtained by the method for manufacturing an organic semiconductor device of the present invention.

FIG. 5 illustrates an example of an ink dropping process using the inkjet recording medium shown in FIG. 1. By completing the ink dropping process shown in FIG. 5, the member for the organic semiconductor device of the present invention shown in FIG. 2 and FIG. 3 is obtained. FIG. 6 is a diagram illustrating an example of an organic semiconductor device finally obtained by going through the member for the organic semiconductor device of the present invention shown in FIG. 2 and FIG. 3 using the inkjet recording medium shown in FIG. 1.

The inkjet recording medium 1 shown in FIG. 1 has a base material 2, an electrode 3 disposed on the base material, and an ink receiving layer 4A disposed on the electrode. The ink receiving layer 4A has an ink penetration prevention area 42 on the electrode 3 side. The ink penetration prevention area 42 is an area that prevents ink which penetrates from the surface S far from the electrode 3 of the ink receiving layer 4A toward the electrode 3 from reaching the electrode 3. In the ink receiving layer 4A, the area from the surface S to the upper surface of the ink penetration prevention area 42 is the ink penetration area 41 through which the ink penetrates. In the description of FIG. 1, the base material 2 side may be denoted by “bottom” and the ink receiving layer 4A side by “top”.

An inkjet recording medium is a recording medium used to apply printing by an inkjet method. As shown in FIG. 5, the inkjet recording medium may become the member 10A for an organic semiconductor device shown in FIG. 2 and FIG. 3 by undergoing a process of dropping an ink In on the surface S of the ink receiving layer 4A by the inkjet method. Further, by forming an electrode 7 (hereinafter referred to as a “counter electrode 7” to distinguish it from the electrode 3) which is paired with the electrode 3 on the ink receiving layer 4A of the organic semiconductor device member 10A, an organic semiconductor device 100 shown in FIG. 6 is produced.

In addition to the base material, the electrodes, and the ink receiving layer, the inkjet recording medium of the present invention may have additional layers other than these, if necessary. The additional layers include, for example, a release film provided on the ink receiving layer, a gas barrier film provided on the base material, a reflective film for light extraction, and a scattering film. Each of the components in the inkjet recording medium of the present invention will be described below.

### <Base Material>

As the base material 2, there is no particular limitation on the type of constituent material such as glass or plastic, and it may be transparent or opaque. The shape of the base material 2 is preferably in the form of a film or a substrate. The thickness of the base material 2 is not particularly limited, but for example, it is in the range of 1 to 1000 μm.

When the resulting organic semiconductor device is, for example, an organic semiconductor device with a mechanism for taking out light from the base material side, it is preferable that the base material be transparent. As the transparent base material preferably used, a glass base material, a quartz base material, and a transparent resin film may be mentioned. A particularly preferred base material is a resin film capable of providing flexibility to the organic semiconductor device.

Examples of the resin that constitutes the resin film include polyesters such as polyethylene terephthalate (PET) and polyethylene naphthalate (PEN); polyolefins such as Polyethylene and polypropylene; cellulose esters and their derivatives such as cellophane, cellulose diacetate, cellulose triacetate (TAC), cellulose acetate butyrate, cellulose acetate propionate (CAP), cellulose acetate phthalate, and cellulose nitrate; polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyallylates, and cycloolefin resins such as ARTON (trade name, made by JSR Co. Ltd.) and APEL (trade name, made by Mitsui Chemicals, Inc.).

A gas barrier film made of an inorganic substance or an organic substance or a hybrid gas barrier film of both of them may be formed on the surface of the resin film on the side far from the electrode and/or on the electrode side. These gas barrier films preferably have a water vapor permeability (at 25±0.5° C. and relative humidity (90±2)% RH) of 0.01 g/(m²·24h) or less determined by the method based on JIS K 7129-1992. Further, it is preferable that they have high barrier properties of an oxygen permeability of 10⁻³ mL/(m²·24h·atm) or less, measured by a method based on JIS K 7126-1987, and the water vapor permeability of 10⁻⁵ g/(m²·24 h) or less.

As a material for forming the gas barrier film, a material having a function of suppressing penetration of moisture or oxygen which causes deterioration of the element may be used. For examples, silicon oxide, silicon dioxide, or silicon nitride may be used. Further, in order to improve the fragility of the film, it is more preferable to have a laminated structure of these inorganic layers and layers made of an organic material. The stacking order of the inorganic layer and the organic layer is not particularly limited, but it is preferable that both layers are alternately stacked a plurality of times.

The method of forming the gas barrier film is not particularly limited. For example, a vacuum evaporation method, a sputtering method, a reactive sputtering method, a molecular beam epitaxy method, a cluster ion beam method, an ion plating method, a plasma polymerization method, an atmospheric pressure plasma polymerization method, a plasma CVD (Chemical Vapor Deposition method), a laser CVD method, a thermal CVD method, or a coating method may be used. However, an atmospheric pressure plasma polymerization method as described in JP-A 2004-68143 is particularly preferable.

Examples of the opaque support substrate include a metal plate such as aluminum or stainless steel, a film, an opaque resin substrate, and a ceramic substrate.

### <Electrode>

The electrode 3 disposed on the base material 2 comprises an electrode material that is a conductor. The inkjet recording medium 1 is ultimately used as an organic semiconductor device, such as the organic semiconductor device 100 via an inkjet recording medium 10A. The organic semiconductor device 100 is provided with an electrode 3 and a counter electrode 7 which is paired therewith. One of the electrode 3 and the counter electrode 7 is used as an anode and the other as a cathode.

The electrode 3 may function as an anode or as a cathode when the organic semiconductor device is formed. For example, when the organic semiconductor device is an organic EL element and the electrode 3 is used as an anode, the electrode 3 is preferably made of a metal, an alloy, an electrically conductive compound, and a mixture thereof having a large work function (4 eV or more, preferably 4.5 eV or more) as an electrode material. Specific examples of such electrode materials include metals such as Au, conductive transparent materials such as CuI, indium tin oxide (ITO: Indium Tin Oxide), SnO₂, and ZnO. In addition, a material such as IDIXO (In₂O₃-ZnO) that is amorphous and capable of producing a transparent conductive film may be used.

A conductive polymer may also be used for the anode. Examples of the conductive polymer include PEDOT:PSS, polypyrrole, polyaniline, polythiophene, polythienylenevinylene, polyazulene, polyisothianaphthene, polycarbazole, polyacetylene, polyphenylene, polyphenylene vinylene, polyacene polyphenylacetylene, polydiacetylene, polynaphthalene, and derivatives thereof. Only one of these electrode materials may be used alone, or two or more materials may be used in a mixture. It is also possible to construct an electrode by stacking two or more layers comprising each material.

For example, when the organic semiconductor device is an organic EL element, and when the electrode 3 is used as a cathode, the electrode 3 made of a metal having a small work function (5 eV or less) (referred to as an electron injecting metal), an alloy, an electrically conductive compound, or a mixture thereof is used as an electrode material. Specific examples of such electrode materials include sodium, a sodium-potassium alloy, magnesium, lithium, silver, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and rare earth metals.

Among these, a mixture of an electron injecting metal and a second metal, which is a stable metal having a larger work function value than the electron injecting metal, such as a magnesium/silver mixture, a magnesium/aluminum mixture, a magnesium/indium mixture, an aluminum/aluminum oxide (Al₂O₃) mixture, a lithium/aluminum mixture, and aluminum are suitable.

As a cathode, a transparent or translucent cathode is produced by forming a film of the metal having a predetermined thickness, for example, a thickness of 1 to 20 nm, and then forming a conductive transparent material on the film. By applying this, a device in which both the anode and the cathode have transparency may be fabricated.

In the organic semiconductor device, the counter electrode 7 is a cathode when the electrode 3 is an anode, and the counter electrode 7 is an anode when the electrode 3 is a cathode.

The electrode 3, whether anode or cathode, is obtained, for example, by depositing an electrode material as a thin film on the base material 2 by a method such as vapor deposition or sputtering. The electrode 3 may be provided as a flat film having a uniform thickness over the entire surface of the base material 2, or may be provided in a desired pattern shape. The pattern-shaped electrode 3 may, for example, be formed in a pattern of a desired shape by a photolithography method, or, if pattern accuracy is not required too much (about 100 μm or more), the pattern may be formed through a mask of a desired shape at the time of evaporation or sputtering of the electrode material described above.

When a coatable substance such as an organic conductive compound or a metal nanoparticle is used, a wet film deposition method such as a printing method or a coating method may also be used. In the organic EL element, the sheet resistance as an electrode should be several hundred Ω/sq. or less. The thickness of the electrode 3 depends on the material, but is usually selected in the range of 10 nm to 5 μm, preferably 10 to 200 nm.

In the organic EL element, in order to transmit the emitted light, it is convenient when either the anode or the cathode is transparent or translucent to improve the luminous intensity. When light emission is extracted from the electrode, it is preferable to make the transmittance greater than 10%.

### <Ink Receiving Layer>

The ink receiving layer 4A is a layer laminated on the electrode 3. Here, in the cross section shown in FIG. 1, the electrode 3 is formed over the entire upper surface of the base material 2. In this case, the ink receiving layer 4A is formed so that the entire layer is in contact with the upper surface of the electrode 3. However, as explained above, the electrode 3 may be formed in a pattern shape. Accordingly, the lower surface of the ink receiving layer 4A may be formed so as to partially contact the upper surface of the base material 2, instead of contacting only the upper surface of the electrode 3.

In other words, the ink receiving layer 4A is a layer formed on the electrode 3 forming surface of the base material 2 with the electrode 3 in a region including at least the electrode 3. The formed area of the ink receiving layer 4A may, for example, be an area covering the entire surface of the base material 2 with the electrode 3 or an area covering a specific area of the base material 2 with the electrode 3. The ink receiving layer 4A is usually provided as a continuous single layer.

The formation area of the ink receiving layer 4A on the base material 2 with the electrode 3 is, for example, an area including an area where a patterned organic semiconductor material-containing area is formed by dropping of an ink, and is selected appropriately according to the type and application of the semiconductor device. Specifically, when the organic semiconductor device is an organic EL element and is used in a display device, the formation area of the ink receiving layer 4A may be the display area.

The ink receiving layer 4A has an ink penetration area 41 and an ink penetration prevention area 42. The ink penetration area 41 and the ink penetration prevention area 42 exist in a layered manner over the entire formation area of the ink receiving layer 4A. The ink penetration area 41 and the ink penetration prevention area 42 may be formed separately as individual layers, or they may be two areas distinguished by a continuous change in composition in the layer upon formation of the ink receiving layer 4A. In either case, the shape of the interface between the ink penetration area 41 and the ink penetration prevention area 42 is not limited and may be a flat shape or an uneven shape.

In FIG. 1, the ink penetration prevention area 42 is provided at the most electrode 3 side of the ink receiving layer 4A. In the present invention, the ink penetration prevention area 42 need only be provided at a position close to the electrode 3 of the ink receiving layer 4A, and another area may be further provided on the electrode side of the ink penetration prevention area 42. The ink penetration prevention area 42 is preferably provided at the most electrode 3 side of the ink receiving layer 4A from the viewpoint of ease of manufacture.

The specific differences in the composition of the ink penetration area 41 and the ink penetration prevention area 42 are as follows: the material of the ink penetration prevention area 42 has a lower affinity for an ink or is insoluble compared to the material of the ink penetration area 41; the material of the ink penetration prevention area 42 has a denser structure compared to the material of the ink penetration area 41; and the material of the ink penetration prevention area 42 has a higher thermal property indicated by the glass transition temperature (Tg) compared to the material of the ink penetration area 41.

In the ink receiving layer 4A, the ink penetration area 41 and the ink penetration prevention area 42 are preferably layers made of different materials. The layer corresponding to the ink penetration area 41 is referred to as the ink penetrating layer, and the layer corresponding to the ink penetration prevention area 42 is referred to as the ink penetration prevention layer. The ink penetration prevention layer is preferably an ink insoluble layer that is insoluble in ink. Hereinafter, the ink penetration area 41 and the ink penetration prevention area 42 are described as the ink penetrating layer and the ink insoluble layer, respectively, with the same sign as the ink penetration area 41 and the ink penetration prevention area 42, respectively.

The ink penetrating layer 41 is a layer including the surface S of the ink receiving layer 4A. The layer thickness t1 of the ink penetrating layer 41 is preferably a thickness that sufficiently secures the thickness of the organic semiconductor material-containing area formed by the penetration of the ink In. Specifically, the layer thickness t1 of the ink penetrating layer 41 is preferably 2 nm to 4.9 μm, and 10 nm to 100 nm is more preferable.

On the other hand, the layer thickness t2 of the ink insoluble layer 42 is a layer that prevents the ink that has penetrated the ink penetrating layer 41 from penetrating to the electrode 3. Although it depends on the type of ink and the composition of the ink insoluble layer 42, in order to perform the function of preventing the penetration of the ink, the layer thickness t2 of the ink insoluble layer 42 is preferably 1 to 100 nm, for example, 2 to 100 nm is more preferable, and 5 to 100 nm is even more preferable. In the ink receiving layer 4A, the distance from the edge of the electrode 3 side of the resulting organic semiconductor material-containing area to the electrode 3 is preferably 1 nm or more from the viewpoint of sufficiently suppressing the generation of a leakage current, and more preferably 100 nm or less from the viewpoint of suppressing an increase in the drive voltage. From such a viewpoint, the layer thickness t2 of the ink insoluble layer 42 is preferably in the above range.

The layer thickness T of the ink receiving layer 4A is the combined thickness of the layer thickness t1 of the ink penetrating layer 41 and the layer thickness t2 of the ink insoluble layer 42, preferably it is 3 nm to 5 μm, and more preferably 30 to 150 nm.

The constituent materials of the ink receiving layer 4A, that is, the ink penetrating layer 41 and the ink insoluble layer 42, are preferably resins, and the resins are preferably insulating. “Insulating” means that the electrical resistivity is 1×10⁶Ω·m or more, preferably 1×10⁸Ω·m or more, and even more preferably 1×10¹⁰ Ω·m or more. It is believed that an electrical resistivity of the resin of 1×10⁶Ω·m or more may suppress a leakage current flowing in the organic semiconductor layer 6 of the resulting organic semiconductor device.

The ink penetrating layer 41 is preferably composed of a resin having ink penetrating properties (hereinafter referred to as a “resin A”). The resin A is preferably composed mainly of an insulating resin. As such a resin, a resin having a higher stability and whose main chain is composed of carbon atoms is preferred. The ink penetrating layer 41 preferably does not contain a cross-linked resin from the viewpoint of permeability.

When the ink penetrating layer 41 is formed as a layer having the resin A as a main component, for example, so that it may be formed by a coating method, the resin A should be soluble in an appropriate solvent, and it is preferable that the resin A shows solubility in an aprotic polar solvent. Specifically, the solubility of the resin A in 1 g of N,N-dimethylformamide at 25° C. is preferably 0.5 mg or more, more preferably 1.0 mg or more, and still more preferably 2.0 mg or more.

There is no particular restriction on the type of resin A as long as it has ink permeability. From the viewpoint of permeability, it is preferable that the resin A has no crosslinking point or has a low crosslinking density.

Examples of the resin A includes non-ionic resins such as polystyrene resin, acrylic resin such as polymethylmethacrylate, polycarbonate resin, polyvinyl alcohol resin, polyacrylamide resin, polyvinylpyrrolidone resin, polyvinylpolypyrrolidone resin, polyethylene glycol resin, polymethylvinyl ether resin, and polyisopropylacrylamide resin; cationic resins such as sodium polyacrylate resin, sodium polystyrene sulfonate resin, sodium polyisopropylene sulfonate resin, polynaphthalene sulfonic acid condensate salt, polyethylene imine xanthate salt; anionic resins such as dimethylaminomethyl (meth) acrylate quaternary salt resin, dimethyldialylammonium chloride resin, polyamidine resin, polyvinylimidazoline resin, dicyandiamide-based condensate resin, epichlorohydrin dimethylamine condensate, and polyethyleneimine resin; and amphoteric resins such as dimethylaminoethyl (meth)acrylate quaternary salt acrylic acid copolymer, and Hofmann decomposition product of polyacrylamide.

Further examples of the resin A include polyalkylene resins such as polyethylene, polypropylene, polyvinylidene fluoride, and polyacrylonitrile; aromatic ring-containing polymers such as polyethylene terephthalate, polyethylene naphthalate, polyphenyl ether, polyethylene ether ketone, polyphenylene sulfide, poly polyphenylene sulfone, polysulfone, polyether sulfone, polyarylate, polystyrene, polyvinylphenol and derivatives of these polymers; and curing resins such as phenolic resin and epoxy resin.

Of these, a polystyrene resin, an acrylic resin such as polymethyl methacrylate, or a polycarbonate resin is preferable as the resin A. The aromatic ring-containing polymer is preferred in terms of meshing with the electrode crystal lattice and interaction with adjacent layers. In particular, a resin (polymer) containing a benzene ring such as polystyrene resin is preferable.

It is preferable that the polymer containing the benzene ring is a non-conjugated polymer from the viewpoint of carrier blocking. It is also preferred that the non-conjugated polymer includes the benzene ring as a side chain from the viewpoint of the effect of dispersing the organic semiconductor material described below.

It is particularly preferable that the non-conjugated polymer is a polystyrene resin from the viewpoint of suppressing interfacial recombination. In the case of a polymer including a benzene ring, particularly a polymer including a benzene ring in a side chain, such as a polystyrene resin, it easily interacts with the organic semiconductor material containing a large amount of π-conjugation to easily enclose the organic semiconductor material during drying, and to form a phase separation structure to obtain a trap suppression effect and a carrier blocking effect. In addition, it is preferable for the non-conjugated polymer to be a mixture of components having different steric regularity, from the viewpoint that the interfacial localization amount of the polymer may be controlled and the carrier balance may be adjusted.

Herein, the term “polystyrene resin” refers to a resin that primarily contains polymerization units based on a styrene monomer. The term “mainly includes” means that the ratio of polymerization units based on styrene monomer to total polymerization units is 50 mol% or more. The same meaning applies to other resins.

The styrene monomer includes styrene represented by the structural formula CH₂═CH—C₆H₅ as well as styrene having a known side chain or functional group in the styrene structure. The functional group includes, for example, a hydroxy group, an ester group, and an amide group.

Specific examples of the styrene monomer include styrene, o-methylstyrene, m-methylstyrene, p-methylstyrene, a-methylstyrene, p-phenylstyrene, p-ethylstyrene, 2,4-dimethylstyrene, p-tert-butylstyrene, p-n-hexylstyrene, p-n-octylstyrene, p-n-nonylstyrene, p-n-decylstyrene, and p-n-dodecylstyrene. These styrene monomers may be used alone or in combination of two or more types.

The polystyrene resin may comprise polymerization units based solely on styrene monomers, or may contain polymerization units based on vinyl monomers other than styrene monomers. Such vinyl monomers include (meth)acrylic acid (a generic term for acrylic acid and methacrylic acid) or (meth)acrylic acid-based monomers that are derivatives thereof, and olefin-based monomers such as alicyclic or aliphatic olefins.

As the polystyrene resin, polystyrene in which the polymerization units are all polymerization units based on styrene (CH₂═CH—C₆H₅) is preferable. As the polystyrene resin, it is preferable to be polyvinylphenol from the viewpoint of suppressing recombination at both electrode side interfaces. The inclusion of a polar group-added benzene ring in the side chain, such as polyvinylphenol, forms a hydrogen bond between the polymers and promotes the formation of a phase separation structure by heating during drying.

As the aromatic ring-containing polymer described above, it is preferable that the polymer is an aromatic ring-containing polymer having a structure represented by the following Formula (I) or Formula (II). In particular, it is preferable to be a benzene-ring-containing polymer. It is also preferred that the benzene-ring-containing polymer is a non-conjugated polymer. Furthermore, it is also preferred that the non-conjugated polymer is a polymer containing a benzene ring as a side chain, such as polystyrene or a polystyrene derivative.

The aromatic ring-containing polymers having a structure represented by the following Formula (I) or Formula (II) are described in detail below.

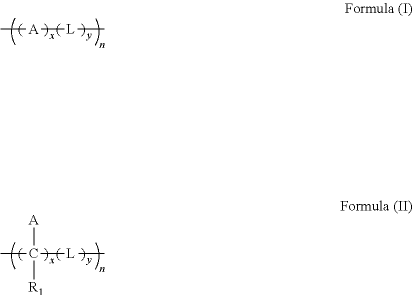

In the above Formula (I) and Formula (II), A represents an aromatic ring, wherein the aromatic ring includes an aromatic hydrocarbon ring and an aromatic heterocyclic ring. The aromatic ring may be monocyclic or fused; L represents a divalent linking group; x and y represent integers of 0 or 1 or more, provided that x and y do not become 0 at the same time, when x is 0, L contains an aromatic ring. n represents a degree of polymerization, which is 10 or more and 100,000 or less. R₁ represents a hydrogen atom or a substituent.

The aromatic ring represented by A includes an aromatic hydrocarbon ring and an aromatic heterocyclic ring, as described above. Each of these may be a single ring or a fused ring. From the viewpoint of conductivity or insulating property, it is preferable that the aromatic ring is an aromatic hydrocarbon ring. The number of atoms constituting the aromatic ring excluding substituents from the above Formula (I) and Formula (II) is preferably 20 or less, 12 or less is more preferable, and 6 or less is even more preferable from the viewpoint of solubility.

Examples of the aromatic hydrocarbon ring includes a benzene ring, and acene-based structures such as a naphthalene ring, a fluorene ring, an anthracene ring, a phenanthrene ring, a tetracene ring, a pentacene ring, a chrysene ring, a pyrene ring, a perylene ring, a coronene ring, a fluoranthene ring, a dibenzoanthracene ring, and a benzopyrene ring. Preferable rings are a benzene ring and a naphthalene ring.

Examples of the aromatic heterocyclic ring includes a pyridine ring, a pyrimidine ring, a triazine ring, a quinoline ring, an isoquinoline ring, an acridine ring, a thiophene ring, a furan ring, a pyrrole ring, a benzofuran ring, a benzothiophene ring, an indole ring, an imidazole ring, a pyrazole ring, an oxazole ring, an isoxazole ring, a thiazole ring, an isothiazole ring, a triazole ring, an oxadiazole ring, a thiadiazole ring, a dioxazole ring, a dithiazole ring, a tetrazole ring, and a pentazole ring.

From the viewpoint of making the organic semiconductor material (ink containing the organic semiconductor material) compatible by interaction, it is preferable that the aromatic ring represented by A is a benzene ring, and specifically, the structure of the following Formula (III) is mentioned.

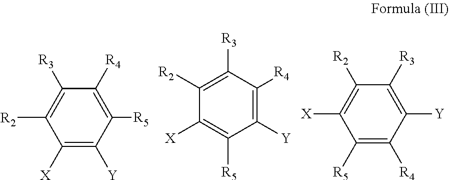

In the above Formula (III), X and Y represent hydrogen atom or a bonding position with a repeating unit L or A in the above Formula (I), or a bonding position with C (a carbon atom) in the above Formula (II).

R₁ to R₅ represent a hydrogen atom or a substituent. More specifically, R₁ to R₅ each independently represent a hydrogen atom, a deuterium atom, a halogen atom, a hydroxy group, a carboxyl group, a sulfo group, a alkoxycarbonyl group, a haloformyl group, a formyl group, an acyl group, an alkoxy group, a mercapto group, a cyano group, an alkyl group, an alkenyl group, an alkynyl group, an alkoxy group, an amino group, a carbamoyl group, a silyl group, a phosphine oxide group, an imide group, an aromatic imide ring group, an aromatic hydrocarbon ring group, an aromatic heterocyclic group, a non-aromatic hydrocarbon ring group, or a non-aromatic heterocyclic group, and these groups may further have a substituent.

In the above Formula (I), Formula (II), and Formula (III), examples of the alkyl group represented by R₁ to R₅ include a methyl group, an ethyl group, a propyl group, an isopropyl group, a (t)-butyl group, a pentyl group, a hexyl group, an octyl group, a dodecyl group, a tridecyl group, a tetradecyl group, a pentadecyl group, and a benzyl group.

Examples of the alkenyl group represented by R₁ to R₅ include those having one or more double bonds to the above-mentioned alkyl group are mentioned, and more specifically, a vinyl group, an allyl group, a 1-propenyl group, an isopropenyl group, a 2-butenyl group, a 1,3-butadienyl group, a 2-pentenyl group, and a 2-hexenyl group may be mentioned.

Examples of the alkynyl group represented by R₁ to R₅ include an ethynyl group, an acetylenyl group, a 1-propynyl group, a 2-propynyl group (propargyl group), a 1-butynyl group, a 2-butynyl group, a 3-butynyl group, a 1-pentynyl group, a 2-pentynyl group, a 3-pentynyl group, a 1-hexynyl group, a 2-hexynyl group, a 3-hexynyl group, a 1-heptynyl group, a 2-heptinyl group, a 5-heptinyl group, a 1-octynyl group, a 3-octynyl group, and a 5-octynyl group may be mentioned.

Examples of the aromatic hydrocarbon ring group (also referred to as an aryl group) represented by R₁ to R₅ include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group.

Examples of the aromatic heterocyclic group represented by R₁ to R₅ include a pyridyl group, a pyrimidinyl group, a furyl group, a pyrrolyl group, an imidazolyl group, a benzoimidazolyl group, a pyrazolyl group, a pyrazinyl group, a triazolyl group (for example, a 1,2,4-triazole-1-yl group, a 1,2,3-triazole-1)yl group), an oxazolyl group, a benzoxazolyl group, a thiazolyl group, an isooxazolyl group, an isothiazolyl group, a frazanyl group, a thienyl group, a quinolyl group, a benzofuryl group, a dibenzofuryl group, benzothienyl group, a dibenzothienyl group, an indolyl group, a carbazolyl group, a carborinyl group, a diazacarbazolyl group (indicating a ring group in which one of the carbon atoms constituting the carboline ring of the carbolinyl group is replaced with a nitrogen atom), a quinoxalinyl group, a pyridazinyl group, a triazinyl group, a quinazolinyl group, and a phtalazinyl group.

Examples of the non-aromatic hydrocarbon ring group represented by R₁ to R₅ include a monovalent group derived from a cycloalkyl group (e.g., a cyclopentyl group, a cyclohexyl group), a cycloalkoxy group (e.g., a cyclopentyloxy group, a cyclohexyl oxy group), a cycloalkylthio group (e.g., a cyclopentylthio group, a cyclohexylthio group), a tetrahydronaphthalene ring, a 9,10-dihydroanthracene ring, and a biphenylene ring.

Examples of the non-aromatic hydrocarbon ring group represented by R₁ to R₅ include a monovalent group derived from an epoxy ring, an aziridine ring, a thiirane ring, an oxetane ring, an azetidine ring, a thietane ring, a tetrahydrofuran ring, a dioxolane ring, a pyrrolidine ring, a pyrazolidine ring, an imidazolidine ring, an oxazolidine ring, a tetrahydrothiophene ring, a sulfolane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyran ring, a 1,3-tetrahydropyran ring, a 1,3-dioxane ring, a 1,4-dioxane ring, a trioxane ring, a tetrahydrothiopyran ring, a thiomorpholine ring, a thiomorpholine-1,1-dioxide ring, a pyranose ring, a diazabicyclo [2,2,2]-octane ring, a phenoxazine ring, a phenothiazine ring, an oxanthrene ring, a thioxanthene ring, and a phenoxathiine ring.

Examples of the alkoxy group represented by R₁ to R₅ include a methoxy group, an ethoxy group, a propoxy group, an isopropoxy group, a butoxy group, a pentyloxy group, a hexyloxy group, a 2-ethylhexyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, and octadecyloxy group.

Examples of the acyl group represented by R₁ to R₅ include an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and pyridylcarbonyl group.

Examples of the amino group represented by R₁ to R₅ include an amino group, an ethylamino group, a dimethylamino group, a butylamino group, a cyclopentylamino group, a 2-ethylhexylamino group, a dodecylamino group, an anilino group, a naphthylamino group, and a 2-pyridylamino group.

Examples of the silyl group represented by R₁ to R₅ include a trimethyl silyl group, a triisopropyl silyl group, a triphenylsilyl group, and a phenyldiethylsilyl group.

Examples of the phosphine oxide group represented by R₁ to R₅ include a diphenylphosphine oxide group, a ditorylphosphine oxide group, a dimethylphosphine oxide group, a dinaphthylphosphine oxide group, and a 9,10-dihydro-9-oxa-10-phosphaphenanthrene-10-oxide group.

Examples of a substituent that may be possessed by the group represented by R₁ to R₅ include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, a pentadecyl group, and a benzyl group); a cycloalkyl group (for example, a cyclopentyl group and a cyclohexyl group); an alkenyl group (for example, a vinyl group and an allyl group); an alkynyl group (for example, a propargyl group); an aromatic hydrocarbon group (also called an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenyl group); a heterocyclic group (for example, an epoxy ring, an aziridine ring, a thiirane ring, an oxetane ring, an azetidine ring, a thietan ring, a tetrahydrofuran ring, a dioxolan ring, a pyrrolidine ring, a pyrazolidine ring, an imidazolidine ring, an oxazolidine ring, a tetrahydropyran ring, a sulfolane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyran ring, a 1,3-dioxane ring, a1,4-dioxane ring, a trioxane ring, a tetrahydropyran ring, a thiomorpholin ring, a thiomorpholin-1,1-dioxane ring, a pyranose ring, and a diazabicyclo[2,2,2] -octane ring); an aromatic heterocyclic group (for example, a pyridyl group, a pyrimidinyl group, a furyl group, a pyrrolyl group, an imidazolyl group, a benzimidazolyl group, a pyrazolyl group, a pyrazinyl group, a triazolyl group (for example, 1,2,4-triazol-1-yl group, and 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, an diazacarbazolyl group (indicating a ring structure in which one of the carbon atoms constituting the carboline ring of the carbolinyl group is replaced with nitrogen atoms), a quinoxalinyl group, a pyridazinyl group, a triazinyl group, a quinazolinyl group, and a phthalazinyl group); a halogen atom (for example, a chlorine atom, a bromine atom, an iodine atom, and a fluorine atom); an alkoxy group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, a hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); an acyl group (for example, an acetyl group, an ethyl carbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethyhexylcarbonylamino group, an octylcarbonylamino group, a dodecylcarbonylamino group, a phenylcarbonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethymexylaminocarbonyl group, a dodecylaminocarbonyl group, a phenylaminocarbonyl group, a naphthylaminocarbonyl group, and a 2-pyridylaminocarbonyl group); a sulfinyl group (for example, a methylsulfinyl group, an ethylsufinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group or an arylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a dodecylamino group, an anilino group, a diarylamono group (for example, a diphenylamino group, a dinaphthylamino group, and a phenylnaphthylamino group, a naphthylamino group, and a 2-pyridylamino group); a cyano group; a nitro group; a hydroxyl group; a mercapto group; an alkylsilyl group or an arylsilyl group (for example, a trimethylsilyl group, a triethylsilyl group, a (t)-butyldimethylsilyl group, a triisopropylsilyl group, a (t)-butyldiphenylsilyl group, a triphenylsilyl group, a trinaphthylsilyl group, a 2-pyridylsilyl group); an alkylphosphino group or an arylphosphino group (for example, a dimethylphosphino group, a diethylphosphino group, a dicyclohexylphosphino group, a methylphenylphosphino group, a diphenylphosphino group, a dinaphthylphosphino group, a di(2-pyridyl)phosphino group); an alkylphosphoryl group or an arylphosphoryl group (for example, a dimethylphosphoryl group, a diethylphosphoryl group, a dicyclohexylphosphoryl group, a methylphenylphosphoryl group, a diphenylphosphoryl group, a dinaphthylphosphoryl group, a di(2-pyridyl)phosphoryl group), a alkylthiophosphoyl group or an arylthiophosphoryl groups (for example, a dimethylthiophosphoryl group, a diethylthiophosphoryl group, a dicyclohexylthiophosphoryl group, a methylphenylthiophosphoryl group, a diphenylthiophosphoryl group, a dinaphthylthiophosphoryl group, and a di(2-pyridyl)thiophosphoryl group.

These substituents may be further substituted by the above substituents, or they may be fused with each other to further form a ring.

In the above Formula (I) and Formula (II), L represents a divalent linking group and may be an alkylene group, an alkenylene group, a carbonyl group, an ether group, an imino group, an imide group, an amide group, an o-phenylene group, an m-phenylene group, a p-phenylene group, a sulfonyl group, a sulfide group, a thioester group, a silyl group, a phosphine oxide group, or a divalent aromatic heterocyclic group, and may have further substituent groups.

In the above Formula (I) and Formula (II), the alkylene group represented by L includes, for example, a methylene group, an ethylene group, a trimethylene group, a propylene group, a butylene group, a butane-1,2-diyl group, and a hexylene group.

The alkenylene group represented by L is, for example, a vinylene group, a propenylene group, a butenylene group, a pentenylene group, a 1-methylvinylene group, a 1-methylpropenylene group, a 2-methylpropenylene group, a 1-methylpentenylene group, a 3-methylpentenylene group, a 1-ethylvinylene group, a 1-ethylpropenylene group, a 1-ethylbutenylene group, and a 3-ethylbutenylene group.

The amide group represented by L is, for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group.

The divalent aromatic heterocyclic group represented by L is, for example, a divalent group derived from those listed as the aromatic heterocyclic group represented by R₁ to R₅ in the above Formula (I), Formula (II), and Formula (III).

In Formula (I) and Formula (II), x and y represent 0 or an integer of 1 or more. n represents a degree of polymerization, which is 10 or more and 100,000 or less. These repeating structures may be sequentially polymerized, such as A-L-A-L repeats, or block polymerized, such as A-A-L-L and A-L-L-L, for example.

When both or either of x and y is 2 or more, the two or more A, L and R₁ to R₅ may be the same or different from each other.

A specific example of the resin A is a polymer having the following structure. In the following structural formulas, n, x and y are integers, the degree of polymerization n is in the range of 10 to 100, and the copolymerization ratio is preferably in the range of x:y=1:99 to 99:1.

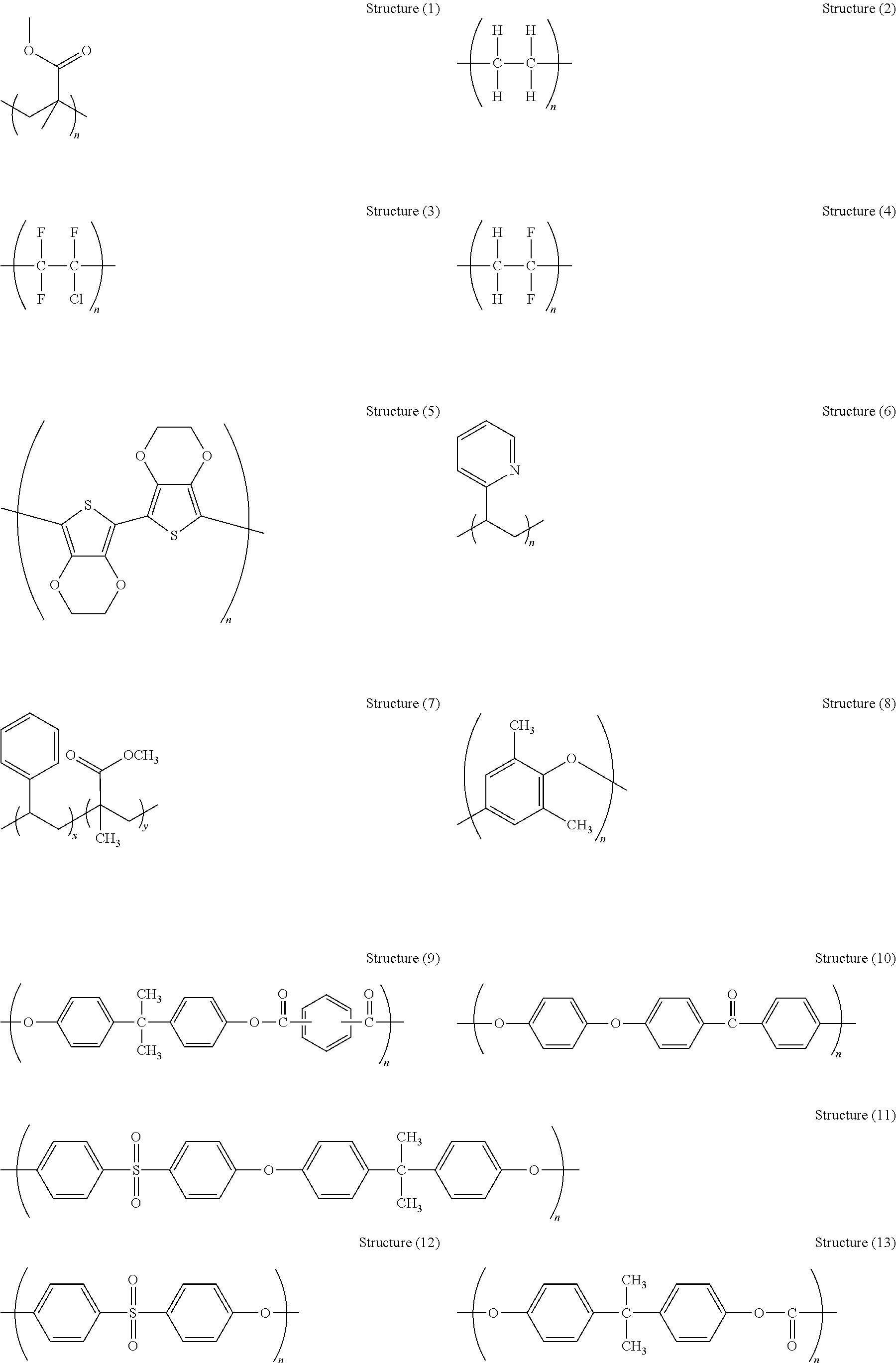

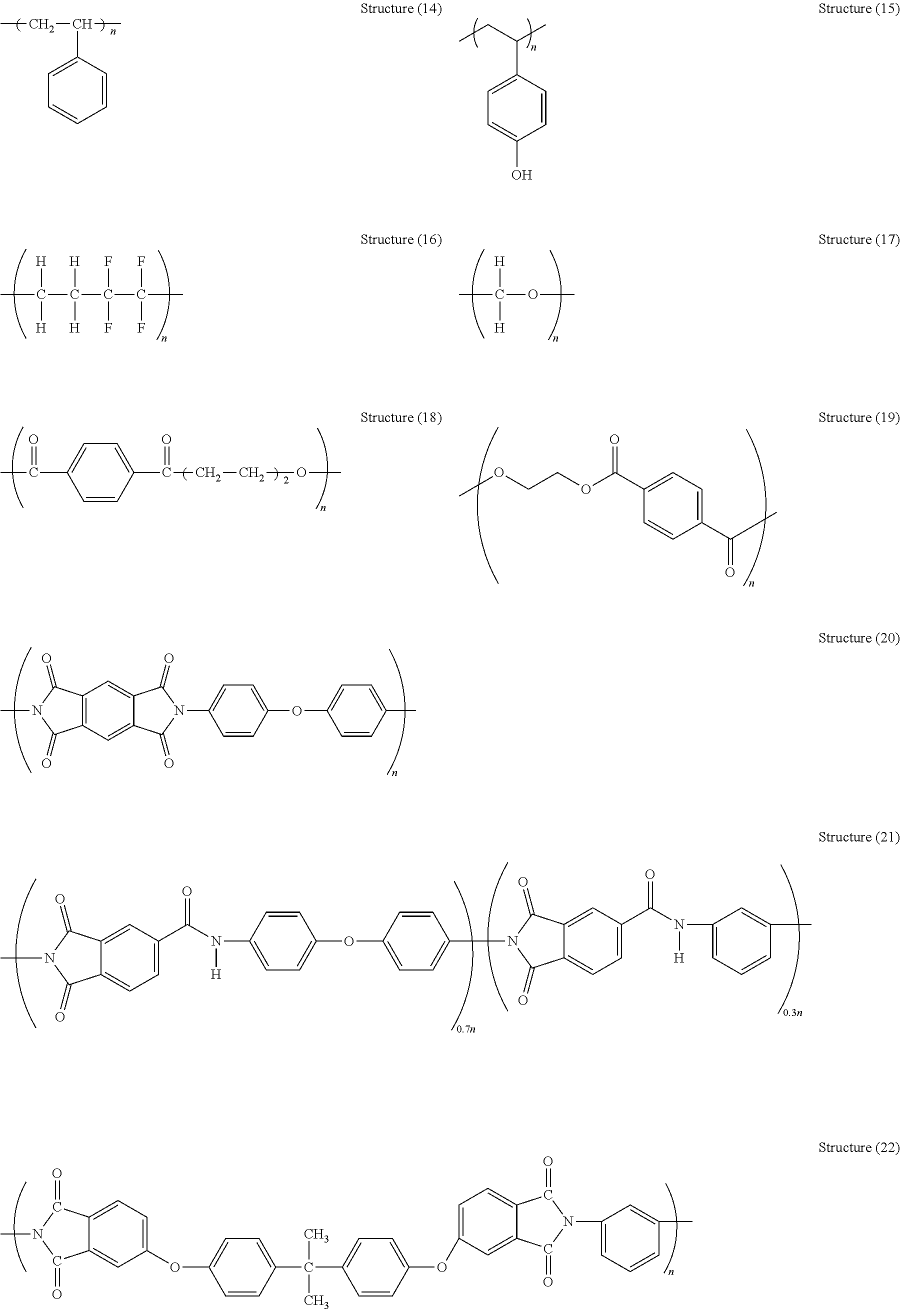

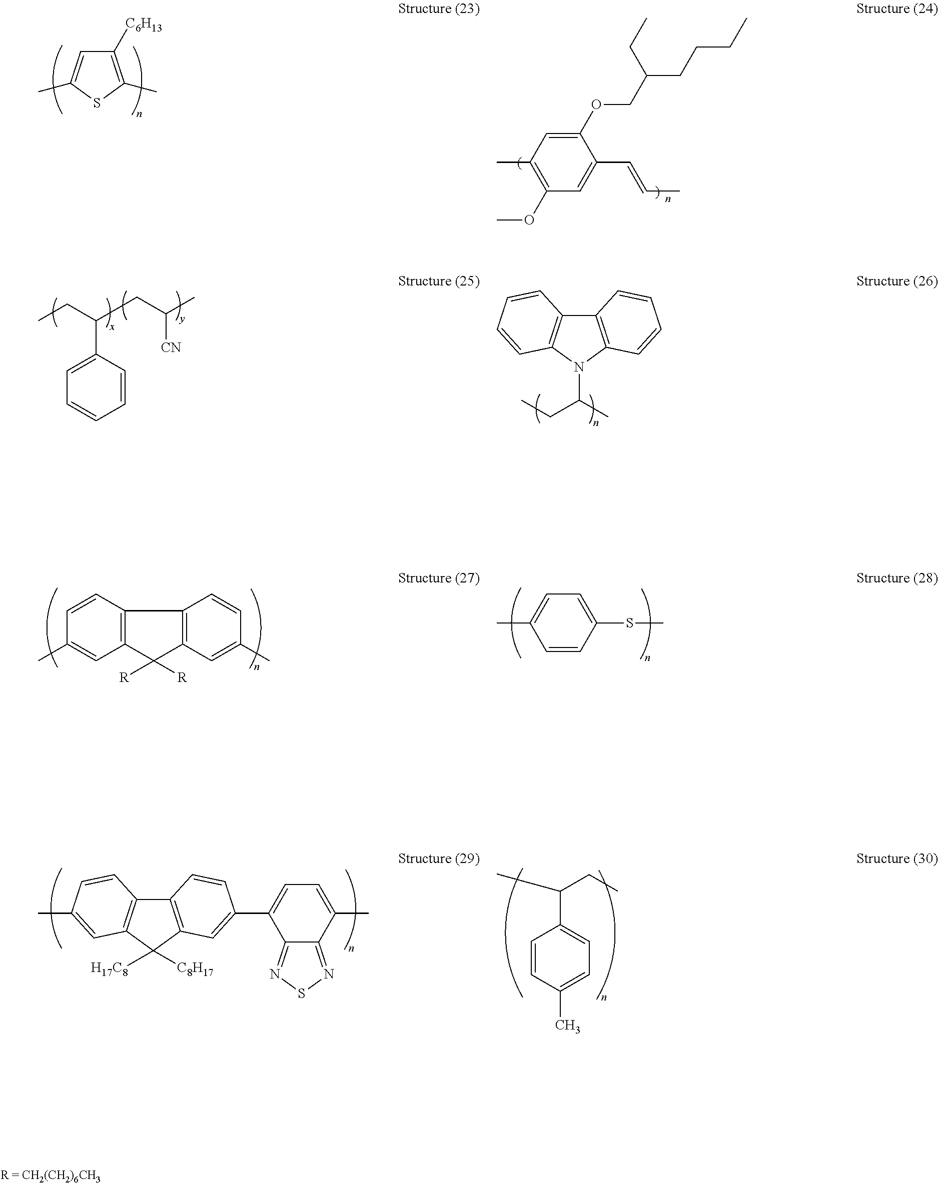

The weight average molecular weight of the resin A is adjusted appropriately according to the type of the resin A and the ink, and the layer thickness t1 of the ink penetrating layer 41. The weight average molecular weight of the resin A is preferably smaller than, for example, the weight average molecular weight of the resin B that mainly constitutes the ink insoluble layer 42 described below.

For example, when the resin A is a polystyrene resin, a weight average molecular weight of the resin A is preferably in the range of 1×10³ to 1000×10³, more preferably in the range of 50×10³ to 400×10³, and even more preferably in the range of 50×10³ to 350×10³, from the viewpoint that the permeability of the ink may be appropriately controlled. It is believed that the weight average molecular weight in this range enables appropriate control of the penetration and diffusion of the ink in the ink penetrating layer 41.

The weight average molecular weight refers to the weight average molecular weight measured by gel permeation chromatography (GPC) using dimethylformamide as the solvent and converted to polystyrene. If the weight average molecular weight cannot be measured using dimethylformamide, tetrahydrofuran is used. If the weight average molecular weight cannot be measured using dimethylformamide, hexafluoroisopropanol is used. If the weight average molecular weight cannot be measured using hexafluoroisopropanol, 2-chloronaphthalene is used.

The ink penetrating layer 41 may comprise only the resin A, or may contain optional components. One type of resin A may be used alone, and two or more types may be used together. The optional components include a resin other than the resin A, a charge transport compound (a host compound for the organic semiconductor material), a surfactant, and other additives. However, from the viewpoint of ink penetration, it is preferable that the ink penetrating layer 41 does not contain any resin other than the resin A.

Other additives include, for example, halogen elements such as bromine, iodine, and chlorine, and halogenated compounds, complexes, and salts of alkali metals, alkaline earth metals, and transition metals such as Pd, Ca, and Na. Although the amount of the other additives may be determined arbitrarily, it is preferable that the amount of the other additives is 1000 mass ppm or less relative to the total amount of the ink penetrating layer.

The charge transport compound may be used alone or in combination with a plurality of other compounds. By using a plurality of charge transport compounds, it is possible to adjust the charge transfer, and the organic semiconductor device may be made highly efficient.

From the viewpoint of driving stability, the charge transport compound should be able to exist stably in all active species states of the cation radical state, the anion radical state, and the excited state, and should not undergo chemical changes such as decomposition or addition reactions. Furthermore, it is preferable that the charge transport compound molecules do not migrate at the angstrom level in the layer with the passage of electric current.

For the charge transport compound of the present invention, it is preferable that the value of electron mobility/hole mobility, which is the ratio of the electron mobility [cm²/(Vs)] and the hole mobility [cm²/(Vs)], is within the range of 0.5 to 2.0 in terms of luminous [cm²/(Vs)] efficiency.

The electron mobility [cm²/(Vs)] and hole mobility [cm²/(Vs)] are measured by measuring the current density and the applied voltage of the electron-only device (configuration example: ITO anode/calcium layer/charge transport compound layer/potassium fluoride layer/aluminum cathode), and the hole-only device (configuration example: ITO anode/charge transport compound layer/α-NPD layer/aluminum cathode) fabricated respectively. The current density-voltage characteristics of these devices are measured and made into a double logarithmic graph, and the current density and applied voltage obtained therefrom and the space charge limiting current formula may be used to determine the current density.

The space charge limiting current formula is J=(9/8) εᵣε₀ μ (V²/L³). In the formula, J is a current density, εᵣ is a dielectric constant of a charge transport compound layer, ε₀ is a dielectric constant of the vacuum,μ is an electron mobility [cm²/(Vs)] or a hole mobility [cm²/(Vs)], L is a thickness of the charge transport compound layer, and V is an applied voltage.

As the charge transport compound, a charge transport compound known in organic semiconductor devices may be used. Specifically, the compounds described in the following document may be mentioned, but the present invention is not limited thereto.

Japanese patent application publication (JP-A) Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837, 2016-178274; US Patent Application Publication (US) Nos. 2003/0175553, 2006/0280965, 2005/0112407, 2009/0017330, 2009/0030202, 2005/0238919; WO 2001/039234, WO 2009/021126, WO 2008/056746, WO 2004/093 207, WO 2005/089025, WO 2007/063796, WO 2007/063754, WO 2004/107822, WO 2005/030900, WO 2006/114966, WO 2009/086028, WO 2009/003898, WO 2012/023947, JP-A 2008-074939, JP-A 2007-254297, EP 2034538, WO 2011/055933, WO 2012/035853, JP-A No. 2015-38941, and US 2017/056814 may also be suitably used.

As the charge transport compound, it is preferable that the compound has a structure represented by the following Formula (1).

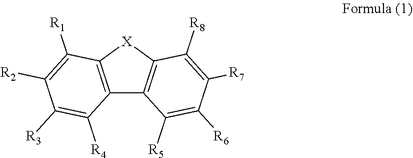

In Formula (1), X represents O, S, or NR₉. R₉ represents a hydrogen atom, a deuterium atom, an alkyl group, an alkenyl group, an alkynyl group, an aralkyl group, an aromatic hydrocarbon ring group, an aromatic heterocyclic group, a non-aromatic hydrocarbon ring group, a non-aromatic heterocyclic group, or a substituent represented by the following Formula (2). R₁ to R₈ each respectively represent a hydrogen atom, a deuterium atom, a halogen atom, a cyano group, an alkyl group, an alkenyl group, an alkynyl group, an alkoxy group, an acyl group, an amino group, a silyl group, a phosphine oxide group, an aromatic hydrocarbon ring group, an aromatic heterocyclic group, a non-aromatic hydrocarbon ring group, a non-aromatic heterocyclic group, or a substituent represented by the following Formula (2). At least one of R₁ to R₉ represents a substituent represented by the Formula (2) below. R₁ to R₉ may be the same or different from each other and may have further substituents.

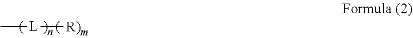

In Formula (2), L represents an alkylene group, an alkenylene group, an o-phenylene group, an m-phenylene group, a p-phenylene group, an amide group, or a divalent aromatic heterocyclic group, and may have a substituent. n represents an integer of 1 to 8, and when n represents an integer of 2 or more, the two or more Ls may be the same or different from each other. R represents an alkyl group having 1 to 20 carbon atoms, an alkoxy group having 1 to 20 carbon atoms, an alkyl fluoride group having 1 to 20 carbon atoms, an aromatic hydrocarbon ring group, an aromatic heterocyclic group, or a non-aromatic hydrocarbon ring group. m represents an integer of 1 to 3. At least one of L and R represents an alkylene group or an alkyl group. When there is a plurality of substituents represented by Formula (2), L and R may be the same or different from each other, but they are not connected to each other to form a ring.

The substituent represented by R₁ to R₉ in the above Formula (1) is synonymous with R₁ to R₆ in the above Formulas (I) to (II). In addition, the linking group represented by L in the above Formula (2) is synonymous with L in the above Formulas (I) and (II).

In the above Formula (2), an alkyl group having 1 to 20 carbon atoms represented by R is, for example, a group having 1 to 20 carbon atoms among those listed as an alkyl group represented by R₁to R₉ in the above Formula (1).

The alkyl fluoride group having 1 to 20 carbon atoms represented by R is, for example, a group in which a hydrogen atom of the above-mentioned alkyl group having 1 to 20 carbon atoms is replaced by a fluorine atom.

The alkoxy group having 1 to 20 carbon atoms represented by R is, for example, a group having 1 to 20 carbon atoms among those listed as an alkoxy group represented by R₁ to R₉ in the above Formula (1).

The aromatic hydrocarbon ring group, aromatic heterocyclic ring group or non-aromatic hydrocarbon ring group represented by R is, for example, the same as the aromatic hydrocarbon ring group, aromatic heterocyclic ring group or non-aromatic hydrocarbon ring group represented by R₁ to R₉ in the above Formula (1).

In the above Formula (2), the substituents that L and R may further have are, for example, the same as the substituents that R₁ to R₉ may have in the above Formula (1).

As the compound having the structure represented by Formula (1), among the substituents represented by Formula (2), those in which at least one L is an alkylene group having 1 to 6 carbon atoms are preferable. Further, among the substituents represented by Formula (2), those in which at least one R is an alkyl group having 1 to 6 carbon atoms are preferable.

Specific examples of the compound having the structure represented by Formula (1) of the present invention are shown below, but are not limited thereto.

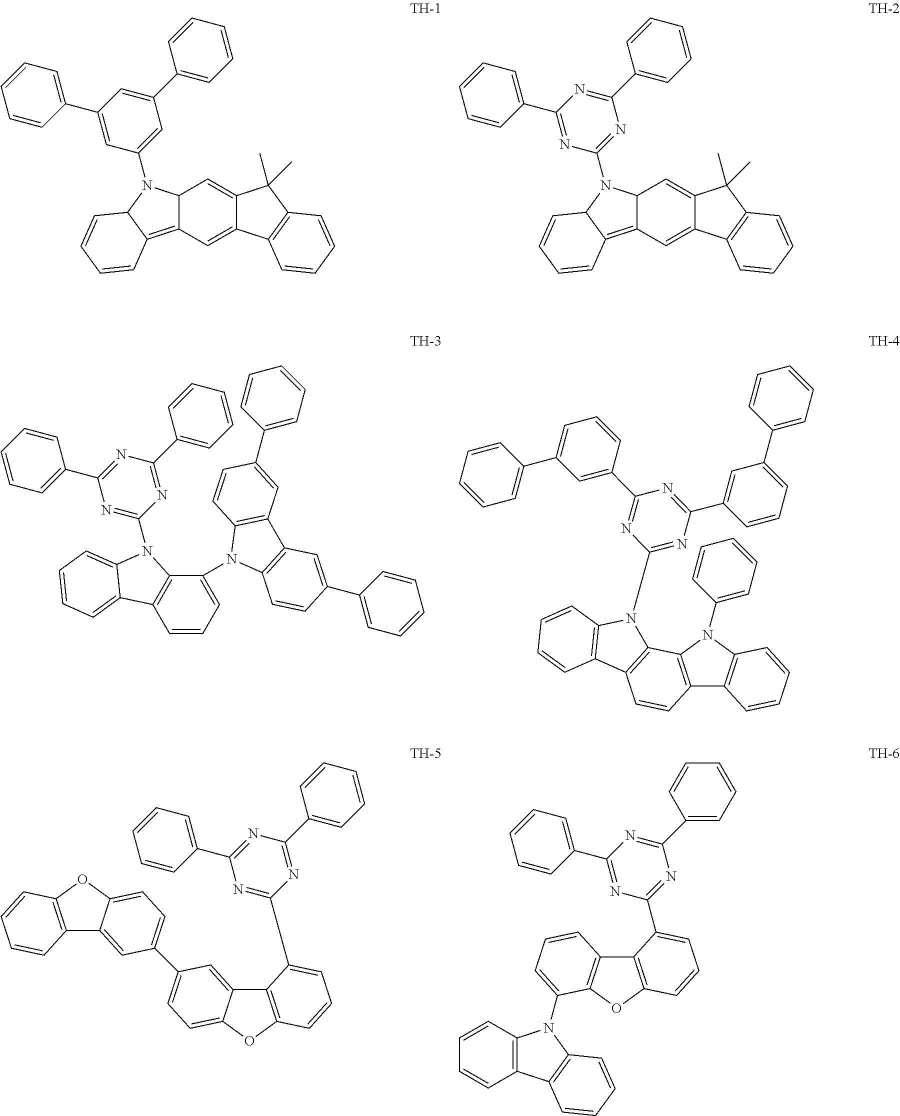 [SMILES: CC1(C)C2=CC3C(=C4C=CC=CC4N3c3cc(-c4ccccc4)cc(-c4ccccc4)c3)C=C2c2ccccc21 ; CC1(C)C2=CC3C(=C4C=CC=CC4N3c3nc(-c4ccccc4)nc(-c4ccccc4)n3)C=C2c2ccccc21 ; c1ccc(-c2ccc3c(c2)c2cc(-c4ccccc4)ccc2n3-c2cccc3c4ccccc4n(-c4nc(-c5ccccc5)nc(-c5ccccc5)n4)c23)cc1 ; c1ccc(-c2cccc(-c3nc(-c4cccc(-c5ccccc5)c4)nc(-n4c5ccccc5c5ccc6c7ccccc7n(-c7ccccc7)c6c54)n3)c2)cc1 ; c1ccc(-c2nc(-c3ccccc3)nc(-c3cccc4oc5ccc(-c6ccc7oc8ccccc8c7c6)cc5c34)n2)cc1 ; c1ccc(-c2nc(-c3ccccc3)nc(-c3cccc4oc5c(-n6c7ccccc7c7ccccc76)cccc5c34)n2)cc1]

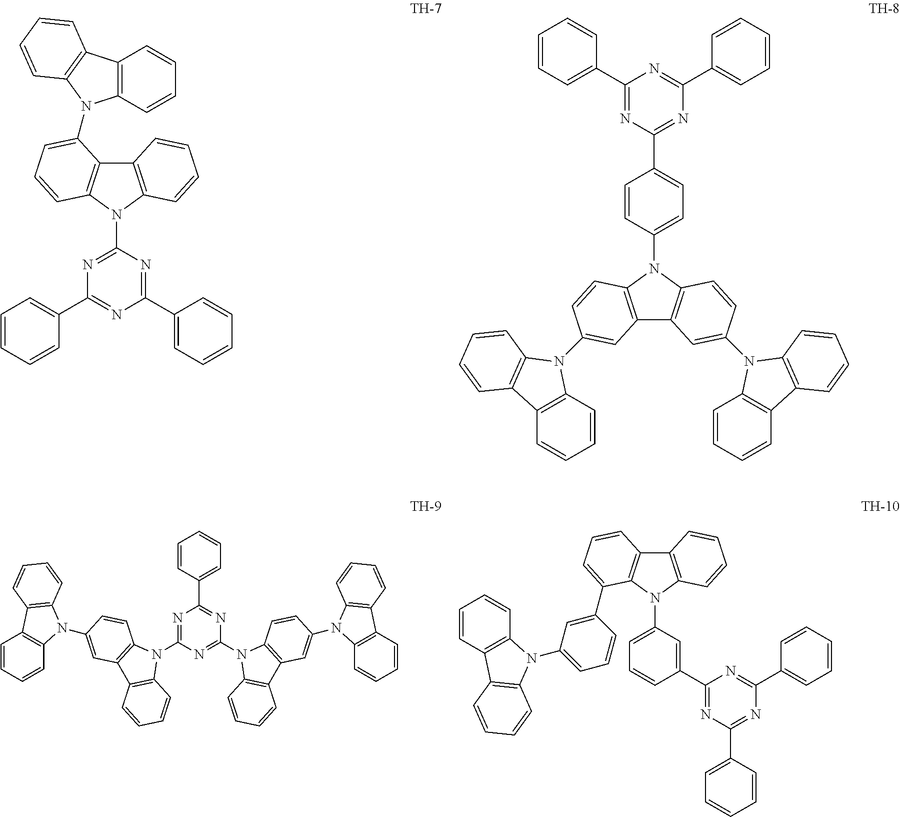 [SMILES: c1ccc(-c2nc(-c3ccccc3)nc(-n3c4ccccc4c4c(-n5c6ccccc6c6ccccc65)cccc43)n2)cc1 ; c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2nc(-c3ccccc3)nc(-c3cccc(-n4c5ccccc5c5cccc(-c6cccc(-n7c8ccccc8c8ccccc87)c6)c54)c3)n2)cc1]

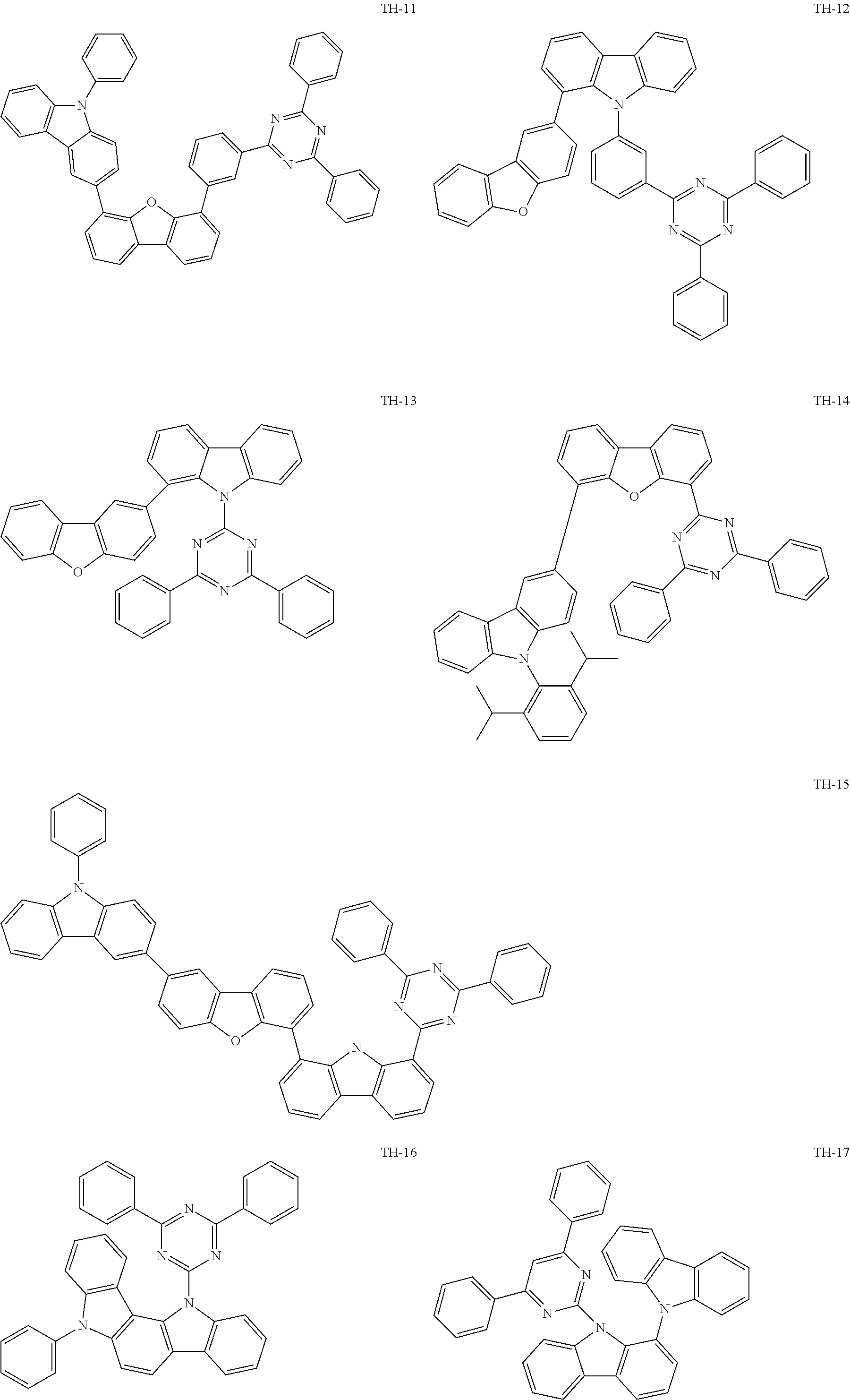

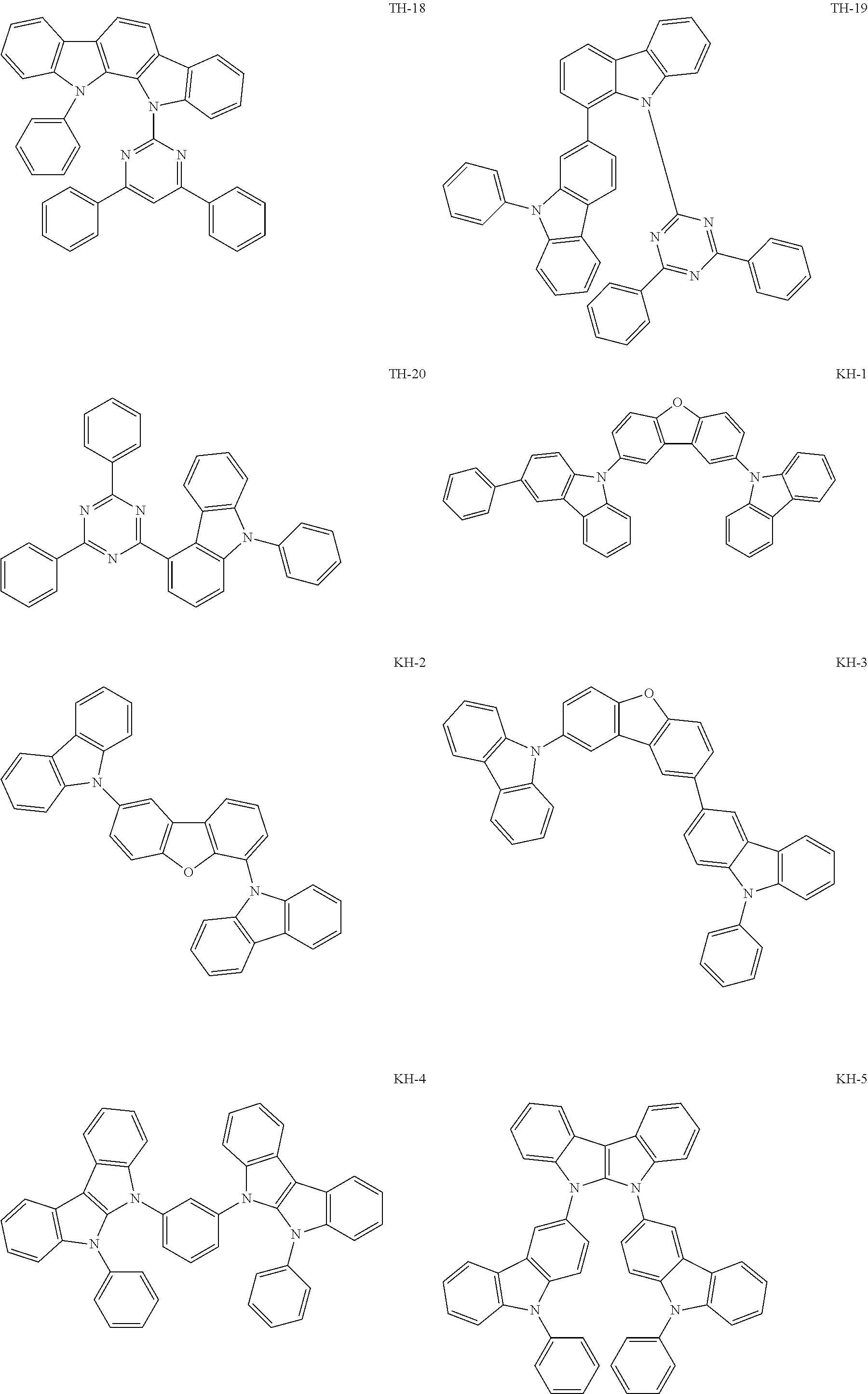

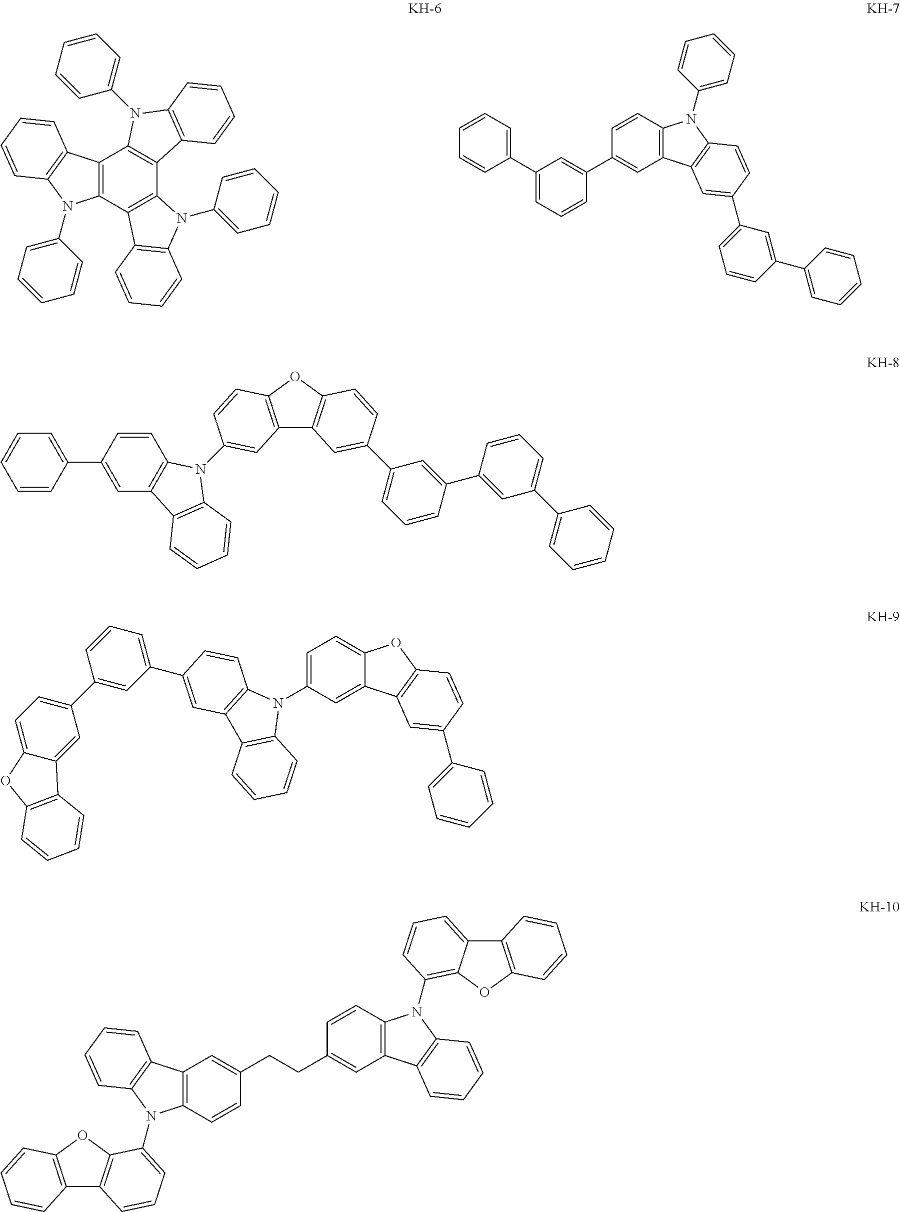 [SMILES: c1ccc(-n2c3ccccc3c3c2c2c4ccccc4n(-c4ccccc4)c2c2c4ccccc4n(-c4ccccc4)c32)cc1 ; c1ccc(-c2cccc(-c3ccc4c(c3)c3cc(-c5cccc(-c6ccccc6)c5)ccc3n4-c3ccccc3)c2)cc1 ; c1ccc(-c2cccc(-c3cccc(-c4ccc5oc6ccc(-n7c8ccccc8c8cc(-c9ccccc9)ccc87)cc6c5c4)c3)c2)cc1 ; c1ccc(-c2ccc3oc4ccc(-n5c6ccccc6c6cc(-c7cccc(-c8ccc9oc%10ccccc%10c9c8)c7)ccc65)cc4c3c2)cc1 ; c1ccc2c(c1)oc1c(-n3c4ccccc4c4cc(CCc5ccc6c(c5)c5ccccc5n6-c5cccc6c5oc5ccccc56)ccc43)cccc12]

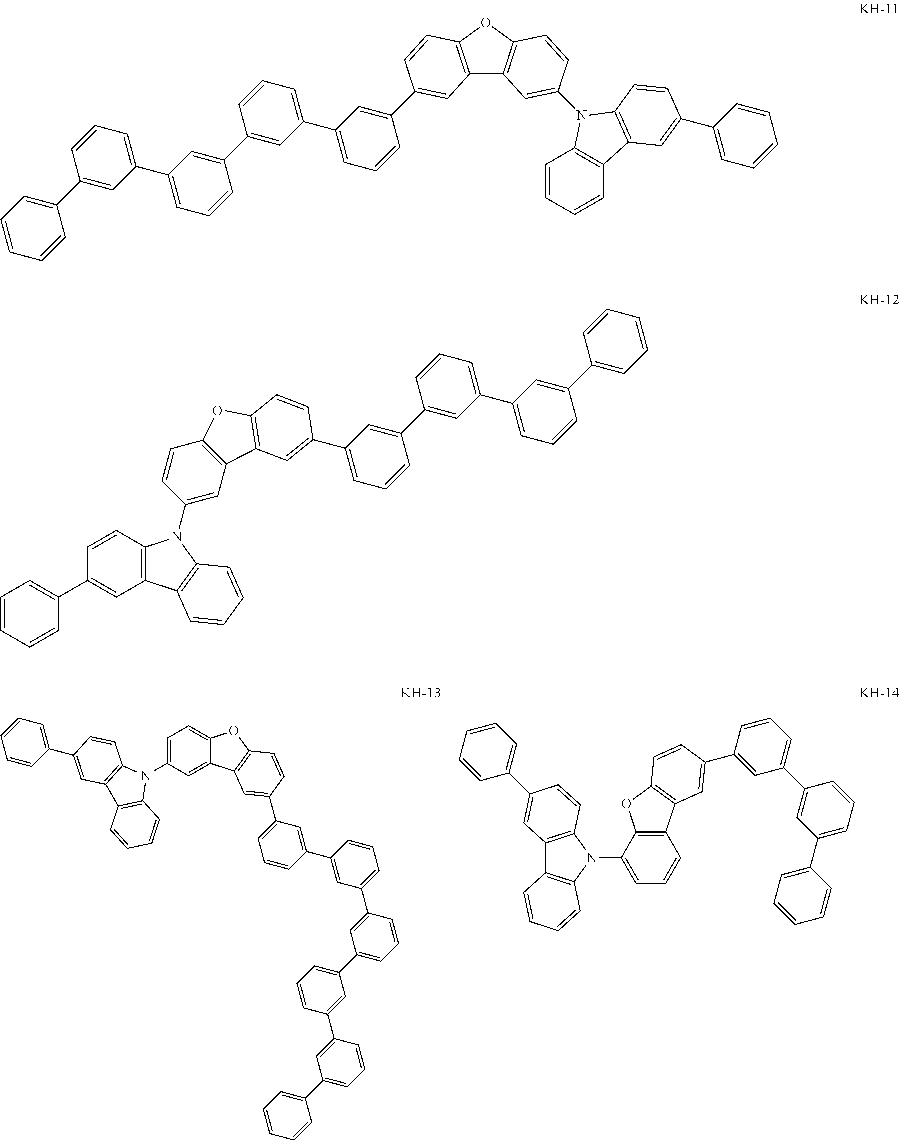 [SMILES: c1ccc(-c2cccc(-c3cccc(-c4cccc(-c5cccc(-c6ccc7oc8ccc(-n9c%10ccccc%10c%10cc(-c%11ccccc%11)ccc%109)cc8c7c6)c5)c4)c3)c2)cc1 ; c1ccc(-c2cccc(-c3cccc(-c4cccc(-c5ccc6oc7ccc(-n8c9ccccc9c9cc(-c%10ccccc%10)ccc98)cc7c6c5)c4)c3)c2)cc1 ; c1ccc(-c2cccc(-c3cccc(-c4cccc(-c5cccc(-c6cccc(-c7ccc8oc9ccc(-n%10c%11ccccc%11c%11cc(-c%12ccccc%12)ccc%11%10)cc9c8c7)c6)c5)c4)c3)c2)cc1 ; c1ccc(-c2cccc(-c3cccc(-c4ccc5oc6c(-n7c8ccccc8c8cc(-c9ccccc9)ccc87)cccc6c5c4)c3)c2)cc1]

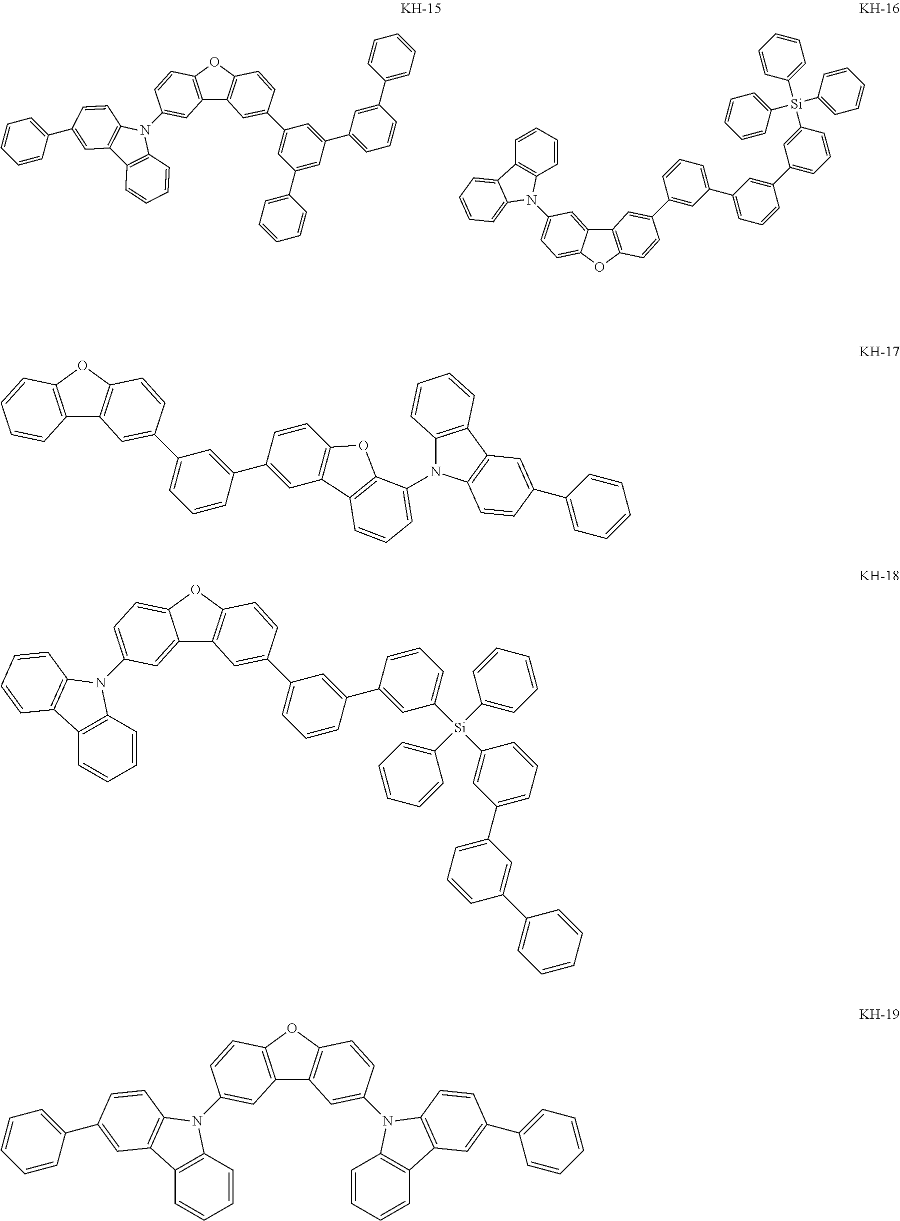

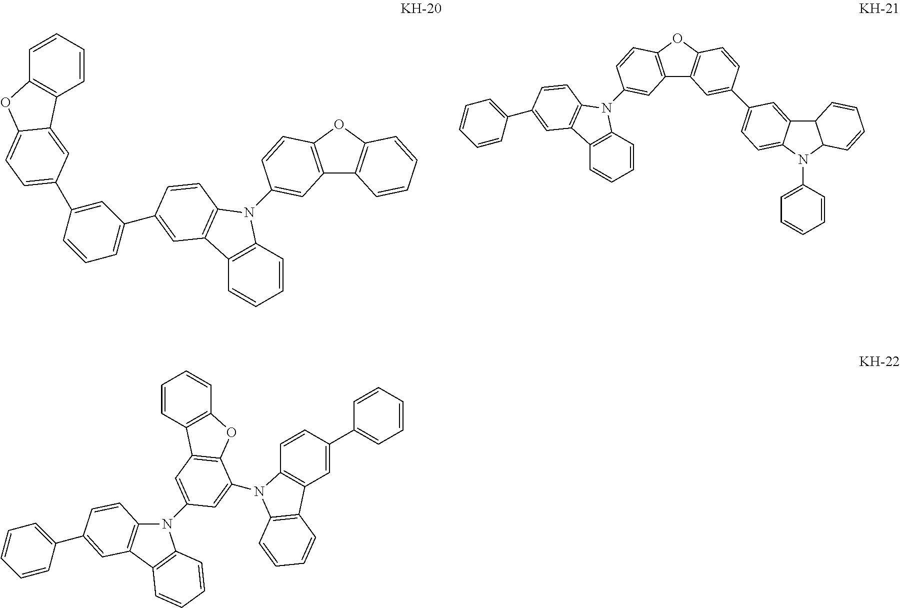 [SMILES: c1cc(-c2ccc3oc4ccccc4c3c2)cc(-c2ccc3c(c2)c2ccccc2n3-c2ccc3oc4ccccc4c3c2)c1 ; C1=CC2c3cc(-c4ccc5oc6ccc(-n7c8ccccc8c8cc(-c9ccccc9)ccc87)cc6c5c4)ccc3N(c3ccccc3)C2C=C1 ; c1ccc(-c2ccc3c(c2)c2ccccc2n3-c2cc(-n3c4ccccc4c4cc(-c5ccccc5)ccc43)c3oc4ccccc4c3c2)cc1]

From the viewpoint of ink penetration, the ink penetrating layer 41 should have a high affinity with the ink to be used. For example, if the SP value of the constituent material of the ink penetrating layer 41 is indicated by SP(M1) and the SP value of the ink used for manufacturing the organic semiconductor device is indicated by SP(I), it is preferable that the absolute value of the difference between the two indicated by |SP(M1)-SP(I)| is 3.0 (J/cm³)^{1/2} or less.

The SP value is referred to as a solubility parameter. The SP values of various compounds in the present invention may be obtained from literature, for example, the Dictionary of Plastics Materials (http://www.plastics-material.com/solubility-parameters (SP values) of plasticizers and solvents/). Alternatively, the SP value may be determined by molecular dynamics (MD) or other methods. For example, the SP value may be determined from the molecular attraction constant, i.e., from the molecular attraction constant (G) and molar volume (V) of each functional group or atomic group constituting the molecule of the compound, by the equation: SP value=EGN (D. A. Small, J Appl. Chem., 3, 71, (1953), K. L. Hoy, J. Paint Technol., 42, 76 (1970)).

The ink penetrating layer and the ink usually comprise a plurality of compounds. In such a case, the SP value of the constituent materials may be obtained by weighted averaging from the SP value of each component contained by the constituent materials and the composition of the components. In this specification, SP values are rounded off to the second decimal place and expressed to the first decimal place.

When the value of |SP(M1)-SP(I)| is 3.0 (J/cm³)^{1/2} or less, the ink penetrating layer 41 is capable of sufficiently penetrating the ink. It is more preferable that the value of |SP(M1)-SP(I)| is 2.3 (J/cm³)^{1/2} or less.

The SP values of the solvent and the solute in the ink are close to each other, and in many cases, the solvent accounts for most of the composition of the ink, for example, 98 mass % or more, so in such cases, when the SP value of the solvent is SP(S), and this is replaced by the SP value of the ink SP(I), and the absolute value of the difference from SP(M1) may be used. In other words, since |SP(M1)-SP(I)| is nearly equal to |SP(M1)-SP(S)|, it is preferable that |SP(M1)-SP(S)| is 3.0 (J/cm³)^{1/2} or less, and 2.3 (J/cm³)^{1/2} or less is more preferable.

The ink insoluble layer 42 has a function of preventing penetration of the ink from the ink penetrating layer 41 to the electrode 3 side by being insoluble in the ink. The ink contains an organic semiconductor material and a solvent as essential components as described below. In order to have the above-described function, the ink insoluble layer 42 includes, as a main component, a resin having sufficiently low ink permeability compared to the resin A (hereinafter referred to as “resin B”). The ink insoluble layer 42 preferably contains a resin that has no ink permeability (hereinafter referred to as a “resin B”). The term “sufficiently low ink permeability of resin B compared to resin A” means that the ink permeability of resin B is low enough to prevent ink penetration to electrode 3 at a layer thickness t2 of the ink insoluble layer 42.

Like the resin A, the resin B is preferably an insulating resin, and a resin in which the main chain having higher stability is composed of carbon atoms is preferable. It is preferred that the resin B is insoluble in the ink. Being insoluble in the ink specifically means being able to satisfy an index based on the SP value described below.

When the ink insoluble layer 42 is formed as a layer mainly composed of the resin B, for example, it is preferable that the resin B is soluble in a suitable solvent different from the ink, for example, an aprotic polar solvent, so that it may be formed by a coating method. Specifically, the solubility of the resin B in 1 g of N,N-dimethylformamide at 25° C. is preferably 0.5 mg or more, more preferably 1.0 mg or more, and still more preferably 2.0 mg or more.

As the resin B, a resin that tends to take a dense structure, such as a high atomic density in a polymerization unit, a long molecular chain, a molecule having a cross-linked structure, or a molecular chain being intertwined, is preferred. As the resin B, for example, a resin of the same type as the resin A and having a higher weight average molecular weight than the resin A is mentioned.

For example, when the polystyrene resin is used as the resin B, the weight average molecular weight is preferably in the range of 100×10³ to 3000×10³, 360×10³ to 1500×10³ is more preferable, and 400×10³ to 1000×10³ is even more preferable from the viewpoint of sufficiently low ink penetration.

As the resin B, a cross-linked resin is preferred, and a resin having a high crosslinking density is preferred. Such a resin B includes, for example, a melamine cross-linked resin, an epoxy cross-linked resin, and a phenol resin.

As the resin B, a resin including an interpenetrating polymer network (IPN: Interpenetrating Polymer Network) structure, which is a structure in which heterogeneous polymers are intertwined with each other (hereinafter also referred to as “resin B1”) is preferable. The interpenetrating polymer network structure is characterized as a state in which two or more polymer chains are intertwined with each other to form a mesh-like structure without chemical bond formation. It is distinguished from a simple polymer blend or copolymer. The interpenetrating polymer network structure is characterized by the fact that it swells in a solvent but does not elute, and that while phase separation generally occurs in the case of heterogeneous polymers, but the phase separation is difficult to occur with IPN (Reference: Journal of Life Science and Technology, vol. 8, no. 1, pp. 144-147, 2006).

The resin B1 may be made, for example, by mixing a polymer compound and a monomer (radical polymerizable compound) of a type different from the monomer pertaining to the polymerization unit of the polymer compound, and polymerizing the monomer under appropriate conditions. A polymerization initiator may be added according to the kind of monomer used. When a monomer such as cyanoacrylate, which reacts with moisture in the air and hardens, is used, a polymerization initiator is not essential.

The polymer compound includes, for example, a polystyrene resin, an epoxy resin, and a polyester resin. The monomer includes (meth)acrylic acid or a (meth)acrylic acid monomer derivative that is a derivative thereof. The mixing ratio (mass %) of the monomer to 100 mass % of the polymer compound is, for example, 0.1 to 50 mass %, and 0.1 to 20 mass % is more preferable.

As the resin B 1, a resin manufactured by using a polystyrene resin as a polymer compound and a cyanoacrylate as a monomer to be mixed therewith is preferable. The cyanoacrylate includes methyl 2-cyanoacrylate, ethyl 2-cyanoacrylate, n-butyl cyanoacrylate, and 2-octyl cyanoacrylate.

As the resin B, a resin having a high atomic density in the polymerization unit is preferred, and as such a resin, a resin containing tetraphenylbenzidine or a derivative thereof as the main polymerization unit (hereinafter also referred to as “resin B2”) may be exemplified. Examples of the derivative of the tetraphenylbenzidine include compounds in which the hydrogen atoms bonded to the four benzene rings are substituted with hydrocarbon groups or functional groups. The hydrocarbon group includes an alkyl group having a carbon number of 1 to 8, and an n-butyl group is preferred. The functional group includes a hydroxy group, an ester group, and an amide group.

As the resin B2, for example, a resin (PTPD) having a polymerization unit based on N,N′-bis(4-butylphenyl)-N,N′-bis(phenyl)-benzidine (TPD) as a repeating unit is preferred.

The ink insoluble layer 42 may comprise only the resin B, and may also contain optional components. One type of resin B may be used alone, and two or more types may be used together. The optional components include a resin other than the resin B, a charge transport compound, a surfactant, and other additives. However, from the viewpoint of maintaining low permeability to the ink, it is preferred that the ink insoluble layer 42 does not contain any resin other than the resin B. As the other additives, the same additives as described for the ink penetrating layer 41 may be used in the same content.

As the charge transport compound, a charge transport compound similar to that described for the ink penetrating layer 41 may be used. When the ink insoluble layer 42 contains the charge transport compound, the amount of the charge transport compound may be the same as in the case of the ink penetrating layer 41.

The ink insoluble layer 42 should have a property of low permeability of the ink, that is, it should have a low affinity with the ink. For example, when the SP value of the constituent material of the ink insoluble layer 42 is indicated by SP(M2) and the SP value of the ink used for manufacturing the organic semiconductor device is indicated by SP(I), it is preferable that the absolute value of the difference between the two indicated by |SP(M2)-SP(I)| should be 3.1 (J/cm³)^{1/2} or more.

When |SP(M2)-SP(I)| is 3.1 (J/cm³)^{1/2} or more, the ink insoluble layer 42 has sufficiently low ink permeability and generally does not allow the ink to reach the electrode 3. When |SP(M2)-SP(I)| is (J/cm³)^{1/2} or more, it is more preferable.

The SP values of the solvent and the solute in the ink are close to each other, and in many cases, the solvent accounts for most of the composition of the ink, for example, 98 mass % or more, so in such cases, when the SP value of the solvent is SP(S), and this is replaced by the SP value of the ink SP(I), and the absolute value of the difference with SP(M2) may be used as the index SP(M2). In other words, since |SP(M2)-SP(I)| is nearly equal to |SP(M2)-SP(S)|, it is preferable that the value of |SP(M2)-SP(S)| is 3.1 (J/cm³)^{1/2} or more, and 3.5 (J/cm³)^{1/2} or more is more preferable.

### <Release Film>

The inkjet recording medium of the present invention is preferably further provided with a release film on the ink receiving layer. The release film is used to enhance the storage stability of the inkjet recording medium, and is peeled off from the inkjet recording medium at the time of use.

As the release film, a known resin film, for example, a polyester resin film, a silicone resin film, or a polyolefin resin film may be used. The thickness of the release film is preferably 0.1 to 1000 μm, and 1 to 50 μm is more preferable from the viewpoint of storage stability and handling.

The use of a release film not only blocks external physical influences (e.g., protection from scratches and other damage, protection from oxygen and water), which is the role of a general protective film, but also has the effect of suppressing the promotion of phase separation caused by the formation of an interface between gas (e.g., air or nitrogen) and an organic thin film (solid). It is presumed that this effect may be achieved.

### (Production of Inkjet Recording Medium)

The inkjet recording medium of the present invention may be produced, for example, by a method comprising the following steps.
(i) Step of forming an electrode 3 on a base material 2 to obtain the base material 2 with an electrode 3
(ii) Step of forming an ink receiving layer 4A on the electrode of the base material 2 with an electrode 3

When the inkjet recording medium further has a release film on the ink receiving layer, the step of (ii) is followed by a further step of (iii) laminating the release film on the ink receiving layer 4A.

(i) Preparation of base material with electrode

The method of forming an electrode 3 on the base material 2 has been described above.

(ii) Formation of ink receiving layer

The step of forming the ink receiving layer 4A is described below using the case of an ink receiving layer having an ink insoluble layer 42 and an ink penetrating layer 41 in that order from the electrode 3 side as an example.

The ink insoluble layer 42 is preferably formed by a wet process. Examples of the wet process include a spin coating method, a casting method, an inkjet printing method, a silk screen printing method, a slot die coating method, a blade coating method, a roll coating method, a spray coating method, a curtain coating method, and an LB method (Langmuir-Blodgett method). A spray coating method, a silk screen printing method, and a slot die coating method, which are excellent for mass production, are suitable from the viewpoint of ease of obtaining a homogeneous thin film and particularly high productivity.

When the ink insoluble layer 42 is formed by a wet process, a coating liquid in which the constituent materials of the ink insoluble layer 42 are dissolved or dispersed in a solvent is used. The solvent is not particularly restricted as long as it is a solvent capable of dissolving or dispersing the optional components such as the resin B and the charge transport compound.

As a solvent, specifically, there is no restriction on the kinds of liquid medium, and examples thereof include halogenated solvents such as chloroform, carbon tetrachloride, dichloromethane, 1,2-dichloroethane, dichlorobenzene, and dichlorohexanone; ketone solvents such as acetone, methyl ethyl ketone, diethyl ketone methyl ethyl ketone, diethyl ketone, methyl isobutyl ketone, n-propyl methyl ketone, and cyclohexanone; aromatic solvents such as benzene, toluene, xylene, mesitylene, and cyclohexyl benzene; aliphatic solvents such as cyclohexane, decalin, and dodecane; ester solvents such as ethyl acetate, n-propyl acetate, n-butyl acetate, methyl propionate, ethyl propionate, y-butyrolactone, and diethyl carbonate; ether solvents such as tetrahydrofuran, and dioxane; amide solvents such as dimethylformamide and, dimethylacetamide; alcohol solvents such as methanol, ethanol, 1-butanol, and ethylene glycol; nitrile solvents such as acetonitrile and propionitrile; dimethyl sulfoxide, water, or a mixed medium of these.

The boiling point of these solvents is preferably below the temperature of the drying process from the viewpoint of rapidly drying the solvent. Specifically it is within the range of 60 to 200° C., and more preferably within the range of 80 to 180° C.

The coating liquid may contain a surfactant according to the purpose of controlling the coating range or suppressing liquid flow associated with a surface tension gradient after coating (e.g., liquid flow causing a phenomenon called coffee ring).

The surfactant includes, for example, an anionic or nonionic surfactant from the viewpoint of the effect of moisture contained in the solvent, leveling property, and wettability to the substrate. Specifically, the surfactants including a fluorine-containing surfactant listed in WO 08/146681 and JP-A 2-41308 may be used.

The coating liquid used for the wet process may be a solution in which the constituent materials of the ink insoluble layer 42 are uniformly dissolved in the solvent or a dispersion liquid in which the constituent materials are dispersed in the solvent as solids. As a dispersion method, dispersion may be performed by a dispersion method such as ultrasonic waves, high shear force dispersion, or media dispersion.

The concentration of the coating solution may be selected as appropriate depending on the solubility or dispersibility of the constituent materials of the ink insoluble layer 42, for example, the solid concentration may be selected within the range of 0.1 to 50 mass %.

The viscosity of the coating liquid may be selected appropriately depending on the solubility or dispersibility of the material forming the ink insoluble layer 42, and may be selected within the range of 0.3 to 100 mPa·s, for example.

The thickness of the coating film should be such that the layer thickness described above is achieved as the ink insoluble layer 42 after drying.

After the coating film is formed by the wet process, a drying process for removing the above-described solvent may be provided. Although the temperature of the drying process is not particularly limited, it is preferable to perform the drying process at a temperature at which the ink insoluble layer 42, the electrode 3, and the base material 2 are not damaged. Specifically, although it may not be said in general because it depends on the composition of the coating solution, for example, the temperature may be 80° C. or higher, and the upper limit is considered to be a possible area up to about 300° C. It is preferable that the time be between 10 seconds and 10 minutes. By using such conditions, drying may be carried out quickly.

The ink penetrating layer 41 is formed on the ink insoluble layer 42. It is preferable to form the ink penetrating layer 41 by a wet process in the same manner as the ink insoluble layer 42 described above. The coating liquid used for the formation of the ink penetrating layer 41 may be the same as the coating liquid used for the formation of the ink insoluble layer 42, except that resin A is used instead of resin B.

For the method of applying the coating liquid, the same method as that for the ink insoluble layer 42 may be applied. It is preferred that the thickness of the coating film be such that the layer thickness described above is achieved as the ink penetrating layer 41 after drying.

After formation of the coating film for the ink penetrating layer 41, drying may be performed in the same manner as for the ink insoluble layer 42. Here, the drying may be performed simultaneously in the formation of the ink insoluble layer 42 and the ink penetrating layer 41. That is, after forming the coating film for the ink insoluble layer 42, the coating film for the ink penetrating layer 41 may be formed without drying, and then drying may be performed to obtain the ink receiving layer 4A.

(iii) Lamination of Release Film

The release film is laminated in a form that covers the entire surface S of the ink receiving layer 4A. The lamination method includes, for example, a method in which a pressure treatment or a heat treatment or a combination of these treatments is performed on the laminated body in which the release film is laminated on the ink receiving layer 4A of the inkjet recording medium.

The pressing may be a pressing by a decompression device. The method of laminating the release film includes, for example, placing the above-described laminate in the apparatus and holding it for 0.1 to 60 minutes under pressure conditions of atmospheric pressure to 10 MPa at a temperature; 0 to 150° C.

### [Member for Organic Semiconductor Device]

The member for an organic semiconductor device of the present invention is a member for an organic semiconductor device in which a base material, an electrode, and an organic semiconductor layer are laminated in this order.

The member for an organic semiconductor device of the present invention is provided with an ink receiving layer in which the organic semiconductor layer is continuously present in the entire area of the organic semiconductor layer forming area on the electrode, and as a discontinuous area surrounded by the ink receiving layer, the surface of the organic semiconductor layer far from the electrode has an exposed portion having a pattern shape, and has an organic semiconductor material-containing area having no interface with the electrode.

In the member for an organic semiconductor device of the present invention, the above-described organic semiconductor material-containing area is, for example, an area formed using an ink containing the above-described organic semiconductor material, and is preferably an area formed by applying an ink containing the organic semiconductor material by an inkjet method. Hereinafter, a case where the organic semiconductor material-containing area is formed by the inkjet method will be described as an example, but is not limited thereto.

The member for an organic semiconductor device of the present invention will now be described with reference to FIG. 2, FIG. 3, and FIG. 4. The organic semiconductor device member 10A shown in FIG. 2 and FIG. 3 is an example of an organic semiconductor device member obtained by using the inkjet recording medium 1 of the present invention shown in FIG. 1. FIG. 4 shows a cross-sectional view of a member 10B for an organic semiconductor device, which is another example of the member 10A for an organic semiconductor device. For example, the organic semiconductor device member 10B may be produced using an inkjet recording medium other than the inkjet recording medium of the present invention.

Thus, the member for an organic semiconductor device may be a member for an organic semiconductor device obtained by using the inkjet recording medium for an organic semiconductor device of the present invention, as long as the member has the features of the above configuration, or may be a member for an organic semiconductor device obtained by using any other inkjet recording medium. It may also be a member for an organic semiconductor device obtained using any other inkjet recording medium.

The organic semiconductor layer is preferably, for example, a light-emitting layer when the organic semiconductor device is an organic EL element, a photoelectric conversion layer in the case of a photoelectric conversion device, and various organic semiconductor layers such as a charge transport layer in the case of an organic TFT.

The organic semiconductor device member 10A shown in FIG. 2 and FIG. 3 is an organic semiconductor device member of the present invention obtained by using the inkjet recording medium 1 shown in FIG. 1, and comprises a base material 2, an electrode 3, and an organic semiconductor layer 6 stacked in this order. The organic semiconductor layer 6 has an ink receiving layer 4A continuously present in the entire area of the formation of the organic semiconductor layer 6 on the electrode 3, and an organic semiconductor material-containing area 5 as a discontinuous area surrounded by the ink receiving layer 4A. The ink receiving layer 4A has, in the order from the electrode 3 side, an ink penetration prevention area 42 and an ink penetration area 41. The organic semiconductor material-containing area 5 has an exposed portion D in a pattern shape on a surface S far from the electrode 3 of the organic semiconductor layer 6, and does not have an interface with the electrode 3.

FIG. 2 is a plan view of the organic semiconductor device member 10A, in which a pattern shape of an exposed portion D of the organic semiconductor material-containing area 5 on the surface S may be confirmed. The organic semiconductor device member 10A has a total of 48 dot-shaped organic semiconductor material-containing areas 5 in six vertical rows and eight horizontal columns in a plan view. However, the dot pattern of the member 10A for an organic semiconductor device shown in FIG. 2 is an example, and the present invention is not limited thereto. FIG. 3 shows a cross-sectional view of the member 10A for an organic semiconductor device cut at in FIG. 2. The organic semiconductor material-containing area 5 has a thickness in the thickness direction equivalent to the thickness of the ink penetration area 41, and is separated from the electrode 3 by the thickness of the ink penetration prevention area 42.

In the member 10A for the organic semiconductor device shown in FIG. 2 and FIG. 3, the organic semiconductor layer 6 is formed in a manner that covers the entire surface of the electrode 3, but the formation area of the organic semiconductor layer 6 is not limited thereto. The formation area is selected as appropriate according to the type and application of the semiconductor device. For example, when the organic semiconductor device is an organic EL element and is used in a display device, the formation area of the organic semiconductor layer 6 may be the display area.

The pattern shape on the surface S of the organic semiconductor material-containing area 5 is not limited to the shape shown in FIG. 2. The pattern shape and the number of patterns are selected as appropriate according to the type and application of the semiconductor device. The individual shape of the exposed portion D of the organic semiconductor material-containing area 5 is preferably a circular dot shape. In this specification, the term “circular” does not refer only to a perfect circle, but is used in a concept that comprehensively includes ellipses and other circular shapes.

When the exposed portion D is a circular dot shape, the maximum diameter d of the exposed portion D may be adjusted as appropriate by, for example, changing the specifications of the head used in the inkjet method, and specifically, it may be in the range of 30 to 300 μm. The maximum diameter d of the exposed portion D may be measured based on an optical microscope photograph taken from the surface S side.

The formation of the organic semiconductor material-containing area 5 is performed, for example, by dropping an ink In from the head 12 of the inkjet apparatus 11 corresponding to the inkjet method onto the surface S of the ink receiving layer 4A of the inkjet recording medium 1, as shown in FIG. 5. The dropped ink In lands on the exposed area D of the surface S of the ink receiving layer 4A (ink penetration area 41) and penetrates from the surface S of the ink receiving layer 4A to the electrode 3 within the ink penetration area 41 in the range of the exposed area D. Then, the penetration of the ink In toward the electrode 3 is stopped by the presence of the ink penetration prevention area 42. Note that the penetration of the ink need only stop in the ink penetration prevention area 42 before reaching the lower surface of the ink penetration prevention area 42, and need not necessarily stop at the upper surface of the ink penetration prevention area 42.

FIG. 5 shows a case in which ink penetration stops at a position of the upper surface of the ink penetration prevention area 42. The ink used in the inkjet method contains a solvent and an organic semiconductor material. Details of the composition of the ink are described below. The ink penetration is specifically a phenomenon in which the ink passes through a gap in the materials constituting the ink penetration area 41. For example, when the ink penetration area 41 is mainly composed of a resin, the ink penetrates between the molecules of the resin. The ink penetration may also be accompanied by dissolution of the materials constituting the ink penetration area 41.

In the ink receiving layer 4A, the solvent is removed from the area where the ink In has penetrated as described above to form an organic semiconductor material-containing area 5 in which the organic semiconductor material is dispersed in the constituent materials of the ink penetration area 41. The ink In-penetrated area in the ink receiving layer 4A and the obtained organic semiconductor material-containing area 5 are of the same shape and size.

Although the amount of the organic semiconductor material in the organic semiconductor material-containing area 5 depends on the design of the organic semiconductor device, the amount of the organic semiconductor material may be about 1 to 100 mass % relative to the total amount of the organic semiconductor material-containing area 5, and preferably about 80 to 99 mass %.

The thickness Th of the organic semiconductor material-containing area 5, that is, the depth from the exposed area D at the surface S to the edge of the electrode 3 side, depends on the design of the organic semiconductor device. In the ink receiving layer 4A, it is preferable to design the thickness of the ink penetration area 41 so that the thickness Th of the organic semiconductor material-containing area 5 may be secured as the designed thickness.

The distance from the edge on the electrode 3 side of the organic semiconductor material-containing area 5 to the electrode 3 is preferably 1 nm or more, 2 nm or more is more preferable, and 5 nm or more is even more preferable from the viewpoint of sufficiently suppressing the generation of a leakage current. In addition, the above distance is preferably 100 nm or less from the viewpoint of suppressing an increase in the drive voltage. In the ink receiving layer 4A, it is preferable to design the thickness of the ink penetration prevention area 42 so that the distance between the organic semiconductor material-containing area 5 and the electrode 3 may be maintained in the above range.

The organic semiconductor device member 10B shown in FIG. 4 has a similar configuration to the organic semiconductor device member 10A except that the configuration of the ink receiving layer is different from that of the organic semiconductor device member 10A. The ink receiving layer 4A of the organic semiconductor device member 10A has an ink penetration area 41 and an ink penetration preventing area 42, while the ink receiving layer 4B of the organic semiconductor device member 10B comprises a single, uniform area.

In an embodiment of the organic semiconductor device member, whether it is the organic semiconductor device member 10A or the organic semiconductor device member 10B, it is preferable that the maximum thickness of the ink receiving layer is in the range of 3 nm to 5 μm. That is, it is preferable that the maximum thickness of the ink receiving layer is in the above range regardless of whether the ink receiving layer is a single layer or a multilayer layer.

Here, the maximum thickness of the ink receiving layer is the layer thickness from the surface far from the electrode of the ink receiving layer to the upper surface of the electrode. The organic semiconductor layer in the member for the organic semiconductor device is obtained by dropping an ink containing the organic semiconductor material in a patterned form on the surface of the ink receiving layer as described below, and allowing the ink to penetrate in the depth direction of the ink receiving layer at the drop portion, thereby forming an organic semiconductor material-containing area. The organic semiconductor layer obtained in this manner is composed of the ink receiving layer and the organic semiconductor material-containing area. Accordingly, the maximum thickness of the ink receiving layer in the organic semiconductor device member is the same as the thickness of the ink receiving layer before the ink drop. The minimum thickness of the ink receiving layer is the distance from the edge of the electrode side of the organic semiconductor material-containing area to the electrode.

The maximum thickness of the ink receiving layer is preferably a thickness that may sufficiently secure the thickness of the organic semiconductor material-containing area formed by the penetration of ink dropped on the surface of the ink receiving layer by the ink-jet method. It is also preferred that the maximum thickness of the ink receiving layer has a thickness that enables the distance between the organic semiconductor material-containing area and the electrode to be designed to be 1 nm or more as described above. From this point of view, it is preferred that the maximum thickness of the ink-receiving layer is within the above range. When the ink receiving layer comprises a single layer, the lower limit of the maximum thickness of the ink receiving layer is preferably 5 nm or more in order to secure a sufficient distance between the organic semiconductor material-containing area and the electrode. It is also known that the thicker the film thickness is, the lower the mobility becomes due to restrictions originating from the low carrier mobility peculiar to the organic semiconductor material, and since this loss is large when exceeding 5 um and affects the function of the device, the upper limit is preferably within 5 μm.

In the embodiment of the member for the organic semiconductor device, it is preferable that the constituent material of the ink receiving layer mainly includes a resin whose weight average molecular weight is in the range of 1×10³ to 1000×10³. Specifically, from the viewpoint of ink penetration, a configuration mainly comprising the resin A in the ink penetrating layer 41 described in the organic semiconductor device member 10A is preferable. For example, in the organic semiconductor device member 10A, the ink receiving layer 4A preferably has a configuration in which an ink penetrating layer 41 is a main component.

When the weight average molecular weight of the main constituent material of the ink receiving layer is within the range of 1×10³ to 1000×10³, the permeability of the ink may be moderately controlled. In other words, the weight average molecular weight of 1×10³ or more may prevent excessive penetration of the ink into the ink receiving layer. For example, even when the ink receiving layer consists of a single layer, it is easy to prevent the organic semiconductor material-containing area from reaching the electrode by adjusting the thickness (maximum thickness) of the ink receiving layer. In addition, by having a weight average molecular weight of 1000×10³ or less, it is easy to allow the ink to penetrate to an appropriate depth in the ink receiving layer.

Similarly, from the viewpoint of the ink permeability, it is preferable that the absolute value of the difference between the SP value of the constituent material of the ink receiving layer and the SP value of the ink used for forming the organic semiconductor material-containing area is 3.0 (J/cm³)^{1/2} or less. When the ink receiving layer is composed of multiple layers, as in the case of the member 10A for the organic semiconductor device, it is preferable that of the absolute value of the difference between the above SP values is 3.0 (J/cm³)^{1/2} or less in the ink penetrating layer 41 as described above.

When the absolute value of the difference between the SP value of the constituent material of the ink receiving layer and the SP value of the ink used to form the organic semiconductor material-containing area is 3.0 (J/cm³)^{1/2} or less, the affinity between the ink and the ink-receiving layer is high and the permeability of the ink into the ink receiving layer may be sufficiently secured.

As a configuration of the ink receiving layer 4B, for example, a configuration in which the ink receiving layer 4B is composed of a constituent material equivalent to the constituent material of the ink penetrating layer described above, for example, a constituent material consisting mainly of the resin A, and in which the layer thickness is larger than that of the ink penetrating layer. In this case, a layer thickness in the range of 3 nm to 5 μm is mentioned, wherein 5 to 200 nm is preferable and 60 to 100 nm is more preferable. This layer thickness indicates the layer thickness (maximum thickness) from the surface S to the upper surface of the electrode 3 in the ink receiving layer 4B.

In the case of the ink receiving layer 4B using the constituent material, although it depends on the type of ink, for example, the design may be such that the distance from the edge of the electrode 3 side of the organic semiconductor material-containing area 5 to the electrode 3 is 1 nm or more, preferably 2 nm or more, and even more preferably 5 nm or more. Also, for example, when the layer thickness of the ink receiving layer 4B is 60 to 100 nm, the ink may be designed such that the ink may generally penetrate to a depth of 50 to 95 nm from the surface S, but the ink may not penetrate to a depth deeper than that and never reaches the electrode 3.

In the ink receiving layer 4B, it is preferable to design the constituent materials and thickness so that the thickness Th of the organic semiconductor material-containing area 5 may be secured as the designed thickness and the distance between the organic semiconductor material-containing area 5 and the electrode 3 may be maintained in the above range.

The ink receiving layer 4B may, for example, be designed to be mainly composed of a resin AL, which is easier to take a dense structure even within the resin A, and easier to take a sparse structure than the resin B. As the resin AL, a resin having a high weight average molecular weight among the resins A is mentioned. For example, when the polystyrene resin is used as the resin AL, from the viewpoint that the permeability of the ink may be adjusted to be lower than that of the ink penetrating layer, a weight average molecular weight in the range of 10×10³ to 1000×10³ is preferable, and a range of 100×10³ to 400×10³ is more preferable.

As for the ink receiving layer 4B, it is preferable that the ink receiving layer 4B has moderate ink permeability to the extent that it does not reach the electrode 3 as described above. From this viewpoint, for example, when the SP value of the constituent material of the ink receiving layer 4B is indicated by SP(M3) and the SP value of the ink used for manufacturing the organic semiconductor device is indicated by SP(I), it is preferable that the absolute value of the difference between the two indicated by |SP(M3)-SP(I)| is 3.0 (J/cm³)^{1/2} or less to have the above-described moderate ink penetrability.

The SP values of the solvent and the solute in the ink are close to each other, and in many cases, the solvent accounts for most of the composition of the ink, for example, 98 mass % or more, in such cases, when the SP value of the solvent is SP(S), and this is replaced by the SP value of the ink (I), and the absolute value of the difference with SP(M3) may be used as the index SP(M3). In other words, since |SP(M3)-SP(I)| is nearly equal to |SP(M3)-SP(S)|, it is preferable that |SP(M3)-SP(S)| is in the range of 0 to 3.0 (J/cm³)^{1/2}.

<Ink>

The ink of the present invention is an inkjet ink applicable to a method of applying ink by an inkjet method, and contains a solvent and an organic semiconductor material. In the ink, the organic semiconductor material is dissolved or dispersed in the solvent.

The viscosity of the ink may be selected as appropriate so that the ink may be ejected from the nozzle of the inkjet head used in the inkjet method (hereinafter simply referred to as the “head”). For example, the viscosity of the ink may be selected within the range of 0.3 to 100 mPa·s. For example, the viscosity of the ink may be selected within the range of 0.3 to 100 mPa·s. The viscosity of the ink may be measured at 25° C. by an E-type viscometer. The number of rotations may be set according to the viscosity, but for example, it may be 10 rpm or 20 rpm. Unless otherwise noted, the viscosity herein is the viscosity at 25° C. measured by the above method.

With respect to the SP value of the ink, when the ink receiving layer is composed of two different areas such as the ink receiving layer 4A, for example, the ink penetrating layer 41 and the ink insoluble layer 42, it is preferable that the above relationship holds in the relationship between the SP value of the constituent material of the ink penetrating layer 41 and the SP value of the constituent material of the ink insoluble layer 42. When the ink receiving layer comprises a single area of uniformity, such as the ink receiving layer 4B, it is preferable that the above relationship is established in relation to the SP values of the constituent materials of the ink receiving layer 4B.

The concentration of the organic semiconductor material in the ink is preferably a concentration at which the viscosity of the ink may be set in the above range. The concentration of the organic semiconductor material in the ink depends on the type of the organic semiconductor material and the solvent, but may be, for example, about 0.1 to 80 mass %, and 0.1 to 10 mass % is preferable.

The ink may contain various functional additives depending on the purpose of ejection stability, print head compatibility, storage stability, image storage stability, and other performance improvements. Examples of the known additive that may be included are a viscosity modifier, a surface tension modifier, a resistivity modifier, a film forming agent, a dispersing agent, a surfactant, an ultraviolet absorber, an antioxidant, an anti-fading agent, a mold inhibitors, and a rust inhibitor. The ink may also contain a charge transport compound similar to the charge transport compound which may be optionally blended in the ink receiving layer.

### (Organic Semiconductor Material)

The organic semiconductor material contained by the ink is appropriately selected according to the type of organic semiconductor device to be fabricated. For example, when the organic semiconductor device is an organic EL element, the organic semiconductor material is a luminescent compound, and the organic semiconductor layer is preferably a light-emitting layer. When the organic semiconductor device is an organic photoelectric conversion device, the organic semiconductor material is an n-type organic semiconductor compound and a p-type organic semiconductor compound, and the organic semiconductor layer is preferably a photoelectric conversion layer. When the organic semiconductor device is an organic TFT, various organic semiconductor materials may be widely used.

### (Luminescent Compound)

Luminescent compounds are classified, for example, as fluorescent compounds, delayed fluorescent compounds and phosphorescent compounds. A plurality of luminescent compounds may be used in combination, such as, for example, a combination of different phosphorescent compounds or a combination of a phosphorescent compound and a fluorescent compound. This allows any luminescent color to be obtained.

The light-emitting layer of the present invention contains a plurality of luminescent compounds having different light-emitting colors, and it is also preferable to exhibit white light emission. Although there is no particular limitation as to the combination of the luminescent compounds that exhibit white color, for example, a combination of blue and orange, or blue, green and red may be mentioned. White color in the present invention means that the chromaticity in the CIE 1931 color system at 1000 cd/m² area of x=0.39±0.09 and y=0.38±0.08 when the 2 degree viewing angle frontal luminance is measured by the following method.

The color emitted by the organic EL element and the compound used in the present invention is determined by the color obtained by applying the result measured with Spectroradiometer CS-1000 (manufactured by Konica Minolta, Inc.) to the CIE chromaticity coordinates in FIG. 3.16 on page 108 of the “New Handbook of Color Science” (edited by the Japan Color Science Society, University of Tokyo Press, 1985).

<Fluorescent Compound>

In the present invention, a “fluorescent compound” refers to a compound that emits fluorescence other than delayed fluorescence. The term “fluorescence” means light emitted when returning to the ground state from a singlet excited state, and “fluorescence other than delayed fluorescence” means fluorescence other than “delayed fluorescence” such as “thermally activated delayed fluorescence (TADF)” and “triplet-triplet annihilation (TTA) delayed fluorescence”. In other words, in the present invention, a “fluorescent compound” means a fluorescent compound that does not include a “delayed fluorescent compound” such as a “heat activation delayed fluorescent compound” or a “triplet-triplet annihilation delayed fluorescent compound”, and indicates a compound that does not cause up-conversion by inverse intersystem crossing from the lowest excited triplet energy level to the lowest excited singlet energy level.

The fluorescent compounds do not have to be heavy metal complexes such as phosphorescent compounds, but may be so-called organic compounds consisting of combinations of common elements such as carbon, oxygen, nitrogen and hydrogen. Furthermore, other non-metal elements such as phosphorus, sulfur, and silicon may be used, and complexes of typical metals such as aluminum and zinc may also be used, so that the variety can be said to be almost infinite.

The fluorescent compound may be selected from known fluorescent compounds used in the light-emitting layer of the organic EL element.

Examples of the known fluorescent compound that may be used in the present invention are an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complexe, a coumarin derivative, a pyran derivative, a cyanine derivative, a croconium derivative, a squalium derivative, an oxobenzanthracene derivative, a fluorescein derivative, a rhodamine derivative, a pyrillium derivative, a perylene derivative, a polythiophene derivative, and a rare earth complex-based compound.

### <Phosphorescent Compound>

In the present invention, a “phosphorescent compound” refers to a compound that emits phosphorescence, and is specifically defined as a compound that emits phosphorescence at room temperature (25° C.) and has a phosphorescence quantum yield of 0.01 or more at 25° C. The preferred quantum yield of phosphorescence is 0.1 or more. The term “phosphorescence” refers to the light emitted when the triplet excited state returns to the ground state.

The above phosphorescence quantum yield may be measured by the method described on page 398 of Spectroscopy II of the Fourth Edition of the Course of Experimental Chemistry 7 (1992 edition, Maruzen). The phosphorescence quantum yield in solution may be measured using a variety of solvents, and the phosphorescent compound used in the present invention may be used when the above phosphorescence quantum yield (0.01 or more) is achieved in any of the solvents.

In the case of excitation by an electric field, such as in organic EL elements, triplet excitons are generated with a probability of 75% and singlet excitons with a probability of 25%. Therefore, phosphorescence luminescence may have a higher luminous efficiency than fluorescence luminescence, which is an excellent method for achieving low power consumption.

Phosphorescence emission is theoretically three times more favorable than fluorescence emission in terms of luminous efficiency. However, the rate constant is usually small because the energy deactivation from the triplet excited state to the singlet ground state (i.e., phosphorescence emission) is a forbidden transition and the intersystem crossing from the singlet excited state to the triplet excited state is also a forbidden transition. The rate constant is usually small, i.e., it is difficult to obtain the desired luminescence because the phosphorescence lifetime is as long as milliseconds to seconds, due to the difficulty of the transitions.

However, when the complexes using heavy metals such as iridium (Ir) and platinum (Pt) are luminescent, the rate constants of the above-mentioned forbidden transitions increase by more than three orders of magnitude due to the heavy atom effect of the central metal, and depending on the choice of ligand, it is possible to obtain a phosphorescent quantum yield of 100%.

The phosphorescent compound may be appropriately selected from among known compounds used for the light-emitting layer of the organic EL element. Specific examples of the known phosphorescent compound that may be used in the present invention include the compounds described in the following documents.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, US Patent 7332232, US 2009/0108737, US 2009/0039776, U.S. Pat. Nos. 6,921,915, 6,687,266, US 2007/0190359, US 2006/0008670, US 2009/0165846, US 2008/0015355, U.S. Pat. Nos. 7,250,226, 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. Nos. 7,393,599, 7,534,505, 7,445,855, US 2007/0190359, US 2008/0297033, U.S. Pat. No. 7,338,722, US 2002/0134984, U.S. Pat. No. 7,279,704, US 2006/098120, US 2006/103874, WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, US 2012/228583, US 2012/212126, JP-A 2012-069737, JP-A 2012-19554, JP-A 2009-114086, JP-A 2003-81988, JP-A 2002-302671 and JP-A 2002-363552.

Among the most preferred phosphorescent compounds are organometallic complexes having Ir as the central metal. More preferably, a complex containing at least one coordination mode of a metal-carbon bond, a metal-nitrogen bond, a metal-oxygen bond, and a metal-sulfur bond is preferred.

As the phosphorescent compound, a complex containing a coordination mode of metal-nitrogen bond whose structure is represented by the following Formula (N) is preferred.

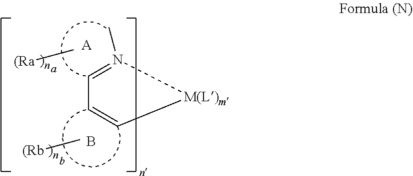

In the formula, ring A and ring B represent a 5- or 6-membered aromatic hydrocarbon ring or aromatic heterocyclic ring, and the 5- or 6-membered aromatic hydrocarbon ring or aromatic heterocyclic ring may be further fused to form a fused polycyclic aromatic hydrocarbon ring or a fused polycyclic aromatic heterocyclic ring. Ra and Rb each independently represent a hydrogen atom, a halogen atom, a cyano group, an alkyl group, an alkenyl group, an alkynyl group, an alkoxy group, an amino group, a silyl group, an aryl alkyl group, an aryl group, a heteroaryl group, a non-aromatic hydrocarbon ring group or a non-aromatic heterocyclic group, and may have a substituent. nₐ represents an integer of 1 or 2, and n_{b} represents an integer of 1 to 4. When there is a plurality of Ra and Rb, they may be bonded to each other to form a ring.

L′ represents one or more of a monoanionic bidentate ligand coordinated to M, wherein M represents a transition metal atom having atomic number 40 or more and belonging to groups 8 to 10 in the periodic table of elements, Ir, Pt, Rh, Ru, Ag, Cu or Os being preferable, and Ir being particularly preferable. m′ represents an integer of 0 to 2, n′ represents an integer of 1 to 3, and m′+n′ represents an integer of 2 or 3.

Among the phosphorescent compounds represented by the above Formula (N), the phosphorescent compound represented by the following Formula (N1), wherein ring A is a pyridine ring, and the phosphorescent compound represented by the following Formula (N2), wherein ring A is an imidazole ring, are preferred.

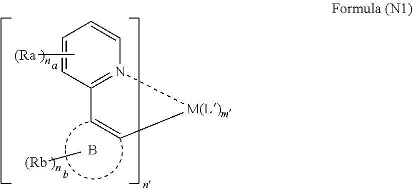

In the formula, ring B represents a 5- or 6-membered aromatic hydrocarbon ring or aromatic heterocyclic ring, and the 5- or 6-membered aromatic hydrocarbon ring or aromatic heterocyclic ring may be further fused to form a fused polycyclic aromatic hydrocarbon ring or a fused polycyclic aromatic heterocyclic ring. Ra and Rb each independently represent a hydrogen atom, a halogen atom, a cyano group, an alkyl group, an alkenyl group, an alkynyl group, an alkoxy group, an amino group, a silyl group, an aryl group, an aryl group, a heteroaryl group, a non-aromatic hydrocarbon ring group or a non-aromatic heterocyclic group, and may have a substituent. nₐ represents an integer of 1 or 2, n_{b} represents an integer of 1 to 4. When there is a plurality of Ra and Rb, they may be bonded to each other to form a ring.

L′ represents one or more of a monoanionic bidentate ligand coordinated to M, wherein M represents a transition metal atom having atomic number 40 or more and belonging to groups 8 to 10 in the periodic table of elements, Ir, Pt, Rh, Ru, Ag, Cu or Os being preferable, and Ir being particularly preferable. m′ represents an integer of 0 to 2, n′ represents an integer of 1 to 3, and m′+n′ represents an integer of 2 or 3.

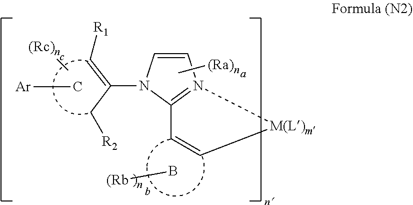

In the formula, ring B and ring C represent a 5- or 6-membered aromatic hydrocarbon ring or aromatic heterocyclic ring, and the 5- or 6-membered aromatic hydrocarbon ring or aromatic heterocyclic ring may be further fused to form a fused polycyclic aromatic hydrocarbon ring or a fused polycyclic aromatic heterocyclic ring. Ar represents an aromatic hydrocarbon ring group, an aromatic heterocyclic group, a non-aromatic hydrocarbon ring group or a non-aromatic heterocyclic group. R₁ and R₂ each independently represent a hydrogen atom, a halogen atom, a cyano group, an alkyl group, an alkenyl group, an alkynyl group, an alkoxy group, an amino group, a silyl group, an aralkyl group, an aryl group, a heteroaryl group, a non-aromatic hydrocarbon ring group, or a non-aromatic heterocyclic group, and may further have a substituent. At least one of R₁ and R₂ represents an alkyl group or a cycloalkyl group having 2 or more carbon atoms. Ra, Rb, and Rc each independently represent a hydrogen atom, a halogen atom, a cyano group, an alkyl group, an alkenyl group, an alkynyl group, an alkoxy group, an amino group, a silyl group, an aralkyl group, an aryl group, a heteroaryl group, a non-aromatic hydrocarbon ring group or a non-aromatic heterocyclic group, and may further have a substituent. nₐ and n_{c} represent an integer of 1 or 2, and n_{b} represent an integer of 1 to 4.

L′ represents one or more of a monoanionic bidentate ligand coordinated to M, wherein M represents a transition metal atom having atomic number 40 or more and belonging to groups 8 to 10 in the periodic table of elements, Jr, Pt, Rh, Ru, Ag, Cu or Os being preferable, and Ir being particularly preferable. m′ represents an integer of 0 to 2, n′ represents an integer of 1 to 3, and m′+n′ represents an integer of 2 or 3.

Among the phosphorescent compounds represented by the above Formula (N2), the phosphorescent compound represented by the following Formula (N21), wherein ring B and ring C represent a benzene ring, is preferred.

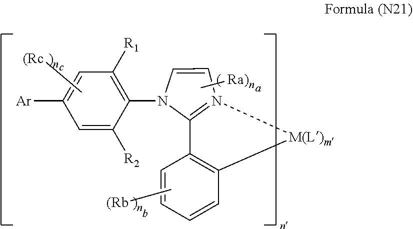

In the formula, Ar represents an aromatic hydrocarbon ring group, an aromatic heterocyclic group, a non-aromatic hydrocarbon ring group or a non-aromatic heterocyclic group. R₁ and R₂ each independently represent a hydrogen atom, a halogen atom, a cyano group, an alkyl group, an alkenyl group, an alkynyl group, an alkoxy group, an amino group, a silyl group, an aralkyl group, an aryl group, a heteroaryl group, a non-aromatic hydrocarbon ring group or a non-aromatic heterocyclic group, and may further have a substituent. At least one of R₁ and R₂ represents an alkyl group or a cycloalkyl group having 2 or more carbon atoms. Ra, Rb and Rc each independently represent a hydrogen atom, a halogen atom, a cyano group, an alkyl group, an alkenyl group, an alkynyl group, an alkoxy group, an amino group, a silyl group, an arylalkyl group, an aryl group, a heteroaryl group, a non-aromatic hydrocarbon ring group or a non-aromatic heterocyclic group, and may further have a substituent. nₐ and n_{c} represent an integer of 1 or 2, and n_{b} represents an integer of 1 to 4.

L′ represents one or more of a monoanionic bidentate ligand coordinated to M, wherein M represents a transition metal atom having an atomic number of 40 or more and belonging to groups 8 to 10 in the periodic table of elements, Ir, Pt, Rh, Ru, Ag, Cu or Os being preferred, and Ir being particularly preferred. m′ represents an integer of 0 to 2, n′ is at least 1, and m′+n′ represents an integer of 2 or 3.

Among the phosphorescent compounds represented by the above Formula (N1), as compounds where M is Ir, specifically, compounds GD-1 to GD-4, and RD-1 to RD-3 whose structures are shown below are mentioned.

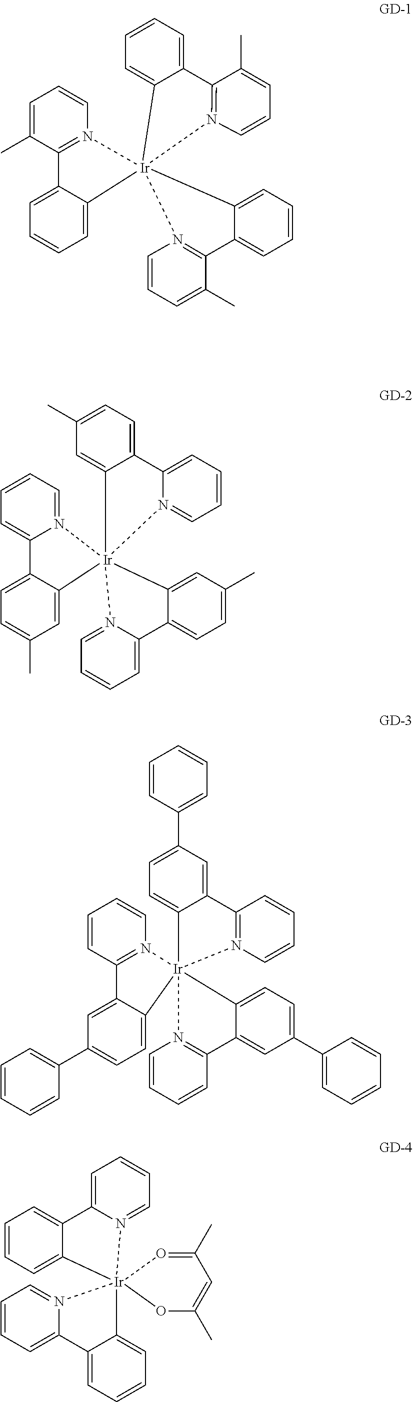

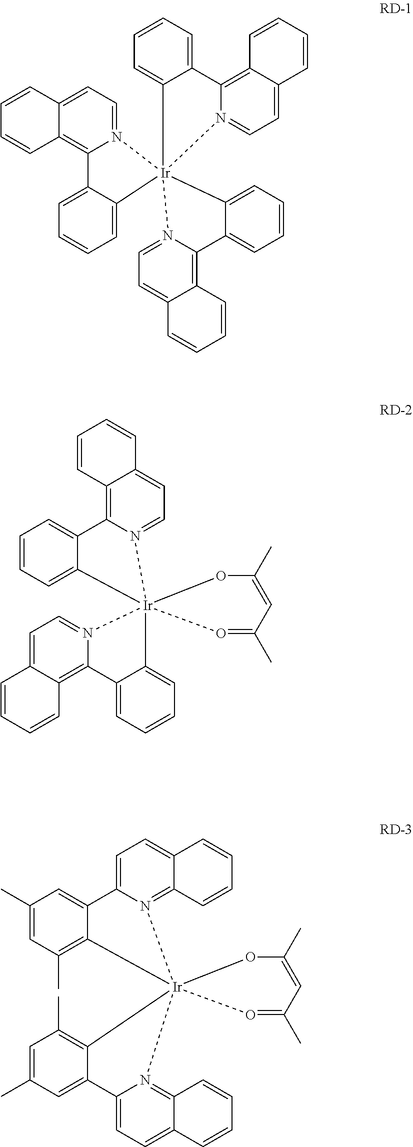

Among the phosphorescent compounds represented by the above Formula (N21), as compounds wherein M is Ir, specifically, compounds of BD-1 to BD-5 whose structures are shown below are mentioned.

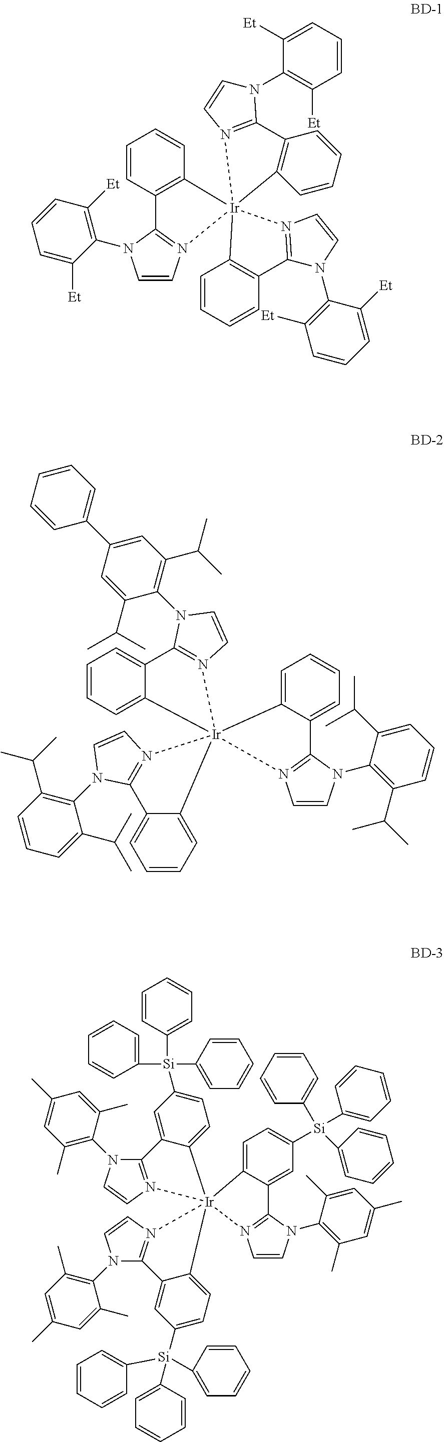

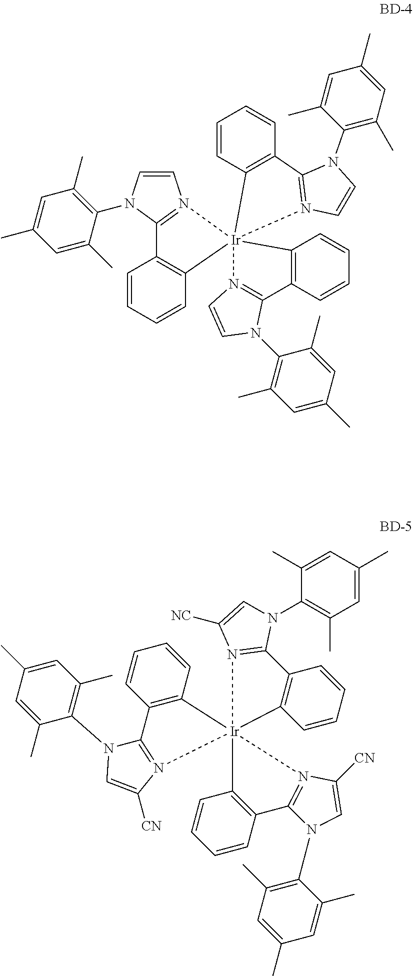

<Delayed Fluorescent Compound>

In the present invention, “delayed fluorescent compound” refers to a compound that emits delayed fluorescence. The term “delayed fluorescence” refers to the light emitted when the singlet excited state returns to the ground state as a result of up-conversion by inverse intersystem crossing from the lowest excited triplet energy level to the lowest excited singlet energy level.

Up-conversion by inverse intersystem crossing from the lowest excited triplet energy level to the lowest excited singlet energy level occurs when the energy level difference ΔFsT between the lowest excited triplet energy level and the lowest excited singlet energy level is very small

‘Delayed fluorescence’ includes ‘thermally activated delayed fluorescence’ and ‘triplet-triplet annihilation delayed fluorescence’. That is, ‘delayed fluorescent compounds’ include ‘thermally activated delayed fluorescent compounds’ and ‘triplet-triplet annihilation delayed fluorescent compounds’.

### (Thermally Activated Delayed Fluorescent Compound)

The term “thermally activated delayed fluorescent compound” means a compound that emits thermally activated delayed fluorescence (TADF). The term “thermally activated delayed fluorescence (TADF)” refers to the light emitted when a singlet excited state returns to the ground state as a result of up-conversion by inverse intersystem crossing from the lowest excited triplet energy level to the lowest excited singlet energy level due to absorption of ambient thermal energy.

Since the rate constant of the deactivation from the singlet excited state to the ground state (=fluorescence emission) is extremely large for thermally activated delayed fluorescence compounds, it is kinetically more favorable for the triplet exciton to return to the ground state while emitting via the singlet excited state than to thermally deactivate itself to the ground state (radiation-free deactivation). Therefore, 100% emission is theoretically possible in thermally activated delayed fluorescence (TADF).

Examples of the thermally activated delayed fluorescent compounds include the compounds described in WO 2011/156793, JP-A 2011-213643, JP-A 2010-93181, Japanese Patent No. 5366106, WO 2013/161437, and WO 2016/158540, but the present invention is not limited thereto.

### (Triplet-Triplet Annihilation Delayed Fluorescent Compound)

The term “triplet-triplet annihilation delayed fluorescent compound” refers to a compound that emits triplet-triplet annihilation delayed fluorescence (TTA-delayed fluorescence). The term “triplet-triplet annihilation-delayed fluorescence (TTA-delayed fluorescence)” refers to the light emitted when a singlet excited state returns to the ground state as a result of up-conversion by inverse intersystem crossing from the lowest excited triplet energy level to the lowest excited singlet energy level due to collisions between excited triplet states. This is the light emitted when the singlet excited state returns to the ground state.

The formation of singlet excitons by collisions between excited triplets may be described by the following equation.

Equation: T*+T*→S*+S

(In the equation, T* is a triplet exciton, S* is a singlet exciton, and S is a ground state molecule.

As the triplet-triplet annihilation delayed fluorescent compound, known ones may be used.

[n-Type Organic Semiconductor Compound and p-type Organic Semiconductor Compound]

The organic semiconductor materials used when the organic semiconductor device is a photoelectric conversion device include n-type organic semiconductor compounds and p-type organic semiconductor compounds.

The p-type organic semiconductor compound includes, for example, the following fused polycyclic aromatic low molecular weight compounds, conjugated polymers, and conjugated oligomers.

Examples of the fused polycyclic aromatic low molecular weight compounds include anthracene, tetracene, pentacene, hexacene, heptacene, chrysene, picene, fluminene, pyrene, peropyrene, perylene, terylene, quaterylene, coronene, ovalene, circumanthracene, bisanthene, zeslene, heptazeslene, pyranthrene, biolanten, isobiolanten, circobiphenyl, and anthradithiophene, porphyrin and copper phthalocyanine, tetrathiafulvalene (TTF)-tetracyanoquinodimethane (TCNQ) complexe, and bis-ethylenedithiotetrathiafulvalene (BEDTTTF)-perchlorate complexe, and derivatives and precursors thereof.

Examples of derivatives having the above fused polycyclic rings include pentacene derivatives with substituents described in WO 03/16599, WO 03/28125, U.S. Pat. No. 6,690,029, JP-A 2004-107216, pentacene precursors described in US 2003/136964, acene-based compounds substituted with trialkylsilylethynyl described in J. Amer. Chem. Soc., vol. 127, No. 14, 4986, J. Amer. Chem. Soc., vol. 123, p. 9482, and J. Amer. Chem. Soc. Vol. 130, No. 9, 2706 (2008).

Examples of the conjugated polymers include polythiophene and its oligomers such as poly(3-hexylthiophene) (P3HT), or polythiophene having a polymezable group described in Technical Digest of the International PVSEC-17,. Fukuoka, Japan, 2007, p. 1225, polythiophene-thienothiophene copolymer described in Nature Material, (2006) vol. 5, p. 328, the polythiophene-diketopyrrolopyrrole copolymer described in WO 2008/00066, polythiophene-thiazolothiazole copolymer described in Adv. Mater, 2007, p. 4160, polythiophene copolymer such as PCPDTBT described in Nature Material, (2006) vol. 6, p. 497, polypyrrole and its oligomers, polyaniline, polyphenylene and its oligomers, polyphenylene vinylene and its oligomers, polythienylene vinylene and its oligomers, polyacetylene, polydiacetylene, a-conjugated polymers such as polysilane and polygermanes.

In addition, as oligomeric materials rather than polymeric materials, the thiophene hexamers such as α-sexithiophene, α,ω-dihexyl-α-sexithiophene, α,ω-dihexyl-α-quinquethiophene, α,ω-bis(3-butoxypropyl)-α-sexithiophene, and other oligomers may be suitably used.

There are no particular restrictions on the n-type organic semiconductor compound as long as it is an organic compound that is an acceptor (electron accepting) for the p-type organic semiconductor compound, and any material that may be used in the present technology may be used.

Such compounds may be any compound that has a LUMO level of 0.2 to 0.5 eV or deeper relative to the LUMO level of the p-type organic semiconductor compound. Examples thereof include fullerenes, carbon nanotubes, octaazaporphyrins, perfluorinated compounds in which a hydrogen atom of the above p-type organic semiconductor compound is replaced with a fluorine atom (e.g. perfluoropentacene, perfluorophthalocyanine), polymers having a structure of aromatic carboxylic anhydrides and imide compounds such as naphthalene tetracarboxylic anhydride, naphthalene tetracarboxylic diimide, perylene tetracarboxylic anhydride, and perylene tetracarboxylic diimide.

Of these, it is preferable to use a fullerene or a carbon nanotube or a derivative thereof from the viewpoint of being able to perform charge separation with a p-type organic semiconductor compound at a high speed (about 50 fs) and efficiently. More specific examples are fullerene C60, fullerene C70, fullerene C76, fullerene C78, fullerene C84, fullerene C240, fullerene C540, mixed fullerene, fullerene nanotube, multi-walled carbon nanotube, single-walled carbon nanotube, and a carbon nanohorns (conical), and fullerene derivatives having a portion which is substituted with a halogen atom (a fluorine atom, a chlorine a tom, a bromine atom, an iodine atom), a substituted or unsubstituted alkyl group, alkenyl group, alkynyl group, aryl group, heteroaryl group, cycloalkyl group, silyl group, ether group, thioether group, amino group, thioether group, or amino group.

Particularly preferred compounds are: [6,6]-phenylC61-butyric acid methyl ester (abbreviated PCBM), [6,6]-phenylC61-butyric acid n butyl ester (PCBnB), [6,6]-phenylC61-butyric acid isobutyl ester (PCBiB), [6,6]-phenylC61-butyric acidn-hexyl ester (PCBH), [6,6]-phenylC71-butyric acid methyl ester (abbreviated PC71BM), bis-PCBM described in Adv. Mater. Vol. 20 (2008), p2116, aminated fullerene described in JP-A-2006-199674, metallocene fullerene described in JP-A-2008-130889, fullerene having a cyclic ether group described in U.S. Pat. No. 7,329,709. A fullerene derivative whose solubility is improved by a substituent is preferably used.

As the p-type organic semiconductor compound and the n-type organic semiconductor compound, only one type may be used alone, or two or more types may be used in combination.

The junction form of the p-type organic semiconductor compound and the n-type organic semiconductor compound in the photoelectric conversion layer is preferably a bulk heterojunction (bulk heterojunction). In a bulk heterojunction, a domain of a p-type organic semiconductor compound and a domain of an n-type organic semiconductor compound form a microphase separation structure in a single organic semiconductor material-containing area formed by applying an ink containing a mixture of a p-type organic semiconductor compound and an n-type organic semiconductor compound. In the resulting single organic semiconductor material-containing area, the domains of the p-type organic semiconductor compound and the domains of the n-type organic semiconductor compound have a microphase separation structure.

The mixing ratio of the p-type organic semiconductor and the n-type organic semiconductor contained by the ink is preferably in the range of 2:8 to 8:2 by mass, and more preferably in the range of 3.3:6.7 to 5:5.

### [Organic Semiconductor Material for Organic TFT]

Various fused polycyclic aromatic compounds and conjugated compounds may be applied as organic semiconductor materials used when the organic semiconductor device is an organic TFT.

The organic semiconductor material preferably has an alkyl group for its solubility and affinity with the above-described ink receiving layer. For the alkyl group, the carbon number is 1 to 40, preferably it is 1 to 20.

Examples of the fused polycyclic aromatic compound include anthracene, tetracene, pentacene, hexacene, heptacene, chrysene, picene, fluminene, pyrene, peropyrene, perylene, terylene, quaterylene, coronene, ovalene, circumanthracene, bisanthene, zeslene, heptazeslene, pyranthrene, biolanten, isobiolanten, circobiphenyl, phthalocyanine, porphyrin, and other compounds and derivatives thereof.

Examples of the conjugated compound include polythiophene and oligomers thereof, polypyrrole and oligomers thereof, polyaniline, polyphenylene and oligomers thereof, polyphenylene vinylene and oligomers thereof, polythienylene vinylene and oligomers thereof, polyacetylene, polydiacetylene, tetrathiafulvalene, quinone compounds, cyano compounds such as tetracyanoquinodimethane, fullerene, and derivatives or mixtures thereof can be mentioned.

Among polythiophenes and their oligomers, particularly suitable compounds are the thiophene hexamers such as a-sexithiophene, α,ω-dihexyl-α-sexithiophene, α,ω-dihexyl-α-quinquethiophene, α,ω-bis(3-butoxypropyl)-α-sexithiophene, and other oligomers.

Furthermore, metal phthalocyanines such as copper phthalocyanine and fluorine-substituted copper phthalocyanine described in JP-A 11-251601, naphthalene tetracarboxylic acid diimides such as naphthalene-1,4,5,8-tetracarboxylic acid diimide, N,N′-bis(4-trifluoromethylbenzyl)naphthalene-1,4,5,8-tetracarboxylic acid diimide, N,N′-bis(1H,1H-perfluorooctyl), N,N′-bis(1H,1H-perfluorobutyl) and N,N′-dioctylnaphthalene 1,4,5,8-tetracarboxylic acid diimide derivatives, naphthalene-2,3,6,7-tetracarboxylic acid diimide, anthracene tetracarboxylic acid diimides such as anthracene-2,3,6,7-tetracarboxylic diimide, fullerenes such as C60, C70, C76, C78, and C84, carbon nanotubes such as SWNT, dyes such as merocyanine dyes and hemicyanine dyes.

Among these π-conjugated materials, at least one selected from the group consisting of fused polycyclic aromatic compounds such as pentacene, fullerene, fused ring tetracarboxylic acid diimides, and metal phthalocyanines is preferred.

As other organic semiconductor materials, tetrathiafulvalene (TTF)-tetracyanoquinodimethane (TCNQ) complex, bisethylene tetrathiafulvalene (BEDTTTF)-perchlorate complex, BEDTTTF-iodine complex, and TCNQ-iodine complex may also be used. In addition, σ-conjugated polymers such as polysilane and polygerman, and organic/inorganic hybrid materials described in JP-A 2000-260999 may also be used.

### (Solvent)

The solvent is not particularly limited as long as it may dissolve or disperse a desired amount of the above organic semiconductor material and may discharge droplets from a nozzle of the inkjet head, but it is preferable that the solvent be selected appropriately depending on the type of the organic semiconductor material.

Specific examples of the solvent are water, alcohols such as methanol, ethanol, propanol, isopropyl alcohol, butanol, hexanol, heptanol, octanol, decanol, cyclohexanol, terpineol; hydrocarbon compounds such as n-heptane, n -octane, decane, dodecane, tetradecane, toluene, xylene, cymene, durene, indene, dipentene, tetrahydronaphthalene, decahydronaphthalene, and cyclohexylbenzene; ethers such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl) ether, p-dioxane; glycol ether ester compounds such as ethylene glycol monomethyl ether acetate; glycol oligomeric ether esters such as diethylene glycol monomethyl ether acetate, and diethylene glycol monobutyl ether acetate; aliphatic or aromatic esters such as ethyl acetate, n-propyl acetate, propyl benzoate; dicarboxylic acid diesters such as diethyl carbonate; alkoxycarboxylic acid esters such as methyl 3-methoxypropionate and ethyl 3-ethoxypropionate; ketocarboxylic acid esters such as ethyl acetoacetate, as well as polar compounds such as propylene carbonate, γ-butyrolactone, N-methyl-2-pyrrolidone, dimethylformamide, dimethyl sulfoxide, cyclohexanone, and cyclohexanone.

The solvent is selected appropriately according to the type of the organic semiconductor material and the constituent materials of the ink receiving layer, and by taking into account the solubility or dispersibility for the organic semiconductor material and the SP value described above.

The state in which an ink In is dropped onto the ink receiving layers 4A and 4B and the organic semiconductor material-containing area 5 is formed, that is, the state of the organic semiconductor layer, may be observed by the following method.

### (Observation of Ink Retention State)

For the observation of the state of the ink receiving layer, general analysis and analytical means used for the observation of nanometer-order organic thin films may be used.
(1) By elemental mapping using SEM (scanning electron microscope) or TEM (transmission electron microscope) of a cross-section of a material for an organic semiconductor device, it is possible to visually observe how the ink is retained in the organic semiconductor material-containing area 5 in the ink receiving layer. In particular, it is possible to visually observe whether or not the organic semiconductor material in the ink is in contact with the electrode of the lower layer, which is important in the present invention.
(2) By performing time-of-flight secondary ion mass spectrometry (TOF-SIMS) in the thickness direction from the dot area (exposed portion D of the organic semiconductor material-containing area 5), it is possible to visually observe how the ink is retained in the organic semiconductor material-containing area 5 in the ink receiving layer. In particular, it is possible to visually observe whether or not the organic semiconductor material in the ink is in contact with the electrode of the lower layer, which is important in the present invention.
(3) A conductive diamond-coated cantilever for AFM is pressed against the dot site (exposed portion D of the organic semiconductor material-containing area 5), and the presence or absence of electrode exposure may be confirmed by using the fact that a current flows when the electrode of the lower layer is reached.

### [Production Method of Organic Semiconductor Device]

The method for producing an organic semiconductor device of the present invention is a method for producing an organic semiconductor device using the inkjet recording medium for an organic semiconductor device of the present invention, and is characterized by having the following steps.
(I) the step of dropping an ink onto an ink receiving layer
(II) After the step of (I), the step of depositing an electrode 7 which is paired with the electrode 3 on the ink receiving layer.

### (I) Ink Dropping Step

The ink dropping step is a step of dropping an ink containing an organic semiconductor material onto an ink receiving layer to make a part of the ink receiving layer a region containing an organic semiconductor material. As a result, for example, a member for an organic semiconductor device having the configuration of the present invention is obtained.

In the ink dropping step, the ink is dropped onto the ink receiving layer by an inkjet method. FIG. 5 is a cross-sectional view illustrating the ink dropping process in an example of the manufacturing method of the organic semiconductor device. In FIG. 5, a step of dropping an ink In from a head 12 of an inkjet apparatus 11 corresponding to the inkjet method onto a surface S of an ink receiving layer 4A of an inkjet recording medium 1 is shown.

The inkjet method is advantageous over other coating methods in that it may form small droplets of the ink In, thereby forming a fine pattern. The inkjet method is also advantageous in this respect because it is a non-contact printing method that causes little damage to the ink receiving layer.

In the ink dropping step according to the manufacturing method of the present invention, the volume of the ink droplet at the time of dropping depends on the fineness of the dot pattern according to the specifications of the organic semiconductor device, but for example, it is preferable to be 10 μL or less, and more preferably to be 100 pL or less.

In the manufacturing method of the present invention, as the inkjet apparatus 11, a publicly known inkjet apparatus may be applied as appropriate. For example, IJCS-1 (manufactured by Konica Minolta, Inc.) may be used.

The head scan speed is preferably a value at which the dot pitch in the scanning direction may be set to an appropriate value (50 to 500 82 m), preferably it is 10 to 200 mm/sec, and more preferably it is 80 to 100 mm/sec.

The head 12 applicable to the method for manufacturing an organic semiconductor device according to the present invention is not particularly limited. For example, it may be a shear mode type (piezo type) head having a diaphragm with a piezoelectric element in an ink pressure chamber and ejecting ink by a pressure change in the ink pressure chamber caused by the diaphragm, or it may be a thermal type head having a heat generating element and ejecting ink from a nozzle by a sudden volume change caused by film boiling of ink by thermal energy from the heat generating element.

The head 12 preferably have specifications capable of forming picoliter level droplets, and for example, KM512 or KM1024 (manufactured by Konica Minolta, Inc.) may be used.

After the ink is dropped and before the fabrication of the counter electrode in (II), the solvent contained in the ink is removed as necessary. The method for removing the solvent is, for example, a heat treatment or a decompression treatment. In the manufacturing method of the present invention, it is preferable to remove the solvent by holding the solvent at room temperature (25° C.) to 150° C. as the processing temperature and holding under atmospheric pressure for about 0.1 to 60 minutes.

### (II) Preparation of the Counter Electrode

The method of forming the counter electrode 7 on the ink receiving layer (organic semiconductor layer) of the organic semiconductor device member after the above (I) process is described above.

### (Configuration of Organic Semiconductor Device)

FIG. 6 shows a cross-sectional view of an example of an organic semiconductor device obtained by the manufacturing method of the present invention. Specifically, FIG. 6 shows an organic semiconductor device 100 finally obtained by using the inkjet recording medium 1 shown in FIG. 1 and passing through the material 10A for the organic semiconductor device of the present invention shown in FIG. 2 and FIG. 3. The organic semiconductor device 100 is an organic semiconductor device that has been precisely manufactured by the manufacturing method of the present invention described above in a simple process.

In the organic semiconductor device 100, the organic semiconductor device in which the organic semiconductor device member 10A is replaced by the organic semiconductor device member 10B may also be manufactured with high accuracy using a simple process.

The organic semiconductor device 100 shown in FIG. 6 is composed of a base material 2, an electrode 3, an organic semiconductor layer 6, and a counter electrode 7 stacked in that order. The organic semiconductor device may have other organic functional layers other than the organic semiconductor layer 6, such as an electron transport layer and a hole transport layer. For example, when the counter electrode 7 is a cathode, a hole blocking layer (also referred to as a hole barrier layer) or an electron injection layer (also referred to as a cathode buffer layer) may be provided between the organic semiconductor layer 6 and the counter electrode 7. Further, when the counter electrode 7 is an anode, an electron blocking layer (also referred to as an electron barrier layer) or a hole injection layer (also referred to as an anode buffer layer) may be provided between the organic semiconductor layer 6 and the counter electrode 7.

The “electron transport layer” in the present invention is a layer having a function to transport electrons, and in a broad sense, an electron injection layer and a hole blocking layer are also included in the electron transport layer. The electron transport layer may be composed of multiple layers.

In the present invention, a “hole transport layer” is a layer having a function of transporting holes, and in a broad sense, a hole injection layer and an electron blocking layer are also included in a hole transport layer. It may also be composed of multiple layers.

The organic semiconductor device to which the manufacturing method of the present invention is applied includes an organic EL element, an organic TFT, and an organic photoelectric conversion device.

### [Organic EL Element]

Specifically, the organic EL element according to the present invention has a configuration in which the organic semiconductor layer 6 is a light-emitting layer. The light-emitting layer in the organic EL element is, for example, a layer that provides a place where electrons and holes injected from an electrode or an adjacent layer recombine and emit light via excitons, and the emitting portion may be within a layer of the light-emitting layer or at a boundary surface between the light-emitting layer and an adjacent layer.

Although there is no particular restriction on the thickness of the luminescent layer, from the viewpoint of homogeneity of the layer to be formed, prevention of application of an unnecessarily high voltage during luminescence, and improvement of stability of the luminescent color with respect to the drive current, it is preferably adjusted within the range of 3 nm to 5 μm, more preferably within the range of 2 nm to 500 nm, and still more preferably within the range of 5 nm to 200 nm.

In the organic EL element, the luminescent compound is contained in the light-emitting layer within a range of 1 to 80 mass %, and in particular, it is preferable that the luminescent compound is contained within a range of 5 to 40 mass %.

Hereinafter, the other organic functional layers in the organic EL layers will be described.

### <Electron Transport Layer>

An electron transport layer is composed of a material having a function of transferring an electron. It is a layer having a function of transporting an injected electron from a cathode to a light-emitting layer.

A layer thickness of the electron transport layer is not specifically limited, however, it is generally in the range of 2 nm to 5 μm, and preferably, it is in the range of 2 to 500 nm, and more preferably, it is in the range of 5 to 200 nm.

As a material used for an electron transport layer (hereinafter, it is called as “an electron transport material”), it is only required to have either a property of ejection or transport of electrons, or a barrier to holes. Any of the conventionally known compounds may be selected and they may be employed.

Examples of the known compound: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material. A distyryl pyrazine derivative, which is exemplified as a material for a light-emitting layer, may be used as an electron transport material. Further, in the same manner as used for a hole injection layer and a hole transport layer, an inorganic semiconductor such as an n-type Si and an n-type SiC may be also utilized as an electron transport material. A polymer material which is introduced these compounds in the polymer side-chain or a polymer main chain may be used.

In an electron transport layer according to the present invention, it is possible to employ an electron transport layer of a higher n property (electron rich) which is doped with impurities as a guest material. As examples of a dope material, listed are those described in each of JP-A Nos. 4-297076, 10-270172, 2000-196140, 2001-102175, as well as in J. Appl. Phys., 95, 5773 (2004).

Although the present invention is not limited thereto, preferable examples of a known electron transport material used in an organic EL element of the present invention are compounds described in the following publications.

U.S. Pat. Nos. 6,528,187, 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

Examples of a preferable electron transport material are: a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative. An electron transport material may be used singly, or may be used in combination of plural kinds of compounds

### <Hole Blocking Layer>

A hole blocking layer is a layer provided with a function of an electron transport layer in a broad meaning. Preferably, it contains a material having a function of transporting an electron, and having very small ability of transporting a hole. It will improve the recombination probability of an electron and a hole by blocking a hole while transporting an electron. Further, a composition of an electron transport layer described above may be appropriately utilized as a hole blocking layer of the present invention when needed.

A hole blocking layer placed in an organic EL element of the present invention is preferably arranged at a location in the light-emitting layer adjacent to the cathode side. A thickness of a hole blocking layer according to the present invention is preferably in the range of 3 to 100 nm, and more preferably, in the range of 5 to 30 nm.

With respect to a material used for a hole blocking layer, the material used in the aforesaid electron transport layer is suitably used.

### <Electron Injection Layer>

An electron injection layer (it is also called as “a cathode buffer layer”) according to the present invention is a layer which is arranged between a cathode and a light-emitting layer to decrease an operating voltage and to improve an emission luminance An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

In the present invention, an electron injection layer is provided according to necessity, and as described above, it is placed between a cathode and a light-emitting layer, or between a cathode and an electron transport layer. An electron injection layer is preferably a very thin layer. The layer thickness thereof is preferably in the range of 0.1 to 5 nm depending on the materials used.

An election injection layer is detailed in JP-A Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials. The above-described materials may be used singly or plural kinds may be used together in an election injection layer.

<Hole Transport layer>

In the present invention, a hole transport layer contains a material having a function of transporting a hole. A hole transport layer is only required to have a function of transporting a hole injected from an anode to a light-emitting layer. The layer thickness of a hole transport layer of the present invention is not specifically limited, however, it is generally in the range of 5 nm to 5 μm, preferably in the range of 2 to 500 nm, and more preferably in the range of 5 nm to 200 nm.

A material used in a hole transport layer (hereinafter, it is called as “a hole transport material”) is only required to have any one of properties of injecting and transporting a hole, and a barrier property to an electron. A hole transport material may be suitably selected from the conventionally known compounds.

Examples of a hole transport material include: a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or an oligomer (e.g., PEDOT: PSS, an aniline type copolymer, polyaniline and polythiophene).

Examples of a triarylamine derivative include: a benzidine type represented by α-NPD, a star burst type represented by MTDATA, a compound having fluorenone or anthracene in a triarylamine bonding core. A hexaazatriphenylene derivative described in JP-A Nos. 2003-519432 and 2006-135145 may be also used as a hole transport material. In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an ortho-metal compounds having Ir or Pt as a center metal represented by Ir(ppy)₃ are also preferably used. Although the above-described compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain

Specific examples of a known hole transport material used in an organic EL element of the present invention are compounds in the aforesaid publications and in the following publications. However, the present invention is not limited to them.

Examples of the publication are: Appl. Phys. Lett. 69, 2160 (1996), J. Lumin. 72-74, 985 (1997), Appl. Phys. Lett. 78, 673 (2001), Appl. Phys. Lett. 90, 183503 (2007), Appl. Phys. Lett. 51, 913 (1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. Ser. No. 13/585,981. A hole transport material may be used singly or may be used in combination of plural kinds of compounds.

### <Electron Blocking Layer>

An electron blocking layer is a layer provided with a function of a hole transport layer in a broad meaning. Preferably, it contains a material having a function of transporting a hole, and having very small ability of transporting an electron. It will improve the recombination probability of an electron and a hole by blocking an electron while transporting a hole. Further, a composition of a hole transport layer described above may be appropriately utilized as an electron blocking layer of an organic EL element when needed.

An electron blocking layer placed in an organic EL element is preferably arranged at a location in the light-emitting layer adjacent to the anode side. A thickness of an electron blocking layer is preferably in the range of 3 to 100 nm, and more preferably, it is in the range of 5 to 30 nm.

With respect to a material used for an electron blocking layer, the material used in the aforesaid hole transport layer is suitably used.

### <Hole Injection Layer>

A hole injection layer (it is also called as “an anode buffer layer”) is a layer which is arranged between an anode and a light-emitting layer to decrease an operating voltage and to improve an emission luminance. An example of a hole injection layer is detailed in volume 2, chapter 2 “Electrode materials” (pp. 123-166) of “Organic EL Elements and Industrialization Front thereof (Nov. 30, 1998, published by N.T.S. Co. Ltd.)”. A hole injection layer is provided according to necessity, and as described above, it is placed between an anode and a light-emitting layer, or between an anode and a hole transport layer.

A hole injection layer is also detailed in JP-A Nos. 9-45479, 9-260062 and 8-288069. As materials used in the hole injection layer, it is cited the same materials used in the aforesaid hole transport layer.

Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine) iridium complex; and a triarylamine derivative.

The above-described materials used in a hole injection layer may be used singly or plural kinds may be co-used.

### <Other Additive>

The above-described organic functional layer of the present invention may further contain other additive. Examples of the other additive are: halogen elements such as bromine, iodine and chlorine, and a halide compound; and a compound, a complex and a salt of an alkali metal, an alkaline earth metal and a transition metal such as Pd, Ca and Na.

Although a content of the additive may be arbitrarily decided, preferably, it is 1,000 ppm or less based on the total mass of the layer containing the ingredient, more preferably, it is 500 ppm or less, and still more preferably, it is 50 ppm or less. In order to improve a transporting property of an electron or a hole, or to facilitate energy transport of an exciton, the content of the additive is not necessarily within these range.

The method for forming an organic functional layer other than the organic semiconductor layer (for example, a hole injection layer, a hole transport layer, a hole blocking layer, an electron transport layer, an electron injection layer) is not particularly limited, and a conventionally known method may be adopted. For forming the organic functional layer, for example, a vacuum vapor deposition method, a wet process may be used. As the wet process, a method similar to the method for forming the ink receiving layer may be adopted.

When a vapor deposition method is adopted for forming each organic functional layer, the vapor deposition conditions may be changed depending on the compounds used. Generally, the following ranges are suitably selected for the conditions, heating temperature of boat: 50 to 450° C., level of vacuum: 1×10⁻⁶ to 1×10⁻² Pa, vapor deposition rate: 0.01 to 50 nm/sec, temperature of substrate: −50 to 300° C., and layer thickness: 0.1 nm to 5 μm, preferably 5 to 200 nm.

A different film forming method may be applied to every organic functional layer.

When applied to various applications, the organic EL element is used by sealing it as follows, for example. As sealing means employed in the present invention, listed may be, for example, a method in which a sealing member, an electrode, and a support substrate are subjected to adhesion via adhesives. The sealing member may be arranged to cover the display area of an organic EL element, and may be a concave plate or a flat plate. Neither transparency nor electrical insulation is limited.

Specifically listed sealing members are glass plates, polymer plates, polymer films, metal plates, and metal films. As glasses constituting glass plates, specifically listed are soda-lime glass, barium-strontium containing glass, lead glass, aluminosilicate glass, borosilicate glass, barium borosilicate glass, and quartz. Further, as resins constituting polymer plates and polymer films, listed are a polycarbonate resin, an aciyl resin, polyester resins such as PET and PEN, a polyether sulfide resin, and a polysulfone resin. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to achieve a thin organic EL element, it is preferable to employ a polymer film or a metal film. Further, it is preferable that the polymer film has an oxygen permeability of 1×10⁻³ mL/m²/₂4 h or less determined by the method based on JIS K 7126-1987, and a water vapor permeability (at temperature of 25±0.5° C. and relative humidity of (90±2) %RH) of 1×10⁻³ g/(m²/₂4 h) or less determined by the method based on JIS K 7129-1992.

Conversion of the sealing member into concave is carried out by employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type UV curable epoxy resin adhesives.

In addition, since an organic EL element is occasionally deteriorated via a thermal process, preferred are those which enable adhesion and curing between a room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials that form the aforesaid film may be those which exhibit functions to retard penetration of moisture or oxygen which results in deterioration. For example, it is possible to employ silicon oxide, silicon dioxide, and silicon nitride.

Still further, in order to improve brittleness of the film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

It is preferable to inject a gas phase and a liquid phase material of inert gases such as nitrogen or argon, and inactive liquids such as fluorinated hydrocarbon or silicone oil into the space between the space formed with the sealing member and the display area of the organic EL element. Further, it is possible to form vacuum in the space. Still further, it is possible to enclose hygroscopic compounds in the interior of the space.

Examples of a hygroscopic compound include: metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). For sulfate salts, metal halides and perchlorates, suitably used are anhydrous salts.

The organic EL element is sealed as described above when applied to various applications. Further, a protective film or a protective plate for increasing the mechanical strength of the device may be provided on the outside of the sealing film or the sealing film on the side facing the base material with the organic functional layer sandwiched therein. Specifically, when sealing is achieved via the aforesaid sealing film, the resulting mechanical strength is not always high enough, therefore it is preferable to arrange the protective film or the protective plate described above. Usable materials for these include glass plates, polymer plate-films, and metal plate-films which are similar to those employed for the aforesaid sealing. However, from the viewpoint of reducing weight and thickness, it is preferable to employ a polymer film.

### <Improving Method of Light Extraction>

It is generally known that an organic EL element emits light in the interior of the layer exhibiting the refractive index (being about 1.6 to 2.1) which is greater than that of air, whereby only about 15% to 20% of light generated in the light-emitting layer is extracted. This is due to the fact that light incident to an interface (being an interlace of a transparent substrate to air) at an angle of θ which is at least critical angle is not extracted to the exterior of the element due to the resulting total reflection, or light is totally reflected between the transparent electrode or the light-emitting layer and the transparent substrate, and light is guided via the transparent electrode or the light-emitting layer, whereby light escapes in the direction of the element side surface.

Means to enhance the efficiency of the light extraction include, for example: a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light-emitting body and an antireflection film is formed (JP-A No. 62-172691), a method in which a flat layer of a refractive index which is equal to or less than the substrate is introduced between the substrate and the light-emitting body (JP-A No. 2001-202827), and a method in which a diffraction grating is formed between the substrate and any of the layers such as the transparent electrode layer or the light-emitting layer (including between the substrate and the outside) (JP-A No. 11-283751).

The method in which the interface which results in total reflection or a diffraction grating is introduced in any of the media is characterized in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light entitling layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light-emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced. However, by changing the refractive index distribution to a two-dimensional one, light, which travels to all directions, is diffracted, whereby the light extraction efficiency is enhanced.

A position to introduce a diffraction grating may be between any layers or in a medium (in a transparent substrate or a transparent electrode). However, a position near the organic light-emitting layer, where light is generated, is preferable. In this case, the cycle of the diffraction grating is preferably from about 1/2 to 3 times of the wavelength of light in the medium. The preferable arrangement of the diffraction grating is such that the arrangement is two-dimensionally repeated in the form of a square lattice, a triangular lattice, or a honeycomb lattice.

### <Light Collection Sheet>

Via a process to arrange a structure such as a micro-lens array shape on the light extraction side of the organic EL element of the present invention or via combination with a so-called light collection sheet, light is collected in the specific direction such as the front direction with respect to the light-emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 to 100 μm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, A shaped stripes of an apex angle of 90 degrees and a pitch of 50 μm formed on a substrate, a shape in which the apex angle is rounded, a shape in which the pitch is randomly changed, and other shapes may be used.

Further, in order to control the light radiation angle from the organic EL element, simultaneously employed may be a light diffusion plate-film. For example, it is possible to employ the diffusion film (LIGHT-UP), produced by Kimoto Co., Ltd.

### (Applications)

An organic semiconductor device of the present invention, for example, an organic EL element, may be suitably used for a display device that displays a high-quality color image. Further, the organic EL element according to the present invention may be suitably used for lighting devices such as home lighting and vehicle interior lighting.

The organic EL element according to the present invention may be used as a light-emitting light source in other application. For example, it may be used as a backlight for a clock or a liquid crystal, a signboard advertisement, a traffic light, a light source of an optical storage medium, a light source of an electrophotographic copying machine, a light source of an optical communication processor, and a light source of an optical sensor.

The organic semiconductor device of the present invention, for example, an organic photoelectric conversion element may be suitably used for an organic thin film solar cell. Further, the organic photoelectric conversion element may be used as an optical sensor array in which the organic photoelectric conversion elements are arranged in an array. That is, the organic photoelectric conversion element of the present embodiment may also be used as an optical sensor array that converts an image projected on the optical sensor array into an electrical signal by utilizing the photoelectric conversion function.

### EXAMPLES

Hereinafter, the present invention will be specifically described with reference to examples, but the present invention is not limited thereto. In the examples, the indication of “part” or “%” is used, but unless otherwise specified, it represents “part by mass” or “mass %”.

### [Inkjet Recording Medium for Organic Semiconductor Device]

Using a polyethylene film substrate on which a 100 nm film of ITO is formed as an electrode (anode) (hereinafter referred to as a “substrate 1 with ITO”), which has been ultrasonically cleaned with isopropyl alcohol, dried with dry nitrogen gas, and cleaned with UV ozone, an inkjet recording medium for an organic semiconductor device of each example was manufactured.

### (Inkjet Recording Medium 1-1 for an Organic Semiconductor Device)

A 1.0% n-propyl acetate solution of polystyrene (manufactured by ACROS ORGANICS Corporation, weight average molecular weight 260,000, denoted by “PS1” in Table I. The same applies hereinafter.) was deposited on the ITO of the substrate 1 with ITO by a spin coating method under the conditions of 500 rpm and 30 seconds to form a coating film, and then dried at 120° C. for 30 minutes. Thus, an inkjet recording medium 1-1 for an organic semiconductor device provided with a polystyrene ink receiving layer having a layer thickness of 50 nm was produced.

### (Inkjet Recording Medium 2-1 for an Organic Semiconductor Device)

An ink receiving layer comprising the following two layers (an ink insoluble layer and an ink penetrating layer) was formed on the ITO of the substrate 1 with ITO to fabricate an inkjet recording medium 2-1 for an organic semiconductor device.

A 1.0% chlorobenzene solution of POLY-TPD [N,N′-bis(4-butylphenyl)-N,N′-bis(phenyl)-benzidine] (Fujifilm Wako Pure Chemical Co. Ltd; LT-N149, weight average molecular weight 45,000, denoted by “PTPD” in Table I) was deposited on the ITO of the substrate 1 with ITO by a spin coating method under the conditions of 500 rpm and 30 seconds to form a coating film, then dried at 120° C. for 30 minutes. Further, a coating film for the following ink penetrating layer was formed on the obtained coating film, and then dried together with the coating film for the ink penetrating layer under the following conditions to form a POLY-TPD layer (an ink insoluble layer) having a layer thickness of 50 nm.

A 1.0% n-propyl acetate solution of polystyrene (ACROS ORGANICS Corporation, weight average molecular weight 260,000) was deposited by a spin coating method at 500 rpm for 30 seconds to form a coating film, and then dried at 120° C. for 30 minutes to form a polystyrene layer (ink penetrating layer) having a layer thickness of 50 nm.

### (Inkjet Recording Medium 2-2 for an Organic Semiconductor Device)

An ink receiving layer comprising the following two layers (an ink insoluble layer and an ink penetrating layer) was formed on the ITO of the substrate 1 with ITO to fabricate an inkjet recording medium 2-2 for an organic semiconductor device.

A 0.5% chlorobenzene solution of high molecular weight polystyrene (Aldrich Corporation, weight average molecular weight 400,000, denoted by “PS2” in Table I. The same applies hereinafter.) was deposited by a spin coating method under the conditions of 100 rpm for 30 seconds to form a coating film. Further, a coating film for the following ink penetrating layer was formed on the obtained coating film, and then dried together with the coating film for the ink penetrating layer under the following conditions to form a high molecular weight polystyrene layer having a layer thickness of 30 nm.

A 1.0% n-propyl acetate solution of polystyrene (ACROS ORGANICS Corporation, weight average molecular weight 260,000) was deposited by a spin coating method at 500 rpm for 30 seconds to form a coating film, and then dried at 120° C. for 30 minutes to form a polystyrene layer (ink penetrating layer) having a layer thickness of 50 nm.

### (Inkjet Recording Medium 2-3 for an Organic Semiconductor Device)

An ink receiving layer comprising the following two layers (an ink insoluble layer and an ink penetrating layer) was formed on the ITO of the substrate 1 with ITO to fabricate an inkjet recording medium 2-3 for an organic semiconductor device.

To 1000 μL of a 1.0% n-propyl acetate solution of polystyrene (ACROS ORGANICS Corporation, weight average molecular weight 260,000) was added 50 μL of ethyl 2-cyanoacrylate (Aldrich Corporation). After addition, a coating film was formed by a spin coating method at 1000 rpm for 30 seconds. Further, a coating film for the following ink penetrating layer was formed on the obtained coating film, and then dried together with the coating film for the ink penetrating layer under the following conditions to form a polystyrene layer having a IPN (Interpenetrating Polymer Network) structure with a layer thickness of 30 nm (indicated by “IPN-PS” in Table I).

A 1.0% n-propyl acetate solution of polystyrene (ACROS ORGANICS Corporation, weight average molecular weight 260,000) was deposited by a spin coating method at 500 rpm for 30 seconds to form a coating film, and then dried at 120° C. for 30 minutes to form a polystyrene layer with a layer thickness of 50 nm.

### (Inkjet Recording Medium 2-4 for an Organic Semiconductor Device)

An ink receiving layer comprising the following two layers (an ink insoluble layer and an ink penetrating layer) was formed on the ITO of the substrate 1 with ITO to fabricate an inkjet recording medium 2-4 for an organic semiconductor device.

A 0.5% chlorobenzene solution of high molecular weight polystyrene (manufactured by Aldrich Corporation, weight average molecular weight 400,000) was deposited by a spin coating method at 100 rpm for 30 seconds to form a coating film. Further, a coating film for the following ink penetrating layer was formed on the obtained coating film, and then dried together with the coating film for the ink penetrating layer under the following conditions to obtain a high molecular weight polystyrene layer having a layer thickness of 30 nm.

A 0.7% n-propyl acetate solution of the poly(bisphenol A carbonate) (Aldrich Corporation, weight average molecular weight 45,000, denoted by “PC” in Table I) was deposited by a spin coating method at 500 rpm for 30 seconds to form a coating film, and then dried at 120° C. for 30 minutes to form a poly(bisphenol A carbonate) layer having a layer thickness of 50 nm.

### <State Observation of the Ink Receiving Layer>

SEM observation of the cross-section of the thin film of the inkjet recording medium 1-1 for an organic semiconductor device showed that an organic thin film composed of one layer (film thickness: 50 nm) was observed as designed. In the same way, measurements were also performed on inkjet recording media 2-1 to 2-4 for an organic semiconductor device, and organic layers composed of two layers (an ink insoluble layer and an ink penetrating layer) according to the design were confirmed. The composition of the ink receiving layer of the obtained inkjet recording media for an organic semiconductor device is shown in Table I.

TABLE I

| | | | | | | | | | Layer |
|---|---|---|---|---|---|---|---|---|---|
| Inkjet | Ink insoluble layer | | | | Ink penetrating layer | | | | thickness of |
| recording | | | Layer | | | | Layer | | the entire ink |
| medium | | Mw | thickness | SP(M1) | | Mw | thickness | SP(M2) | receiving layer |
| No. | Resin B | [×10³] | [nm] | (J/cm³)^{1/2} | Resin A | [×10³] | [nm] | (J/cm³)^{1/2} | [nm] |
| 1-1 | — | — | 0 | — | PS1 | 260 | 50 | 17.4 | 50 |
| 2-1 | PTPD | 45 | 50 | 21.5 | PS1 | 260 | 50 | 17.4 | 100 |
| 2-2 | PS2 | 400 | 30 | 21.1 | PS1 | 260 | 50 | 17.4 | 80 |
| 2-3 | IPN-PS | — | 30 | —※ | PS1 | 260 | 50 | 17.4 | 80 |
| 2-4 | PS2 | 400 | 30 | 21.1 | PC | 45 | 50 | 20.0 | 80 |

※The SP value cannot be determined due to insoluble treatment

[Member for Organic Semiconductor Device]

A member for an organic semiconductor device was produced using the inkjet recording medium for an organic semiconductor device obtained above and the inkjet recording medium 1-2 for an organic semiconductor device manufactured as follows.

### (Production of an Inkjet Recording Medium 1-2 for an Organic Semiconductor Device)

A 1.5% n-propyl acetate solution of polystyrene (ACROS ORGANICS Corporation, weight average molecular weight 260,000) was deposited on the ITO of the substrate 1 with ITO by a spin coating method at 500 rpm for 30 seconds, and then dried at 120° C. for 30 minutes to form a polystyrene ink receiving layer having a layer thickness of 80. Then, the film was dried at 120° C. for 30 minutes to produce an inkjet recording medium 1-2 for an organic semiconductor device having a polystyrene ink receiving layer with a thickness of 80 nm.

### (Production of Member for an Organic Semiconductor Device)

An ink 1 produced as follows was dropped onto the ink receiving layer of the inkjet recording medium 1-1 for an organic semiconductor device produced above by the following inkjet method. Thus, a member 1-1 for an organic semiconductor device in which a dot region was formed with the pattern shown in FIG. 2 was produced.

The ink was dropped without a time interval after the production of the inkjet recording medium 1-1 for an organic semiconductor device.

Inkjet recording media 1-2, 2-1 to 2-4 for an organic semiconductor device were used instead of an inkjet recording medium 1-1 for an organic semiconductor device to produce members 1-2, 2-1 to 2-4 for an organic semiconductor device.

### (Production of Ink 1)

Tris[2-(p-tolyl)pyridine]iridium(III) (Ir(mppy)₃; emitting green), which is a luminescent compound, was mixed with n-propyl acetate as a solvent at a concentration of 1 mass %. After heating with ultrasonic waves to maintain the temperature at 90° C. for 30 minutes, it was filtered through a 0.2 tμm filter to remove the agglomerated component, and an ink 1 was prepared. The viscosity of the ink 1 was 0.6 mPa·s. The SP value of Ir(mppy)₃ is 20.3 (J/cm³)^{1/2}, and the SP value of n-propyl acetate SP(S) is 18.0 (J/cm³)^{1/2}. Therefore, the SP value of the ink 1, SP(I), is 18.0 (J/cm³)^{1/2}.

### (Conditions of Inkjet Method)

Inkjet apparatus: IJCS-1 made by Konica Minolta, Inc. Inkjet head: KM512 made by Konica Minolta, Inc.

Number of shots: 2 shots

Distance between discharge nozzles of the head: 140 μm pitch

Head scan speed: 90 mm/sec.

### <Evaluation: Observation of the Ink Retention State of the Ink Receiving Layer>

For each of the organic semiconductor device members obtained above, the ink discharge into the ink receiving layer and the ink retention state were examined.

Elemental mapping using SEM (a scanning electron microscope) of the cross section of the thin film of the dot portion of the organic semiconductor device member 1-1 revealed that the Ir element contained in the luminescent compound and the In element, which is a component derived from the electrode, are in contact. In exactly the same way, (2) TOF-SIMS method and (3) conductivity measurement using a conductive diamond-coated cantilever for AFM described in (Observation of ink retention state) also showed that the ink component and the electrode of the lower layer were in contact.

When elemental mapping using SEM was performed for the organic semiconductor device members 1-2 and 2-1 to 2-4, it was observed that the Ir element contained in the luminescent compound and the In element, which is a component derived from the electrode, were not in contact. It was observed that the Jr element in the luminescent compound was not in contact with the In element, which is a component from the electrode. In the same way, the existence of an organic layer between the ink component and the electrode-derived component was observed by TOF-SIMS, supporting the results of the elemental mapping.

The results are shown in Table II together with the configuration of the ink receiving layer of the member for the organic semiconductor device. In Table II, the penetration depth of the ink (the thickness Th of the organic semiconductor-containing area 5), and |SP (M1) -SP (I)| value (indicated as “SP value difference 1” in Table II), and |SP(M2)-SP(I)| (indicated as “SP value difference 2” in Table II) are shown.

TABLE II

| | | | | | | | | | | Thickness | | |
|---|---|---|---|---|---|---|---|---|---|---|---|---|
| | | | | | | | | | | of organic | | |
| | | Ink insoluble | | Ink penetrating | | | | | | semi- | | |
| | | layer | | layer | | Ink receiving layer | | | | conductor | | |
| | Inkjet | | Layer | | Layer | | Layer | SP value | SP value | material- | Presence or | |
| | recording | Con- | thick- | Con- | thick- | | thick- | differ- | differ- | containing | absence of | |
| | medium | stituting | ness | stituting | ness | Layer | ness | ence 1 | ence 2 | area | contact with | |
| *1 | No. | material | [nm] | material | [nm] | number | [nm] | (J/cm³)^{1/2} | (J/cm³)^{1/2} | [nm] | electrode | Remarks |
| 1-1 | 1-1 | — | 0 | PS1 | 50 | 1 | 50 | 0.6 | — | 50 | Presence | *3 |
| 1-2 | 1-2 | — | 0 | PS1 | 80 | 1 | 80 | 0.6 | — | 75 | Absence | *4 |
| 2-1 | 2-1 | PTPD | 50 | PS1 | 50 | 2 | 100 | 0.6 | 3.5 | 50 | Absence | *4 |
| 2-2 | 2-2 | PS2 | 30 | PS1 | 50 | 2 | 80 | 0.6 | 3.1 | 50 | Absence | *4 |
| 2-3 | 2-3 | IPN-PS | 30 | PS1 | 50 | 2 | 80 | 0.6 | —*2 | 50 | Absence | *4 |
| 2-4 | 2-4 | PS2 | 30 | PC | 50 | 2 | 80 | 2.0 | 3.1 | 50 | Absence | *4 |

*1: Organic semiconductor device member No.
*2The SP value cannot be determined due to insoluble treatment
*3: Comparative Example
*4: Present Invention

[Production of Organic Semiconductor Device (Organic EL Element)]

Using the organic semiconductor device member 2-2 obtained above, an organic EL element 2-2 was fabricated as follows.

Immediately after manufacturing the member 2-2 for an organic semiconductor device, the member was mounted on a vacuum deposition apparatus, the vacuum chamber was depressurized to 4×10⁻⁴ Pa, and an electron injection layer and an electrode (cathode) were formed under the following conditions. The electron injection layer was formed by evaporating potassium fluoride at a deposition rate of 0.1 A/sec to a thickness of 2.0 nm. The electrode was formed by evaporating A1 at a deposition rate of 4 A/sec to a thickness of 100 nm. The organic EL element 2-2 was fabricated by the above process. In the same manner, using the organic semiconductor device members 1-1, 1-2, 2-1, 2-3, and 2-4 obtained above, an organic EL elements 1-1, 1-2, 2-1, 2-3, and 2-4 were fabricated.

### <Evaluation: Repeated Stability of Organic EL Element>

As described below, the obtained organic EL elements 1-1, 1-2, 2-1 to 2-4 were sealed to produce a light-emitting device for evaluation, and the repeated stability of the light emission of the organic EL element was evaluated as follows.

### (Preparation of Light-Emitting Device for Evaluation)

A gas barrier film was prepared as a sealing member for the entire organic EL element as follows. That is, an inorganic gas barrier layer comprising SiOₓ was formed on the entire surface of a polyethylene naphthalate film (manufactured by Teijin Film Solutions Ltd.) to a layer thickness of 500 nm using an atmospheric pressure plasma discharge treatment apparatus of the configuration described in JP-A 2004-68143. As a result, a flexible gas barrier film having a gas barrier property with an oxygen permeability of 0.001 ml/(m²·24 h) or less and a water vapor permeability of 0.001 g/(m²·24 h) or less was produced.

Then, a thermosetting liquid adhesive (epoxy resin) layer with a thickness of 25 μm was formed on one side of the gas barrier film as a sealing resin layer. Then, the gas barrier film with the sealing resin layer was superimposed on the organic EL element 2-2. At this time, the sealing resin layer-formed surface of the gas barrier film was continuously overlaid on the sealing surface side of the organic EL element 2-2 so that the edges of the take-out portions of the anode and cathode would be outside. Next, the sample to which the gas barrier film was laminated was placed in a pressure-reducing apparatus and held at 90° C. for 5 minutes by applying a pressing pressure under a pressure-reducing condition of 0.1 MPa. Then, the sample was returned to an atmospheric pressure environment and further heated at 90° C. for 30 minutes to cure the adhesive to obtain a light-emitting device for evaluation.

A constant current of 2.5 mA/cm² was applied to the evaluation light-emitting device for 5 seconds at a temperature of 23° C. to emit light, and then the application was stopped for 10 seconds to quench the light. After 10 cycles of light emission and quenching, the light-emitting devices that emitted light were marked as “AA” and the light-emitting devices that did not emit light were marked as “BB”. The results are shown in Table III.

TABLE III

| Organic EL | Organic semiconductor | Repeated | |
|---|---|---|---|
| element No. | device member No. | stability | Remarks |
| 1-1 | 1-1 | BB | Comparative Example |
| 1-2 | 1-2 | AA | Present Invention |
| 2-1 | 2-1 | AA | Present Invention |
| 2-2 | 2-2 | AA | Present Invention |
| 2-3 | 2-3 | AA | Present Invention |
| 2-4 | 2-4 | AA | Present Invention |

From the above results, it is clear that when the organic semiconductor material (luminescent compound) contained in the ink comes into contact with the electrode (anode) located in the lower layer, a disorder (defect) is generated at the contact point, and a leakage current through the contact point leads to a defective emission of the device (organic EL element). In particular, since there is a close influence on the initial luminescence failure of about 10 cycles, the organic semiconductor device process and the organic semiconductor device described in the present invention, which undergoes the addition of functions accompanying the ink drop onto the ink receptor layer, have a remarkable effect in practical use.

[Production of Inkjet Recording Medium for an Organic Semiconductor Device with a Release Film]

A polyethylene naphthalate film (thickness: 25 μm, produced by Teijin Film Solutions Limited) was overlaid on the ink receiving layer of the inkjet recording medium 2-1 for an organic semiconductor device produced in the same manner as described above. Then, the film was placed in a pressure-reducing apparatus and held for 5 minutes by applying pressure under a pressure-reducing condition of 0.1 MPa at 50° C. to produce an inkjet recording medium 2-1P for an organic semiconductor device with a release film. Inkjet recording media 1-1P, 1-2P, 2-2P and 2-3P for an organic semiconductor device with a release film were prepared in the same manner as described above for inkjet recording media 1-1, 1-2, 2-2 and 2-3 for an organic semiconductor devices.

[Production of an Organic Semiconductor Device (Organic EL Element) Using Inkjet Recording Medium for an Organic Semiconductor Device with a Release Film]

Inkjet recording media 1-1P, 1-2P, and 2-1P to 2-3P for an organic semiconductor device with a release film fabricated as described above were stored in an auto-dry desiccator (manufactured by AS One Corporation, 10% humidity) for 14 days, and then organic semiconductor device was fabricated.

After peeling off the release film on the top surface of the above-mentioned inkjet recording medium for an organic semiconductor device with a release film, the ink 1 is dropped onto the ink receiving layer using the inkjet method in exactly the same way as in the production of the organic EL element 2-2 described above. The ink holding body with dots formed in the pattern shown in FIG. 2 was fabricated, and the ink holding body was mounted on a vacuum deposition device to form an electron injection layer and an electrode (cathode) to fabricate the organic EL elements 1-1P, 1-2P and 2-1P to 2-3P.

After storing the inkjet recording medium 2-1 for an organic semiconductor device fabricated above in an auto-dry desiccator (manufactured by AS ONE Corporation, 10% humidity) at a temperature of 25° C. for 14 days, the organic EL element 2-1H fabricated in exactly the same manner as described above was fabricated.

### <Evaluation>

Organic semiconductor devices (organic EL elements) using inkjet recording media for an organic semiconductor device with a release film and organic EL elements 2-1H, 1-1, 1-2, 2-1 to 2-3 were subjected to a sealing process with adhering a gas barrier film in the same manner as described above. Thus, light-emitting devices for evaluation were fabricated. The following evaluations were performed to them. The results are shown in Table IV.

### (Repeated Stability)

A constant current of 2.5 mA/cm² was applied to the fabricated organic EL element for 5 seconds at a temperature of 23° C. to emit light, and then the application was stopped for 10 seconds to quench the light. After 10 cycles of light emission and quenching, the organic EL elements that emitted light were marked as “AA” and the organic EL elements that did not emit light were marked as “BB”.

### (Luminescence Intensity)

The luminescence intensity was measured when a constant current of 2.5 mA/cm² was applied at a temperature of 23° C. Spectroradiometer CS-2000 (manufactured by Konica Minolta, Inc.) was used for the measurement. The luminescence intensity was expressed as a relative value when the luminescence intensity of the organic EL element 2-1 was 100.

TABLE IV

| Organic EL | Inkjet recording | Repeated | Luminescent | |
|---|---|---|---|---|
| element No. | medium No. | stability | intensity | Remarks |
| 1-1 | 1-1 | BB | 40 | Comparative |
| 1-1P | 1-1P | BB | — | Comparative |
| 1-2 | 1-2 | AA | 80 | Present |
| 1-2P | 1-2P | AA | 90 | Present |
| 2-1 | 2-1 | AA | 100 | Present |
| 2-1H | 2-1H | AA | 100 | Present |
| 2-1P | 2-1P | AA | 110 | Present |
| 2-2 | 2-2 | AA | 95 | Present |
| 2-2P | 2-2P | AA | 100 | Present |
| 2-3 | 2-3 | AA | 95 | Present |
| 2-3P | 2-3P | AA | 105 | Present |

From the above-described results, the repeated stability of the organic EL elements 1-1 and 1-1P was not improved by the release film, mainly due to the effect of contact with the electrode (anode) located in the lower layer. In addition, the luminescence intensity was reduced compared to the organic EL element 2-1 due to the quenching effect of the electrode, and the driving stability of 1-1P with the release film was poor and measurement was not possible.

On the other hand, the organic EL element of the present invention can suppress the quenching effect on the electrode and has a remarkable effect on improving the driving stability of the device. In particular, when comparing the organic EL elements 2-1 and 2-1H, it is found that they show almost the same luminous intensity. This result means that the organic semiconductor process can be separated into two processes, the fabrication of an inkjet recording medium for an organic semiconductor device and the fabrication of an organic semiconductor device, and that the inkjet recording medium for an organic semiconductor device can be stored. This clearly shows that the production process of the present invention is a strong device production process against the external environment. It is clearly demonstrated that the inkjet recording medium for an organic semiconductor device and the manufacturing process using this inkjet recording media are superior to the comparative examples.

In addition, when the organic EL element 2-1P with a release film is compared with the organic EL element 2-1 or the organic EL element 2-1H, there is an improvement in luminous intensity, and this trend is also observed in the organic EL element 2-2P and the organic EL element 2-3P with a release film. Therefore, it is assumed that the release film has not only a function of shielding physical effect (protection against damage of scratching or protection from oxygen or water) from the outside, which is a general function of a protective film, but also it has a function of suppressing the development of phase separation caused by the formation of an interface between the gas (air or nitrogen) and the organic thin film (solid).

### [Production of Organic Semiconductor Device (Organic Photodiode (Photodetector))]

In the production of each of the above the organic EL elements, an organic photodiode 2-1 was fabricated in exactly the same manner except that the ink 2 was used in which the luminescent compound in the ink 1 was changed to a 1:1 (mass ratio) mixture of poly(3-hexylthiophene) (P3HT) and [6,6]-phenyl C61-butyric acid methyl ester (PCBM). An organic photodiode 2-2 was fabricated in exactly the same manner except that the inkjet recording medium 2-1 for an organic semiconductor device was changed to the inkjet recording medium 2-2. The viscosity of the ink 2 was 0.8 mPa·s. The SP value of the above mixture is 16.8 (J/cm³)^{1/2}, and the SP value of the solvent, n-propyl acetate, SP(S), is 18.0 (J/cm3)^{1/2.} Therefore, the SP value of the ink 2, SP(I), is 18.0 (J/cm³)^{1/2}.

When the fabricated organic photodiodes 2-1 and 2-2 were irradiated with a xenon lamp from the transparent electrode (ITO electrode) side and measured the irradiation luminance and the amount of current between the electrodes. As the irradiation intensity was changed from 100 mW to 1000 mW, an increase in the current was observed, and it was confirmed that the fabricated device functioned as a photodiode.

### [Production of Organic Semiconductor Device (Electrochemical Sensor)]

An electrochemical sensor 1 was fabricated as follows using the organic semiconductor device member 2-2 obtained above

Immediately after producing the organic semiconductor device member 2-2, the member was mounted on a vacuum deposition apparatus, the vacuum chamber was depressurized to 4×10⁻⁴ Pa, and an electron injection layer and an electrode were formed under the following conditions. The electron injection layer was formed by evaporating potassium fluoride at a deposition rate of 0.1 Å/sec to a thickness of 2.0 nm. The electrode was formed by evaporating Al to a thickness of 50 nm at a deposition rate of 4 Å/sec, and the electrochemical sensor 1 was fabricated.

### <Evaluation>

The luminescence intensity was measured when a constant current of 2.5 mA/cm² was applied at a temperature of 23° C. Spectroradiometer CS-2000 (manufactured by Konica Minolta, Inc.) was used for the measurement. When dry air was blown on the Al (cathode) surface of the electrochemical sensor 1 at a flow rate of 0.1 L/min, it was observed that when the initial luminance was 100, the relative luminance decreased with the elapsed time of the discharge of the dry air, and the relative luminance decreased to 60 after 30 minutes. As a result, it was confirmed that the electrochemical sensor 1 functions as an electrochemical sensor for oxygen.

### [Production of Organic Semiconductor Device (Electrochemical Sensor 2)]

In exactly the same manner as described above, an inkjet recording medium 2-2 for an organic semiconductor device was prepared. On this inkjet recording medium 2-2 for an organic semiconductor device, the following ink 3 was dropped onto the ink receiving layer by the following inkjet method to form dot areas in the pattern shown in FIG. 2.

### (Production of Ink 3)

n-Propyl acetate was used as a solvent, and poly(3-hexylthiophene-2,5-diyl) (manufactured by TCI Corporation, weight average molecular weight 45,000, high positional regularity (>99%)) was mixed with the solvent at a concentration of 1 mass %. After mixing with the solvent, the mixture was heated by ultrasonic waves to be maintained at 90° C. for 30 minutes, and then filtered through a 0.2 μm filter to remove the agglomerated component, and an ink 3 was prepared. The viscosity of the ink 3 was 0.7 mPa·s. The SP value of poly(3-hexylthiophene-2,5-diyl) is 16.8 (J/cm³)^{1/2} and the SP value of n-propyl acetate, SP(S), is 18.0 (J/cm³)^{1/2}. Therefore, the SP value of the ink 3, SP(I), is 18.0 ((J/cm³)^{1/2}.

### (Conditions of Inkjet Method)

Inkjet apparatus: IJCS-1 made by Konica Minolta, Inc.

Inkjet head: KM512 made by Konica Minolta, Inc.

Number of shots: 2 shots

Distance between discharge nozzles of the head: 140 μm pitch

Head scan speed: 90 mm/sec.

It was mounted on a vacuum deposition apparatus, the vacuum chamber was depressurized to 4×10⁻⁴ Pa, and an electron injection layer and an electrode (cathode) were formed under the following conditions. The electron injection layer was formed by evaporating potassium fluoride at a deposition rate of 0.1 Å/sec to a thickness of 2.0 nm. The electrode was formed by evaporating Al to a thickness of 50 nm at a deposition rate of 4 A/sec, and the electrochemical sensor 2 was fabricated.

### <Evaluation>

The luminescence intensity was measured when a constant current of 2.5 mA/cm² was applied at a temperature of 23° C. Spectroradiometer CS-2000 (manufactured by Konica Minolta, Inc.) was used for the measurement. When dry air was blown on the Al (cathode) surface of the electrochemical sensor 2 at a flow rate of 0.1 L/min, it was observed that when the initial luminance was 100, the relative luminance decreased with the elapsed time of the discharge of the dry air, and the relative luminance decreased to 60 after 30 minutes. As a result, it was confirmed that the electrochemical sensor 2 functions as an electrochemical sensor for oxygen.

### [Production of Organic Semiconductor Device (White)]

In the ink 1 used in the production of each of the above organic EL elements, the luminescent compound (Ir(mppy)₃; emitting green) in the ink 1 was changed to Ir(phq)₃ (tris(2-phenylquinoline)iridium(III); emitting red) and (Ir(mpim)₃ (tris(mesityl -2-phenyl-1H-imidazole)iridium(III); emitting blue) to form an ink 4 (red) and an ink 5 (blue). Viscosity and SP value of the ink 4 and the ink 5 are the same as the ink 1.

The white organic EL element 2-1W was fabricated in exactly the same manner as fabrication of the organic EL element 2-1 described above, except that the ink 1 (green), ink 4 (red) and ink 5 (blue) were arranged so that all dots in the first and fourth rows were ink 4 (red), all dots in the second and fifth rows were ink 1 (green) and all dots in the third and sixth rows were ink 5 (blue) in FIG. 2.

### <Evaluation>

The White OLED device 2-1W was sealed in the same manner as described above, and a constant current of 2.5 mA/cm² was applied at a temperature of 23° C., and white light emission was confirmed.

### [Production of Organic Semiconductor Device (Display)]

The ink 1 (green), ink 4 (red) and ink 5 (blue) were prepared in the same manner as described above. The ink 1 (green), ink 4 (red) and ink 5 (blue) were dropped onto the ink receiving layer of the inkjet recording medium 2-1 for an organic semiconductor device according to a predetermined pattern (the ratio of the number of dots of green, red and blue is 1:1:2) by the inkjet method. Then, wiring and electrodes were formed according to the design of the active matrix type full color display device to obtain the organic EL element 2-1D.

The organic EL element 2-1D has, on the same substrate, a wiring section including a plurality of scanning lines and data lines, and a plurality of juxtaposed pixels (dots) (pixels (dots) whose color of emission is in a red region, pixels (dots) in a green region, and pixels (dots) in a blue region), and the scanning lines and the plurality of data lines of the wiring section are respectively made of conductive material, and the scanning lines and data lines are orthogonal to each other in a lattice configuration and are connected to the pixels (dots) at orthogonal positions. An active-matrix full-color display device was fabricated using the organic EL element 2-1D in combination with other components.

Each pixel (dot) on the organic EL element 2-1D is driven in an active matrix system by a switching transistor and a drive transistor, which are active elements, and when a scanning signal is applied from the scanning line, it receives an image data signal from the data line and emits light according to the received image data.

By driving the active matrix full-color display device equipped with the organic EL element 2-1D, it was found that high brightness, high durability, and clear full-color moving image display can be obtained.

Although embodiments of the present invention have been described and illustrated in detail, the disclosed embodiments are made for purposes of illustration and example only and not limitation. The scope of the present invention should be interpreted by terms of the appended claims

### DESCRIPTION OF SYMBOLS

1: Inkjet recording medium for an organic semiconductor device

2: Base material

3: Electrode

4A, 4B: Ink receiving layer

41: Ink penetration area (ink penetrating layer)

42 Ink penetration prevention area (ink insoluble layer)

5: Organic semiconductor material-containing area

6: Organic semiconductor layer

7: Electrode (counter electrode)

10A, 10B: Member for an organic semiconductor device

11: Inkjet apparatus

12: Inkjet head

100: Organic semiconductor device

What is claimed is:

1. An inkjet recording medium for an organic semiconductor device comprising a base material, an electrode, and ink receiving layer in this order,
wherein the ink receiving layer has an ink penetration prevention area on an electrode side that prevents an ink which permeates from a surface far from the electrode toward the electrode from reaching the electrode.

2. The inkjet recording medium for an organic semiconductor device described in claim 1,
wherein the ink receiving layer has an ink penetrating layer including a surface far from the electrode and an ink insoluble layer on the electrode side as the ink penetration prevention area.

3. The inkjet recording medium for an organic semiconductor device described in claim 2,
wherein the ink insoluble layer contains a crosslinked resin as a main component.

4. The inkjet recording medium for an organic semiconductor device described in claim 2,
wherein the ink insoluble layer includes an interpenetrating polymer network structure.

5. The inkjet recording medium for an organic semiconductor device described in claim 2,
wherein an absolute value of a difference between an SP value of a component of the ink penetrating layer and an SP value of the ink is 3.0 (J/cm³)^{1/2} or less, and an absolute value of a difference between an SP value of a component of the ink insoluble layer and an SP value of the ink is 3.1 (J/cm³)^{1/2} or more.

6. The inkjet recording medium for an organic semiconductor device described in claim 2,
wherein the ink penetrating layer contains a polystyrene resin and the ink insoluble layer contains a resin containing tetraphenylbenzidine or a derivative thereof as a main polymerization unit.

7. The inkjet recording medium for an organic semiconductor device described in claim 1, further having a release film on the ink receiving layer.

8. An organic semiconductor device member comprising a base material, an electrode, and an organic semiconductor layer laminated in this order,
wherein the organic semiconductor layer has:
(i) an ink receiving layer continuously present in an entire area of an organic semiconductor layer formation area on the electrode;
(ii) a pattern-shaped exposed portion on a surface of the organic semiconductor layer far from the electrode as a discontinuous area surrounded by the ink receiving layer; and
(iii) an organic semiconductor material-containing area which has no interface with the electrode.

9. The organic semiconductor device member described in claim 8, wherein a maximum thickness of the ink receiving layer is in the range of 3 nm to 5 μm.

10. The organic semiconductor device member described in claim 8, wherein a constituent material of the ink-receiving layer mainly includes a resin having a weight average molecular weight in the range of 1,000 to 1,000,000.

11. The organic semiconductor device member described in claims 8,
wherein, the organic semiconductor material-containing area is a region formed using an ink containing the organic semiconductor material, and an absolute value of a difference between an SP value of a constituent material of the ink receiving layer and an SP value of the ink is 3.0 (J/cm³)^{1/2} or less.

12. The organic semiconductor device member described in claim 8, wherein the organic semiconductor material-containing area is a region formed using an ink containing the organic semiconductor material, and the ink receiving layer has an ink penetrating layer including a surface far from the electrode and an ink insoluble layer on the electrode side.

13. A method for producing an organic semiconductor device using an inkjet recording medium for an organic semiconductor device described in claim 1, comprising the steps of:
dropping an ink onto the ink receiving layer; and
after dropping of the ink, forming an electrode paired with the electrode on the ink receiving layer.

14. The method for producing an organic semiconductor device described in claim 13, wherein the organic semiconductor device is selected from an organic electroluminescent element, an organic thin film transistor, or an organic photoelectric conversion device.
